(19) United States
(12) Patent Application Publication
(10) Pub. No.: US 2015/0060833 A1
(43) Pub. Date: Mar. 5, 2015

(54) MATERIAL FOR ORGANIC ELECTRONIC DEVICE, AND ORGANIC ELECTRONIC DEVICE USING THE SAME

(71) Applicant: LG CHEM, LTD., Seoul (KR)

(72) Inventors: Hyok Joon KWON, Daejeon (KR); Kidong KOO, Daejeon (KR); Kongkyeom KIM, Daejeon (KR); Minjun KIM, Daejeon (KR); Seong So KIM, Daejeon (KR); Hyoung Seok KIM, Daejeon (KR); Hyoungcheul KIM, Daejeon (KR); Sang Young JEON, Daejeon (KR); Heungwoo CHOI, Daejeon (KR)

(21) Appl. No.: 14/495,400

(22) Filed: Sep. 24, 2014

Related U.S. Application Data
(63) Continuation-in-part of application No. 13/060,248, filed on May 18, 2011.

(30) Foreign Application Priority Data
Aug. 22, 2008 (KR) 10-2008-0082477

(51) Int. Cl. H01L 51/00

(52) U.S. Cl. CPC H01L 51/0067; H01L 51/0072; H01L 51/5056
USPC 257/40; 548/420; 544/284

(57) ABSTRACT

The present specification provides a novel compound that is capable of largely improving an expected life span, efficiency, electrochemical stability, and thermal stability of an organic electronic device, and an organic electronic device that includes an organic material layer including the compound.

### CROSS-REFERENCE TO RELATED APPLICATIONS

This application is a continuation-in-part application of U.S. Ser. No. 13/060,248, filed on Feb. 22, 2011, which is a national stage application of PCT/KR2009/004689, filed on on Aug. 21, 2009, which claims priority to and the benefit of Korean Patent Application No. 10-2008-0082477, filed on Aug. 22, 2008, the entire contents of which are incorporated herein by reference.

### TECHNICAL FIELD

The present specification relates to a novel compound that is capable of largely improving an expected life span, efficiency, electrochemical stability, and thermal stability of an organic electronic device, and an organic electronic device using the same.

### BACKGROUND ART

An organic light emission phenomenon is an example of a conversion of current into visible rays through an internal process of a specific organic molecule. The organic light emission phenomenon is based on the following mechanism. When organic material layers are interposed between an anode and a cathode, if voltage is applied between the two electrodes, electrons and holes are injected from the cathode and the anode, respectively, into the organic material layer. The electrons and the holes which are injected into the organic material layer are recombined to form an exciton, and the exciton is reduced to a bottom state to emit light. An organic light emitting device which is based on the above mechanism typically may include a cathode, an anode, and organic material layers interposed therebetween, for example, organic material layers including a hole injection layer, a hole transport layer, a light emitting layer, and an electron transport layer.

The material(s) used in the organic light emitting device are mostly pure organic materials or complexes of organic material and metal. The material(s) used in the organic light emitting device may be classified into a hole injection material, a hole transport material, a light emitting material, an electron transport material, an electron injection material, or the like, according to its use. In connection with this, an organic material having a p-type property, which is easily oxidized and is electrochemically stable when it is oxidized, is mostly used as the hole injection material or the hole transport material. Meanwhile, an organic material having an n-type property, which is easily reduced and is electrochemically stable when it is reduced, is mostly used as the electron injection material or the electron transport material. As the light emitting layer material, a material having both p-type and n-type properties is preferable, which is stable when it is oxidized and when it is reduced. Also, a material having high light emission efficiency for conversion of the exciton into light when the exciton is formed is preferable.

Furthermore, it is preferable that the material used in the organic light emitting device additionally have the following properties.

First, it is preferable that the material used in the organic light emitting device have excellent thermal stability. The reason is that joule heat is generated by movement of electric charges in the organic light emitting device. Recently, 4,4′-bis[N-(1-naphthyl)-N-phenylamino]biphenyl (NPB), which has mostly been used as the hole transport layer material, has a glass transition temperature value of 100° C. or less, thus it is difficult to apply to an organic light emitting device requiring a high current.

Second, in order to produce an organic light emitting device that is capable of being driven at low voltage and has high efficiency, holes and electrons which are injected into the organic light emitting device must be smoothly transported to a light emitting layer, and must not be released out of the light emitting layer. To achieve this, a material used in the organic light emitting device must have a proper band gap and an appropriate highest occupied molecular orbital (HOMO) or lowest unoccupied molecular orbital (LUMO) energy level. A LUMO energy level of poly(3,4-ethylenedioxythiophene):polystyrene sulfonate (PEDOT:PSS), which is currently used as a hole transport material of an organic light emitting device manufactured using a solution coating method, is lower than that of an organic material used as a light emitting layer material, thus it is difficult to manufacture an organic light emitting device having characteristics of high efficiency and a long expected life span.

Moreover, the material used in the organic light emitting device must have excellent chemical stability, electric charge mobility, and interfacial characteristic with an electrode or an adjacent layer. That is, the material used in the organic light emitting device must be little deformed by moisture or oxygen. Furthermore, proper hole or electron mobility must be assured so as to balance densities of the holes and of the electrons in the light emitting layer of the organic light emitting device to maximize the formation of excitons. Additionally, it is preferable to have an excellent interface characteristic with an electrode including metal or metal oxides or an adjacent layer so as to assure stability of the device.

Accordingly, there is a need to develop an organic material having the above-mentioned requirements in the art.

### SUMMARY OF THE INVENTION

Therefore, the inventors of the present specification aim to provide a novel compound that is capable of satisfying conditions required of a material which may be used for an organic light emitting device and an organic electronic device, for example, a proper energy level, electrochemical stability, and thermal stability, and is capable of largely improving an expected life span and efficiency of the organic electronic device, and an organic electronic device using the same.

The present specification provides a compound that is represented by the following Formula 1:

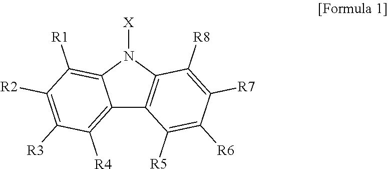

wherein in Formula 1, R3 and R4 are bonded to each other to form an aromatic ring,

at least one of a group at which an aromatic ring is not formed among R1 to R4, a substituent group that is substituted at an aromatic ring that is formed by bonding R3 and R4 to each other, and R5 to R8 is -(L1)p-(Y1)q, herein, p is an integer of 0 to 10, q is an integer of 1 to 10, the remains are each independently -(L2)r-(Y2)s, herein, r is an integer of 0 to 10, and s is an integer of 1 to 10,

X is -(A)m—(B)n, herein, m is an integer of 0 to 10, and n is independently an integer of 1 to 10,

A is an arylene group having 6 to 12 carbon atoms; an alkenylene group; a fluorenylene group; or a heteroarylene group including one or more of N, O, and S atoms,

in the case where m is 0, B is hydrogen; deuterium; an alkyl group; an alkenyl group; a silyl group; a boron group; an aryl group having 6 to 12 carbon atoms; a fluorenyl group; or a hetero ring group including one or more of N, O, and S atoms, in the case where m is not 0, B is hydrogen; deuterium; a halogen group; a nitrile group; a nitro group; a hydroxy group; an alkyl group; a cycloalkyl group; an alkoxy group; an alkylthioxy group; an alkylsulfoxy group; an alkenyl group; a silyl group; a boron group; an aryl group having 6 to 12 carbon atoms; a fluorenyl group; or a hetero ring group including one or more of N, O, and S atoms and unsubstituted or substituted by an aryl group having 6 to 12 carbon atoms,

L1 and L2 are the same as or different from each other, and are each independently an arylene group having 6 to 12 carbon atoms; an alkenylene group; a fluorenylene group; a carbazolylene group; or a heteroarylene group including one or more of N, O, and S atoms,

Y1 is a carbazole group unsubstituted or substituted by at least one of a phenyl group, a biphenyl group, a terphenyl group, a naphthyl group, an anthracenyl group, a phenanthryl group, a perylenyl group, a chrysenyl group, a hetero ring group, and an alkylamine group; or a benzocarbazole group unsubstituted or substituted by at least one of a phenyl group, a biphenyl group, a terphenyl group, a naphthyl group, an anthracenyl group, a phenanthryl group, a perylenyl group, a chrysenyl group, a hetero ring group, and an alkylamine group,

Y2 is hydrogen; deuterium; a halogen group; a nitrile group; a nitro group; a hydroxy group; an alkyl group; a cycloalkyl group; an alkoxy group; an alkylthioxy group; an alkylsulfoxy group; an alkenyl group; a silyl group; a boron group; an alkylamine group; a fluorenyl group; a carbazole group; or a hetero ring group including one or more of N, O, and S atoms, and

in the case where two or more of A, B, L1, L2, Y1, or Y2 are provided, they are the same as or different from each other.

Furthermore, the present specification provides an organic electronic device including a first electrode; a second electrode; and one or more organic material layers that are disposed between the first electrode and the second electrode, in which one or more layers of the organic material layers include the compound of Formula 1.

A compound of the present specification may be used as an organic material layer material, for example, a hole injection material, a hole transport material, a light emitting material, an electron transport material, an electron injection material, and the like, and particularly, the hole injection material and/or the hole transport material in an organic electronic device. In the case where the compound of the present specification is used in an organic light emitting device and an organic electronic device, a driving voltage of the device can be reduced, light efficiency can be improved, and an expected life span characteristic of the device can be improved due to thermal stability of the compound.

### BRIEF DESCRIPTION OF THE DRAWINGS

FIG. 1 illustrates an example of an organic light emitting device that includes a substrate 1, an anode 2, a light emitting layer 3, and a cathode 4.

FIG. 2 illustrates an example of an organic light emitting device that includes a substrate 1, an anode 2, a hole injection layer 5, a hole transport layer 6, a light emitting layer 7, an electron transport layer 8, and a cathode 4.

FIG. 3 is an MS data of intermediate 1-E-1 in Examples of the present specification.

FIG. 4 is a MS data of intermediate 1-E-2 in the Examples of the present specification.

FIG. 5 is an MS data of intermediate 5-A-1 in the Examples of the present specification.

FIG. 6 is an MS data of compound 28 in the Examples of the present specification.

FIG. 7 is an MS data of intermediate 2-B-1 in the Examples of the present specification.

FIG. 8 is an MS data of compound 37 in the Examples of the present specification.

FIG. 9 is an MS data of compound 42 in the Examples of the present specification.

### DETAILED DESCRIPTION

Hereinafter, the present specification will be described in detail.

A compound according to the present specification is represented by Formula 1.

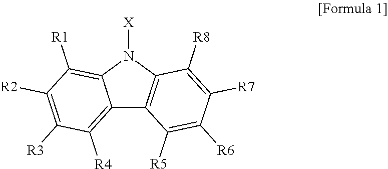

In Formula 1, R3 and R4 are bonded to each other to form an aromatic ring, at least one of a group at which an aromatic ring is not formed among R1 to R4, a substituent group that is substituted at an aromatic ring that is formed by bonding R3 and R4 to each other, and R5 to R8 is -(L1)p-(Y1)q, herein, p is an integer of 0 to 10, q is an integer of 1 to 10, the remains are each independently -(L2)r-(Y2)s, herein, r may be an integer of 0 to 10, and s may be an integer of 1 to 10.

In Formula 1, X is -(A)m-(B)n, herein, m may be an integer of 0 to 10, and n may be independently an integer of 1 to 10.

In Formula 1, A may be an arylene group having 6 to 12 carbon atoms; an alkenylene group; a fluorenylene group; or a heteroarylene group including one or more of N, O, and S atoms.

In Formula 1, in the case where m is 0, B may be hydrogen; deuterium; an alkyl group; an alkenyl group; a silyl group; a boron group; an aryl group having 6 to 12 carbon atoms; a fluorenyl group; or a hetero ring group including one or more of N, O, and S atoms, and in the case where m is not 0, B may be hydrogen; deuterium; a halogen group; a nitrile group; a nitro group; a hydroxy group; an alkyl group; a cycloalkyl group; an alkoxy group; an alkylthioxy group; an alkylsulfoxy group; an alkenyl group; a silyl group; a boron group; an aryl group having 6 to 12 carbon atoms; a fluorenyl group; or a hetero ring group including one or more of N, O, and S atoms and unsubstituted or substituted by an aryl group having 6 to 12 carbon atoms.

In Formula 1, L1 and L2 may be the same as or different from each other, and may be each independently an arylene group having 6 to 12 carbon atoms; an alkenylene group; a fluorenylene group; a carbazolylene group; or a heteroarylene group including one or more of N, O, and S atoms.

In Formula 1, Y1 may be a carbazole group unsubstituted or substituted by at least one of a phenyl group, a biphenyl group, a terphenyl group, a naphthyl group, an anthracenyl group, a phenanthryl group, a perylenyl group, a chrysenyl group, a hetero ring group, and an alkylamine group; or a benzocarbazole group unsubstituted or substituted by at least one of a phenyl group, a biphenyl group, a terphenyl group, a naphthyl group, an anthracenyl group, a phenanthryl group, a perylenyl group, a chrysenyl group, a hetero ring group, and an alkylamine group.

In Formula 1, Y2 may be hydrogen; deuterium; a halogen group; a nitrile group; a nitro group; a hydroxy group; an alkyl group; a cycloalkyl group; an alkoxy group; an alkylthioxy group; an alkylsulfoxy group; an alkenyl group; a silyl group; a boron group; an alkylamine group; a fluorenyl group; a carbazole group; or a hetero ring group including one or more of N, O, and S atoms.

In Formula 1, in the case where two or more of A, B, L1, L2, Y1, or Y2 are provided, they are the same as or different from each other.

In Formula 1, Y1 may be any one of the following Formulas 2 to 5.

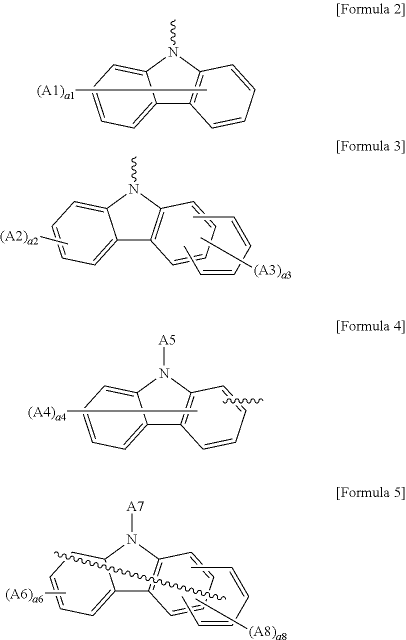

In Formulas 2 to 5, A1 to A8 are each independently a phenyl group, a biphenyl group, a terphenyl group, a naphthyl group, an anthracenyl group, a phenanthryl group, a perylenyl group, a chrysenyl group, a hetero ring group, or an alkylamine group, a1 is an integer of 0 to 8, a2 is an integer of 0 to 4, a3 is an integer of 0 to 6, a4 is an integer of 0 to 7, a6 is an integer of 0 to 4, a8 is an integer of 0 to 6, 0≦a6+a8≦9, and in the case where two or more of A1, A2, A3, A4, A6, and A8 are provided, they are the same as or different from each other.

In Formulas 2 to 5, A5 and A7 may be each independently a phenyl group, a biphenyl group, a terphenyl group, a naphthyl group, an anthracenyl group, a phenanthryl group, a perylenyl group, or a chrysenyl group.

In Formulas 2 to 5, a1 to a4, a6, and a8 may be each independently an integer of 0 to 4.

In Formulas 2 to 5, a1 to a4, a6, and a8 may be each independently 0 or 1.

In Formulas 2 to 5, a1 to a4, a6, and a8 may be 0.

The compound represented by Formula 1 may be represented by the following Formula 6.

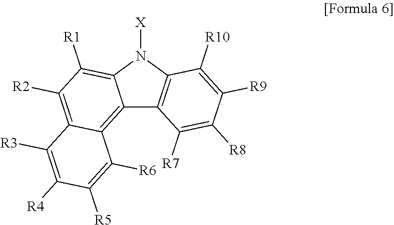

In Formula 6, at least one of R1 to R10 is -(L1)p-(Y1)q, the remains are each independently -(L2)r-(Y2)s, and herein, X, L1, L2, Y1, Y2, p, q, r, and s are the same as those defined by Formula 1.

In an exemplary embodiment of the present specification, at least one of L1 and L2 of Formula 1 or 6 may be a direct bond. Specifically, in the case where L1 of Formula 1 or 6 is the direct bond, p is 0, and in the case where L2 of Formula 1 or 6 is the direct bond, r is 0.

In the exemplary embodiment of the present specification, L1 and L2 of Formula 1 or 6 may be the direct bond. Specifically, in the case where L1 and L2 of Formula 1 or 6 are the direct bond, p and r are 0.

In the exemplary embodiment of the present specification, Y2 of Formula 1 or 6 may be hydrogen.

In the exemplary embodiment of the present specification, L1 and L2 of Formula 1 or 6 may be the direct bond, and Y2 of Formula 1 or 6 may be hydrogen.

The compound represented by Formula 1 may be represented by any one of the following Formulas 7 to 14.

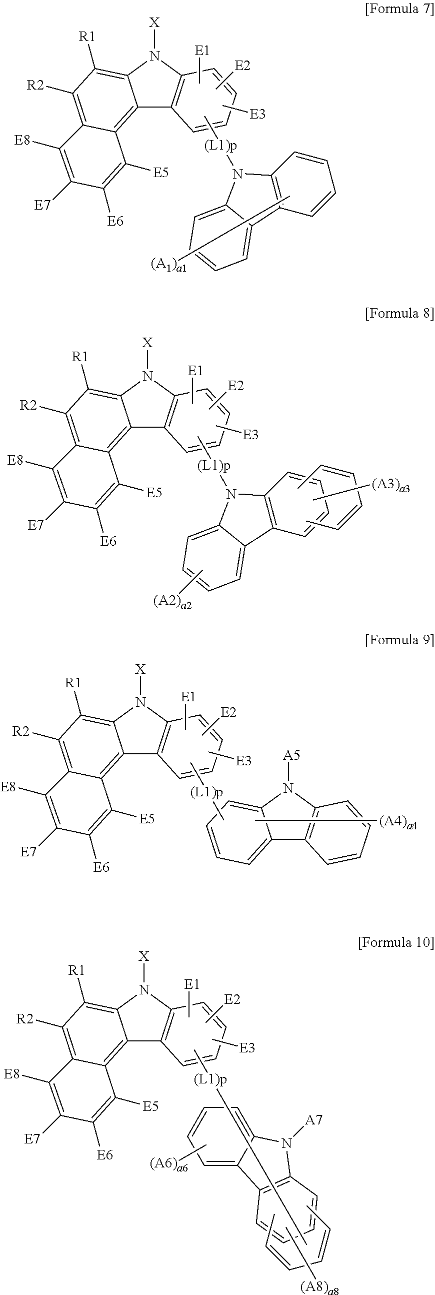

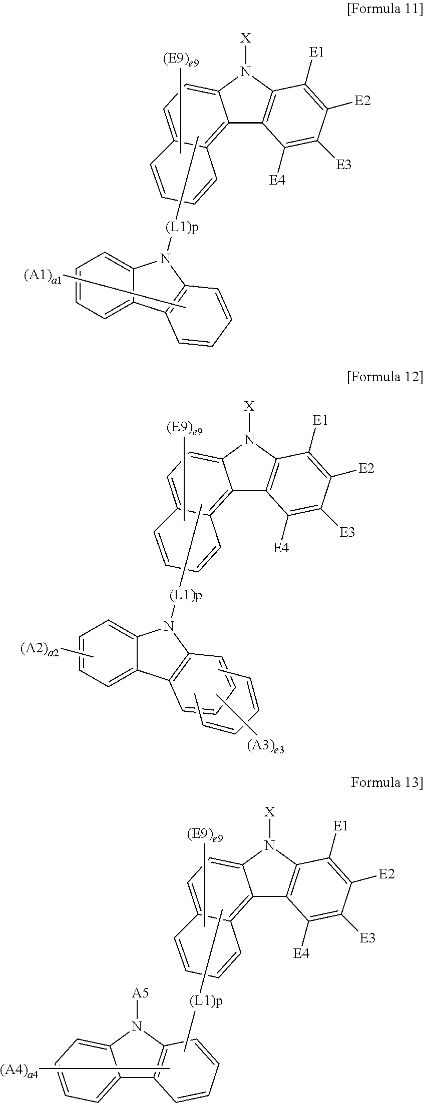

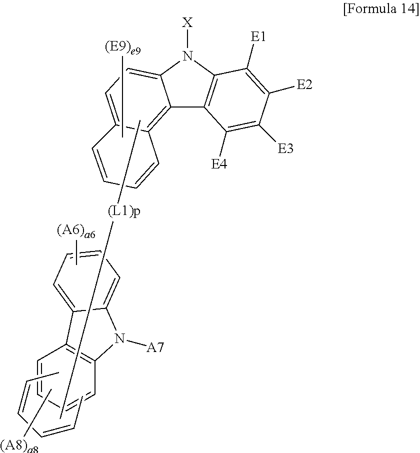

In Formulas 7 to 14, R1, R2, and E1 to E9 are each independently -(L1)p-(Y1)q or -(L2)r-(Y2)s, and herein, X, L1, L2, Y1, Y2, p, q, r, and s are the same as those defined by Formula 1.

In Formulas 7 to 14, A1 to A8 are each independently a phenyl group, a biphenyl group, a terphenyl group, a naphthyl group, an anthracenyl group, a phenanthryl group, a perylenyl group, a chrysenyl group, a hetero ring group, or an alkylamine group, a1 is an integer of 0 to 8, a2 is an integer of 0 to 4, a3 is an integer of 0 to 6, a4 is an integer of 0 to 7, a6 is an integer of 0 to 4, a8 is an integer of 0 to 6, 0≦a6+a8≦9, e9 is an integer of 0 to 5, and in the case where two or more of A1, A2, A3, A4, A6, A8, and E9 are provided, they may be the same as or different from each other.

In Formulas 7 to 14, at least one of L1 and L2 may be a direct bond. Specifically, in the case where L1 of Formulas 7 to 14 is the direct bond, p is 0, and in the case where L2 of Formulas 7 to 14 is the direct bond, r is 0.

In Formulas 7 to 14, L1 and L2 may be the direct bond. Specifically, in the case where L1 and L2 of Formulas 7 to 14 are the direct bond, p and r are 0.

In the exemplary embodiment of the present specification, Y2 of Formulas 7 to 14 may be hydrogen.

In the exemplary embodiment of the present specification, L1 and L2 of Formulas 7 to 14 may be the direct bond, and Y2 of Formulas 7 to 14 may be hydrogen. Specifically, at least one of R1, R2, and E1 to E9 of Formulas 7 to 14 may be hydrogen.

In the exemplary embodiment of the present specification, A5 and A7 of Formulas 9, 10, 13, and 14 may be each independently a phenyl group, a biphenyl group, a terphenyl group, a naphthyl group, an anthracenyl group, a phenanthryl group, a perylenyl group, or a chrysenyl group.

In Formulas 7 to 14, a1 to a4, a6, a8, and e9 may be each independently an integer of 0 to 4.

In Formulas 7 to 14, a1 to a4, a6, a8, and e9 may be each independently 0 or 1.

In Formulas 7 to 14, a1 to a4, a6, a8, and e9 may be 0.

The compound represented by Formula 1 may be represented by any one of the following Formulas 15 to 30.

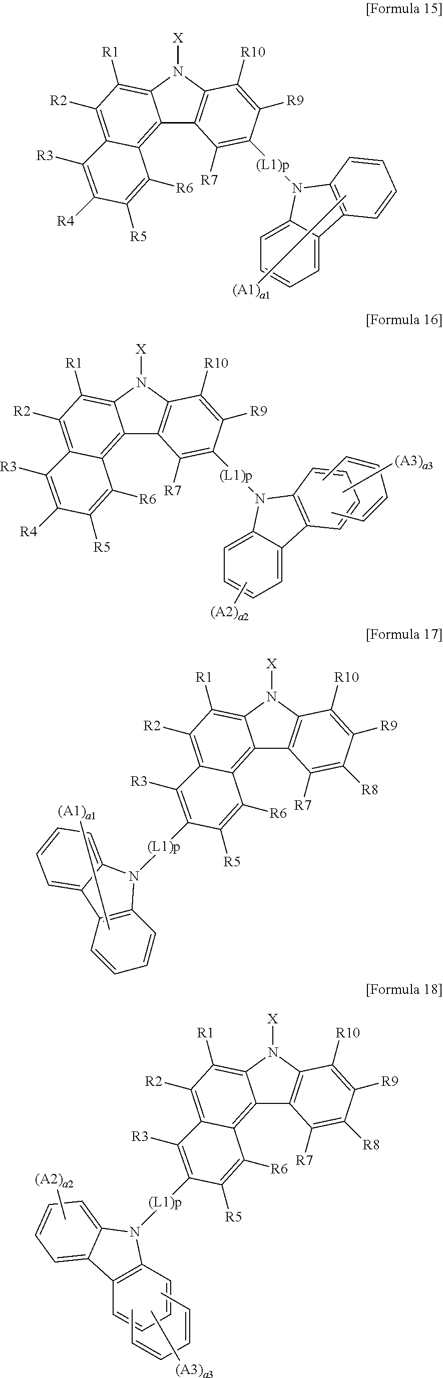

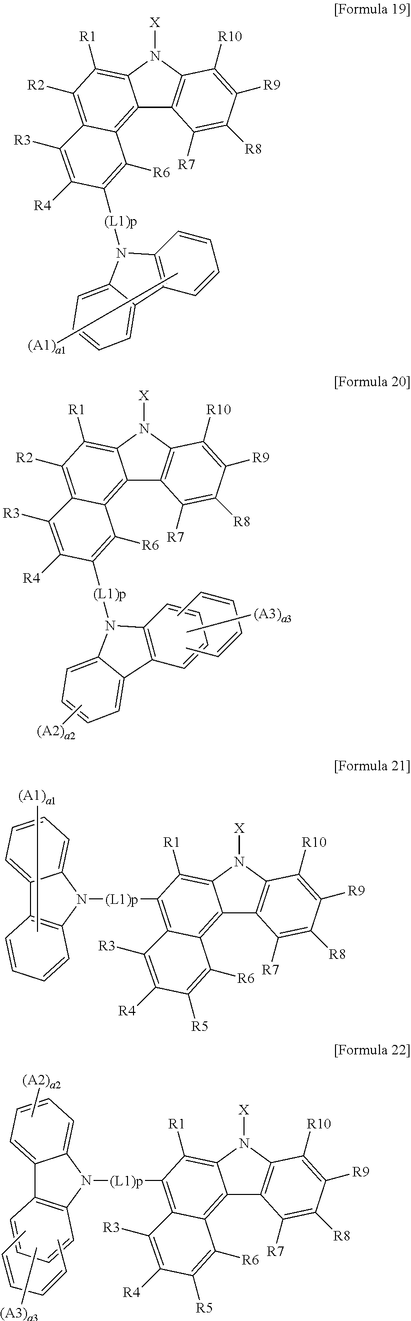

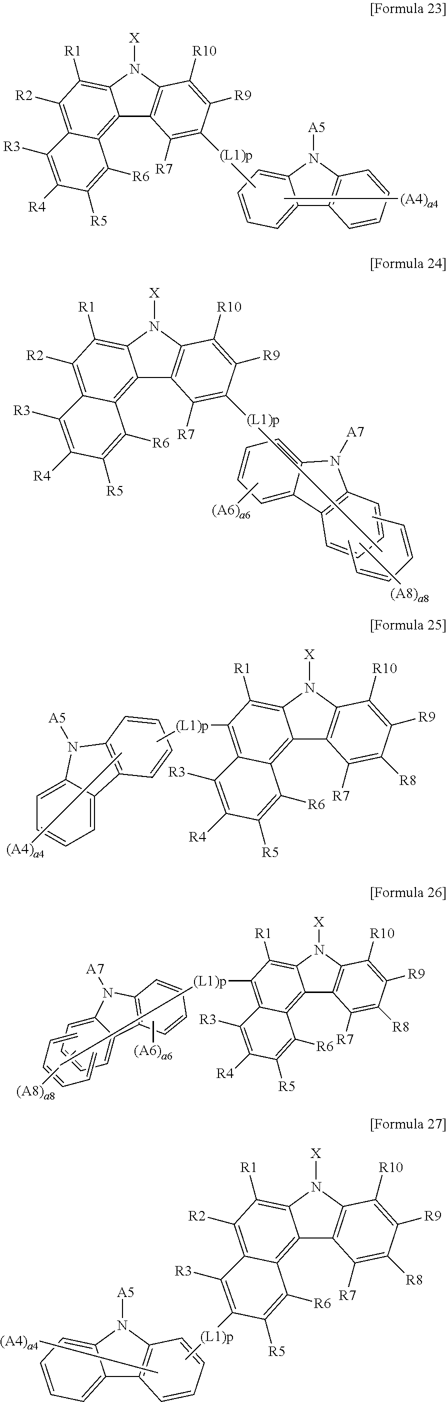

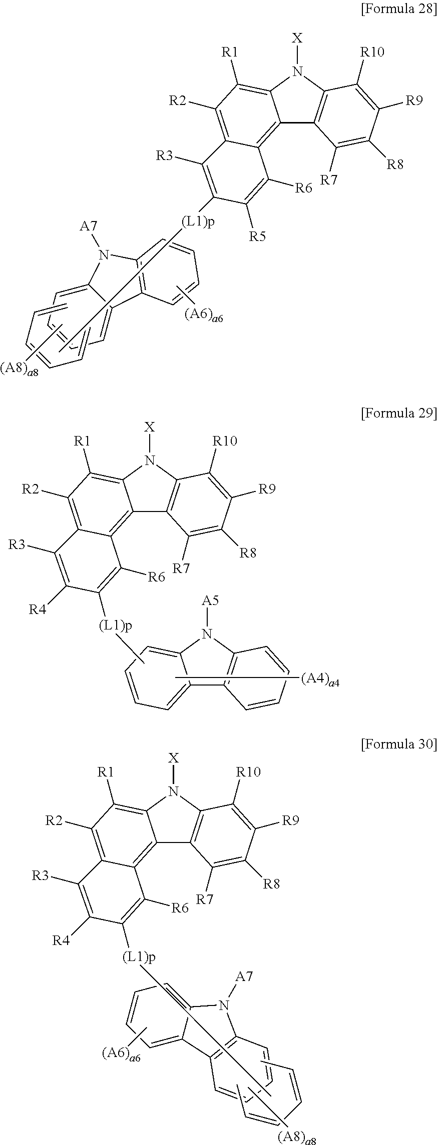

In Formulas 15 to 30, R1 to R10 are each independently -(L1)p-(Y1)q or -(L2)r-(Y2)s, and herein, X, L1, L2, Y1, Y2, p, q, r, and s are the same as those defined by Formula 1.

In Formulas 15 to 30, A1 to A8 are each independently a phenyl group, a biphenyl group, a terphenyl group, a naphthyl group, an anthracenyl group, a phenanthryl group, a perylenyl group, a chrysenyl group, a hetero ring group, or an alkylamine group, a1 is an integer of 0 to 8, a2 is an integer of 0 to 4, a3 is an integer of 0 to 6, a4 is an integer of 0 to 7, a6 is an integer of 0 to 4, a8 is an integer of 0 to 6, 0≦a6+a8≦9, and in the case where two or more of A1, A2, A3, A4, A6, and A8 are provided, they may be the same as or different from each other.

In Formulas 15 to 30, at least one of L1 and L2 may be a direct bond. Specifically, in the case where L1 of Formulas 15 to 30 is the direct bond, p is 0, and in the case where L2 of Formulas 15 to 30 is the direct bond, r is 0.

In Formulas 15 to 30, L1 and L2 may be the direct bond. Specifically, in the case where L1 and L2 of Formulas 15 to 30 are the direct bond, p and r are 0.

In the exemplary embodiment of the present specification, Y2 of Formulas 15 to 30 may be hydrogen.

In the exemplary embodiment of the present specification, L1 and L2 of Formulas 15 to 30 may be the direct bond, and Y2 of Formulas 15 to 30 may be hydrogen. Specifically, at least one of R1 to R10 of Formulas 15 to 30 may be hydrogen.

In the exemplary embodiment of the present specification, A5 and A7 of Formulas 23 to 30 may be each independently a phenyl group, a biphenyl group, a terphenyl group, a naphthyl group, an anthracenyl group, a phenanthryl group, a perylenyl group, or a chrysenyl group.

In Formulas 23 to 30, a1 to a4, a6, and a8 may be each independently an integer of 0 to 4.

In Formulas 23 to 30, a1 to a4, a6, and a8 may be each independently 0 or 1.

In Formulas 23 to 30, a1 to a4, a6, and a8 may be 0.

The compound represented by Formula 1 may be represented by any one of the following Formulas 31 to 42.

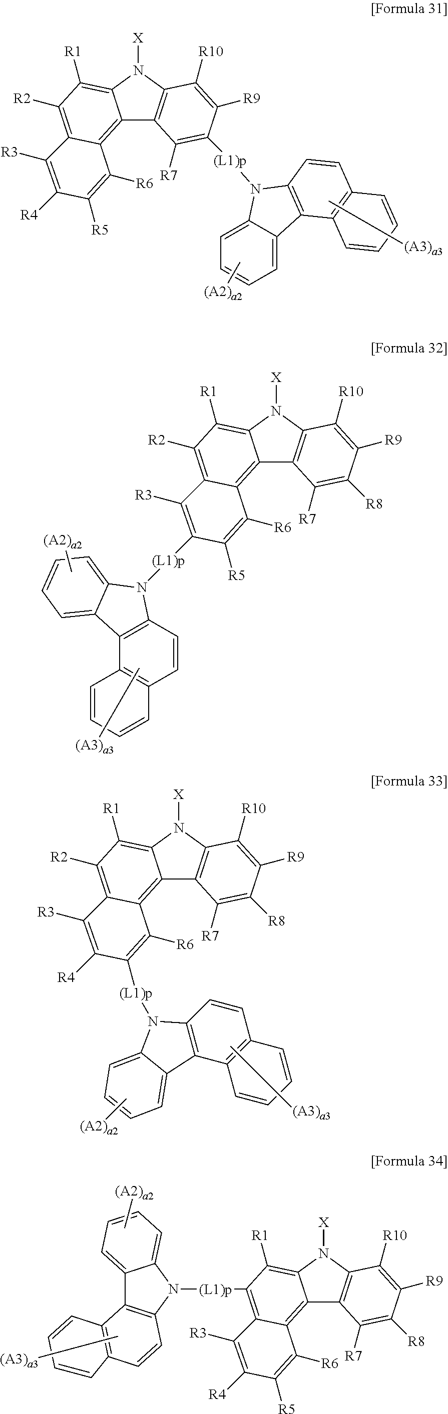

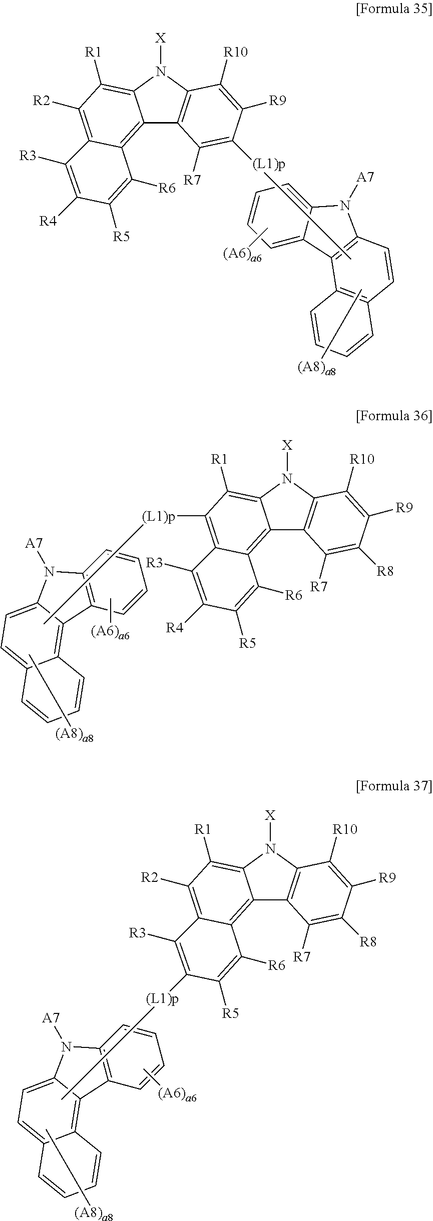

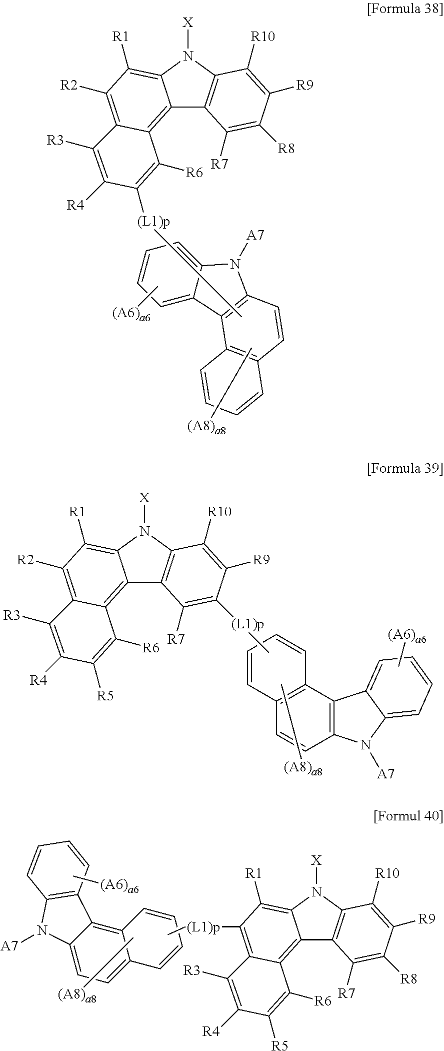

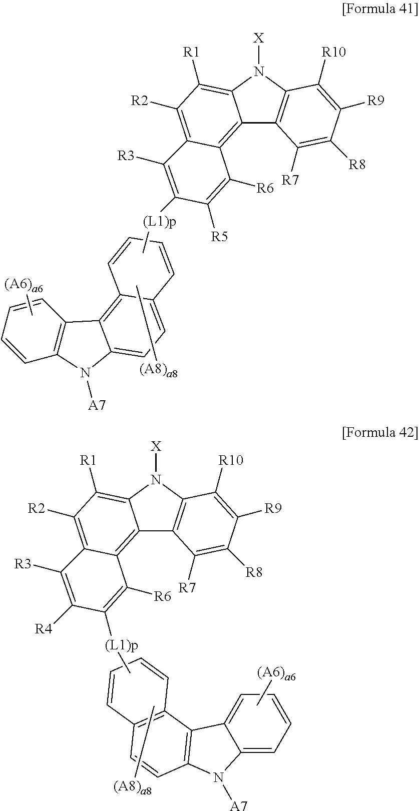

In Formulas 31 to 42, R1 to R10 are each independently -(L1)p-(Y1)q or -(L2)r-(Y2)s, and herein, X, L1, L2, Y1, Y2, p, q, r, and s are the same as those defined by Formula 1.

In Formulas 31 to 42, A2, A3 and A6 to A8 are each independently a phenyl group, a biphenyl group, a terphenyl group, a naphthyl group, an anthracenyl group, a phenanthryl group, a perylenyl group, a chrysenyl group, a hetero ring group, or an alkylamine group, a2 is an integer of 0 to 4, a3 is an integer of 0 to 6, a6 is an integer of 0 to 4, a8 is an integer of 0 to 6, 0≦a6+a8≦9, and in the case where two or more of A2, A3, A6 and A8 are provided, they may be the same as or different from each other.

In Formulas 31 to 42, at least one of L1 and L2 may be a direct bond. Specifically, in the case where L1 of Formulas 31 to 42 is the direct bond, p is 0, and in the case where L2 of Formulas 31 to 42 is the direct bond, r is 0.

In Formulas 31 to 42, L1 and L2 may be the direct bond. Specifically, in the case where L1 and L2 of Formulas 31 to 42 are the direct bond, p and r are 0.

In the exemplary embodiment of the present specification, Y2 of Formulas 31 to 42 may be hydrogen.

In the exemplary embodiment of the present specification, L1 and L2 of Formulas 31 to 42 may be the direct bond, and Y2 of Formulas 31 to 42 may be hydrogen. Specifically, at least one of R1 to R10 of Formulas 31 to 42 may be hydrogen.

In the exemplary embodiment of the present specification, A7 of Formulas 35 to 42 may be each independently a phenyl group, a biphenyl group, a terphenyl group, a naphthyl group, an anthracenyl group, a phenanthryl group, a perylenyl group, or a chrysenyl group.

In Formulas 31 to 42, a2, a3, a6 and a8 may be each independently an integer of 0 to 4.

In Formulas 31 to 42, a2, a3, a6 and a8 may be each independently 0 or 1.

In Formulas 31 to 42, a2, a3, a6 and a8 may be 0.

In Formulas 1, 6, and 7 to 42, A may be an arylene group having 6 to 12 carbon atoms; or a heteroarylene group including one or more of N, O, and S atoms.

In Formulas 1, 6, and 7 to 42, the heteroarylene group of A may be a heteroarylene group including one or more N atoms. Specifically, the heteroarylene group of A may be a divalent quinazoline group, a divalent carbazole group, or a divalent pyridine group.

In Formulas 1, 6, and 7 to 42, in the case where m is 0, B may be an aryl group having 6 to 12 carbon atoms; a fluorenyl group; or a hetero ring group including one or more of N, O, and S atoms.

In Formulas 1, 6, and 7 to 42, in the case where m is not 0, B may be hydrogen; a nitrile group; a silyl group; an aryl group having 6 to 12 carbon atoms; a fluorenyl group; or a hetero ring group including one or more of N, O, and S atoms and unsubstituted or substituted by an aryl group having 6 to 12 carbon atoms.

In Formulas 1, 6, and 7 to 42, A is an arylene group having 6 to 12 carbon atoms; or a heteroarylene group including one or more N atoms, in the case where m is 0, B may be an aryl group having 6 to 12 carbon atoms; a fluorenyl group; or a hetero ring group including one or more of N, O, and S atoms, and in the case where m is not 0, B may be hydrogen; a nitrile group; a silyl group; an aryl group having 6 to 12 carbon atoms; a fluorenyl group; or a hetero ring group including one or more of N, O, and S atoms and unsubstituted or substituted by an aryl group having 6 to 12 carbon atoms.

In Formulas 1, 6, and 7 to 42, m may be an integer of 0 to 2.

In Formulas 1, 6, and 7 to 42, n may be 1.

In Formulas 1, 6, and 7 to 42, m may be an integer of 0 to 2, and n may be 1.

In Formulas 1, 6, and 7 to 42, A is an arylene group having 6 to 12 carbon atoms; or a heteroarylene group including one or more N atoms, m is an integer of 0 to 2, n is 1, in the case where m is 0, B may be an aryl group having 6 to 12 carbon atoms; a fluorenyl group; or a hetero ring group including one or more of N, O, and S atoms, and in the case where m is not 0, B may be hydrogen; a nitrile group; a silyl group; an aryl group having 6 to 12 carbon atoms; a fluorenyl group; or a hetero ring group including one or more of N, O, and S atoms and unsubstituted or substituted by an aryl group having 6 to 12 carbon atoms.

X of Formula 1 may be selected from substituent groups described in the following [Table A-1], but is not limited thereto.

TABLE A-1

| | |
|---|---|
| 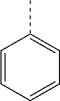 | 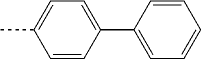 |
| 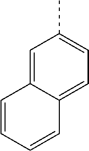 | 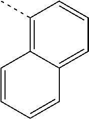 |
| 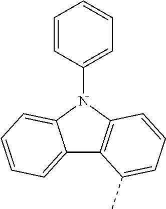 | 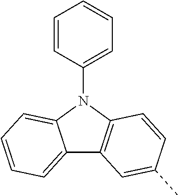 |
| 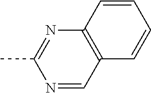 | 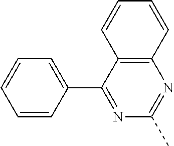 |

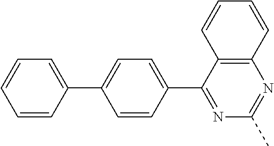

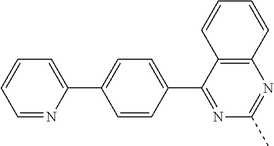

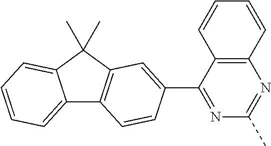

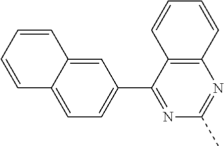

| | |
|---|---|
| 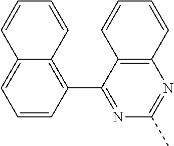 | 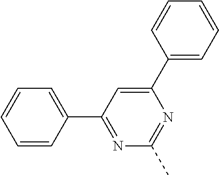 |
| 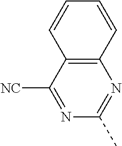 | 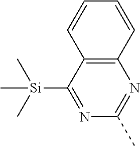 |

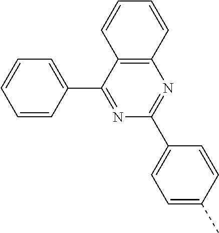

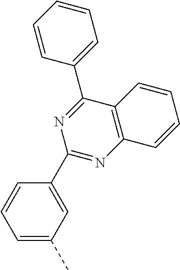

-(L1)p-(Y1)q of Formula 1 may be selected from substituent groups described in the following [Table Y-1], but is not limited thereto.

TABLE Y-1
—(L1)p—(Y1)q

| | |
|---|---|
| 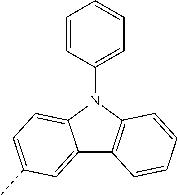 | 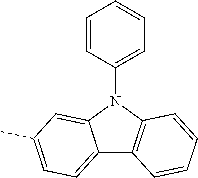 |
| 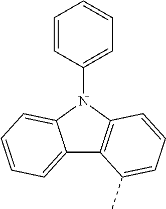 | 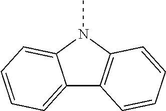 |
| 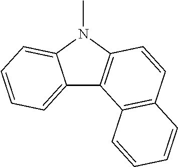 [SMILES: Cn1c2ccccc2c2c3ccccc3ccc21] | 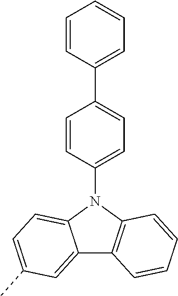 |
| 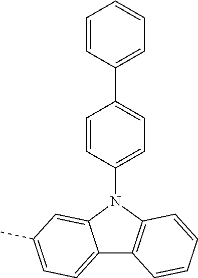 | 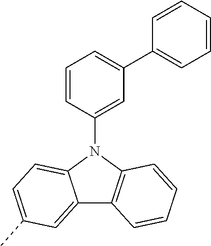 |

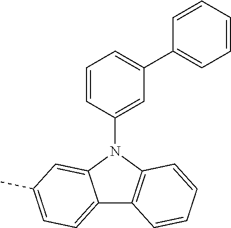

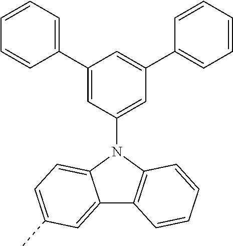

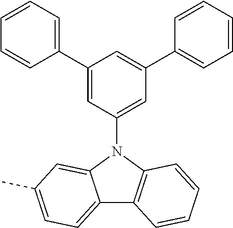

In the present specification, an alkyl group, an alkoxy group, an alkenyl group, an alkylthioxy group, an alkylsulfoxy group, and an alkylamine group may be a straight chain or a branched chain. The number of carbon atoms of the alkyl group, the alkoxy group, the alkenyl group, the alkylthioxy group, the alkylsulfoxy group, and the alkylamine group is not particularly limited, but it is preferable that the number be in the range of 1 to 30, which is the range that does not provide sterical hindrance.

In the present specification, the cycloalkyl group is not particularly limited, but the number of carbon atoms thereof is preferably 3 to 60, and particularly, it is preferable that the cycloalkyl group be a cyclopentyl group or a cyclohexyl group.

In the present specification, as the alkenyl group, the alkenyl group having 2 to 40 carbon atoms is preferable, and in detail, the alkenyl group that is substituted with the aryl group such as the stylbenzyl group and the styrenyl group is preferable, but the alkenyl group is not limited thereto.

In the present specification, the aryl group may be a monocycle or a polycycle. As examples of the monocyclic aryl group, there are the phenyl group, the biphenyl group, the terphenyl group, stilbene, and the like, and as examples of the polycyclic aryl group, there are the naphthyl group, the anthracenyl group, the phenanthryl group, the perylenyl group, the chrysenyl group, the fluoranthenyl group, and the like, but the scope of the present specification is not limited thereto.

In the present specification, the hetero ring group is a ring group having a heteroatom of O, N or S, and the number of carbon atoms thereof is not particularly limited, but it is preferable that the number of carbon atoms be 3 to 60. As examples of the hetero ring group, there are a thiophene group, a furane group, a pyrol group, an imidazole group, a triazol group, an oxazol group, an oxadiazol group, a triazol group, a pyridyl group, a pyridazine group, a quinolynyl group, an isoquinoline group, an acrydyl group and the like, and the compounds that have the following Structural Formulas are preferable, but the examples are not limited thereto.

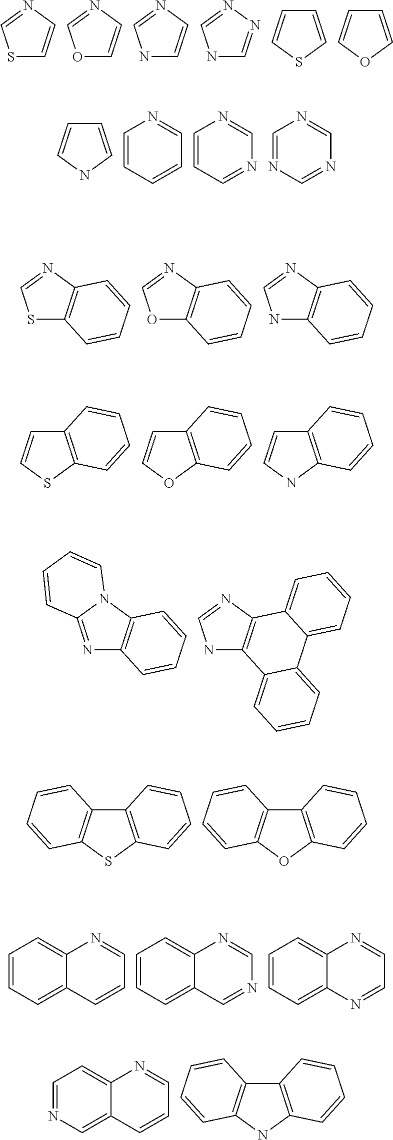

In the present specification, as examples of the halogen group, there are fluorine, chlorine, bromine, or iodine.

In the present specification, it is preferable that the fluorenyl group be the compound of the following Structural Formula, but the fluorenyl group is not limited thereto.

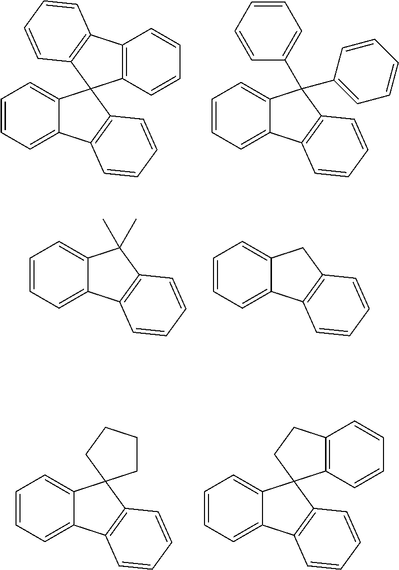

In the exemplary embodiment of the present specification, the compound represented by Formula 1 may be represented by any one of the following Formulas, but is not limited thereto.

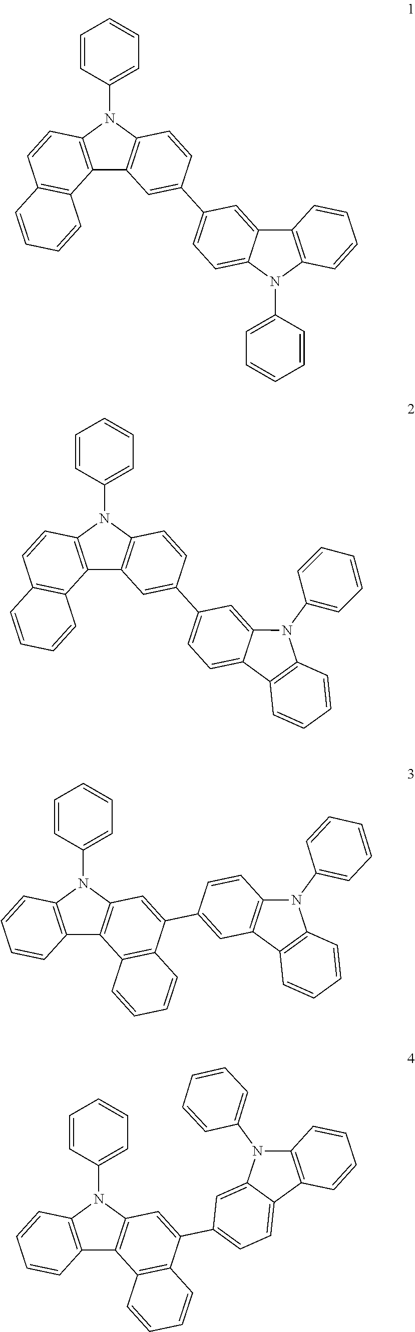 [SMILES: c1ccc(-n2c3ccccc3c3cc(-c4ccc5c(c4)c4c6ccccc6ccc4n5-c4ccccc4)ccc32)cc1 ; c1ccc(-n2c3ccccc3c3ccc(-c4ccc5c(c4)c4c6ccccc6ccc4n5-c4ccccc4)cc32)cc1 ; c1ccc(-n2c3ccccc3c3cc(-c4cc5c(c6ccccc46)c4ccccc4n5-c4ccccc4)ccc32)cc1 ; c1ccc(-n2c3ccccc3c3ccc(-c4cc5c(c6ccccc46)c4ccccc4n5-c4ccccc4)cc32)cc1]

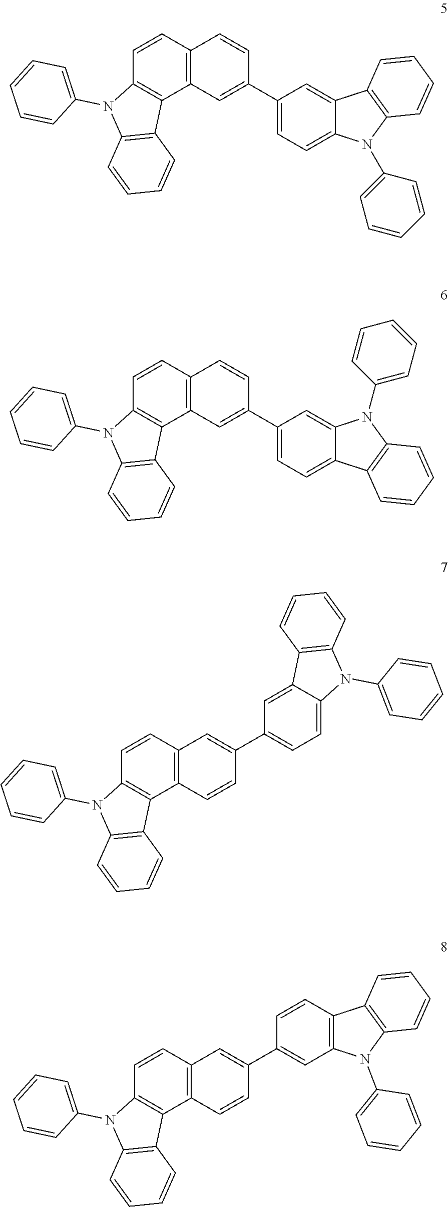 [SMILES: c1ccc(-n2c3ccccc3c3cc(-c4ccc5ccc6c(c5c4)c4ccccc4n6-c4ccccc4)ccc32)cc1 ; c1ccc(-n2c3ccccc3c3ccc(-c4ccc5ccc6c(c5c4)c4ccccc4n6-c4ccccc4)cc32)cc1 ; c1ccc(-n2c3ccccc3c3cc(-c4ccc5c(ccc6c5c5ccccc5n6-c5ccccc5)c4)ccc32)cc1 ; c1ccc(-n2c3ccccc3c3ccc(-c4ccc5c(ccc6c5c5ccccc5n6-c5ccccc5)c4)cc32)cc1]

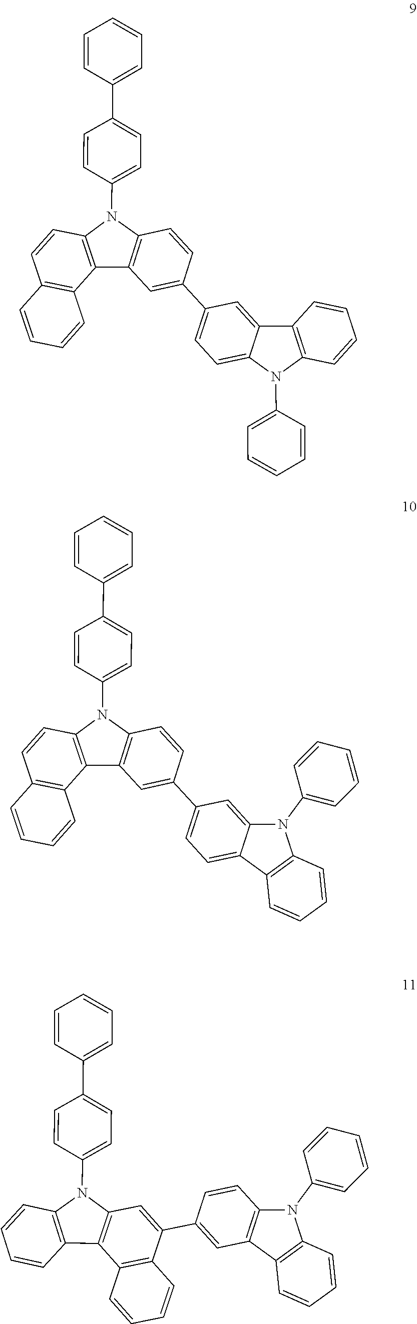 [SMILES: c1ccc(-c2ccc(-n3c4ccc(-c5ccc6c(c5)c5ccccc5n6-c5ccccc5)cc4c4c5ccccc5ccc43)cc2)cc1 ; c1ccc(-c2ccc(-n3c4ccc(-c5ccc6c7ccccc7n(-c7ccccc7)c6c5)cc4c4c5ccccc5ccc43)cc2)cc1 ; c1ccc(-c2ccc(-n3c4ccccc4c4c5ccccc5c(-c5ccc6c(c5)c5ccccc5n6-c5ccccc5)cc43)cc2)cc1]

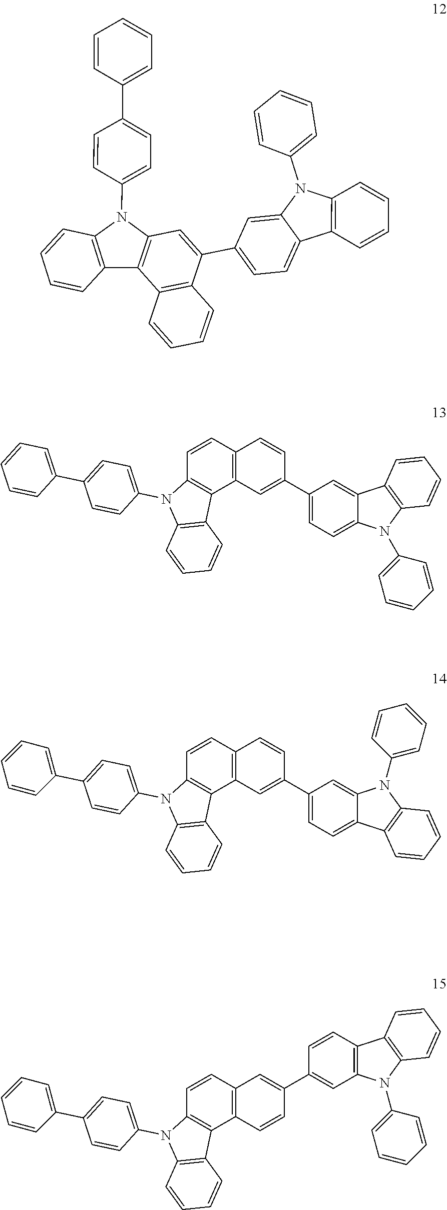 [SMILES: c1ccc(-c2ccc(-n3c4ccccc4c4c5ccccc5c(-c5ccc6c7ccccc7n(-c7ccccc7)c6c5)cc43)cc2)cc1 ; c1ccc(-c2ccc(-n3c4ccccc4c4c5cc(-c6ccc7c(c6)c6ccccc6n7-c6ccccc6)ccc5ccc43)cc2)cc1 ; c1ccc(-c2ccc(-n3c4ccccc4c4c5cc(-c6ccc7c8ccccc8n(-c8ccccc8)c7c6)ccc5ccc43)cc2)cc1 ; c1ccc(-c2ccc(-n3c4ccccc4c4c5ccc(-c6ccc7c8ccccc8n(-c8ccccc8)c7c6)cc5ccc43)cc2)cc1]

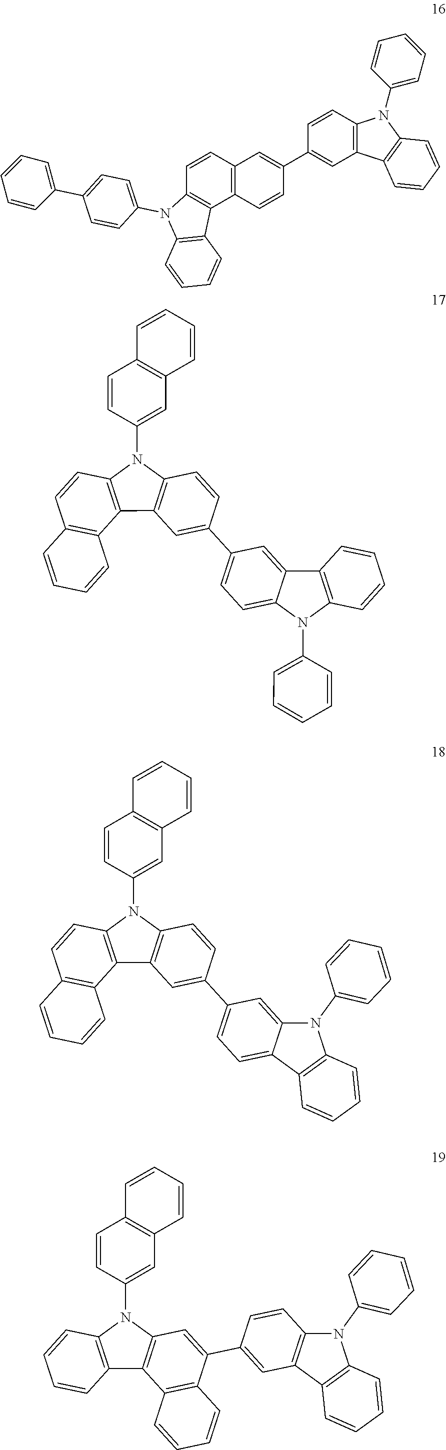

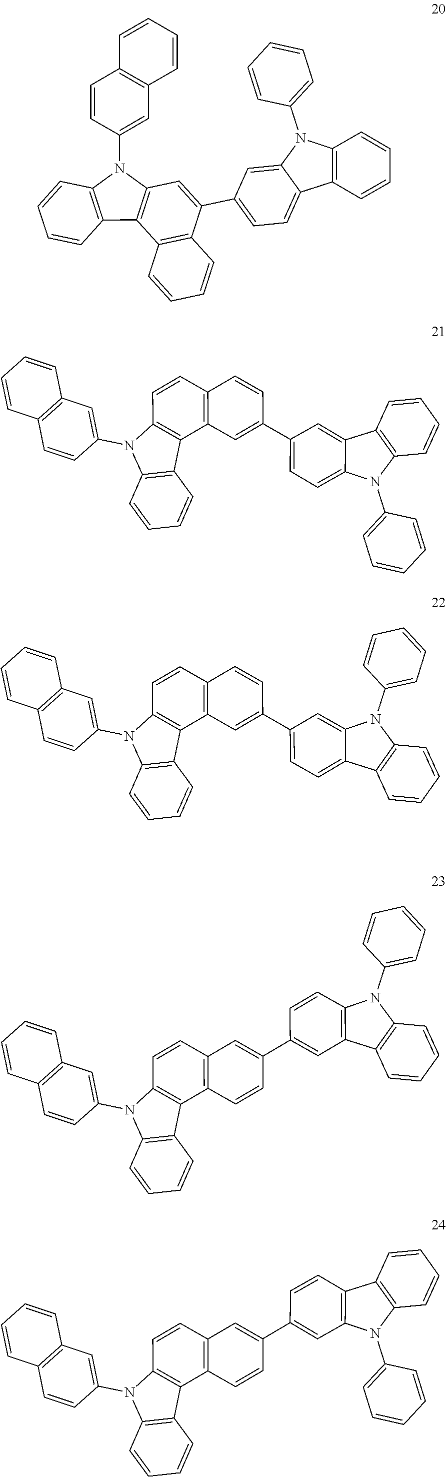 [SMILES: c1ccc(-n2c3ccccc3c3ccc(-c4cc5c(c6ccccc46)c4ccccc4n5-c4ccc5ccccc5c4)cc32)cc1 ; c1ccc(-n2c3ccccc3c3cc(-c4ccc5ccc6c(c5c4)c4ccccc4n6-c4ccc5ccccc5c4)ccc32)cc1 ; c1ccc(-n2c3ccccc3c3ccc(-c4ccc5ccc6c(c5c4)c4ccccc4n6-c4ccc5ccccc5c4)cc32)cc1 ; c1ccc(-n2c3ccccc3c3cc(-c4ccc5c(ccc6c5c5ccccc5n6-c5ccc6ccccc6c5)c4)ccc32)cc1 ; c1ccc(-n2c3ccccc3c3ccc(-c4ccc5c(ccc6c5c5ccccc5n6-c5ccc6ccccc6c5)c4)cc32)cc1]

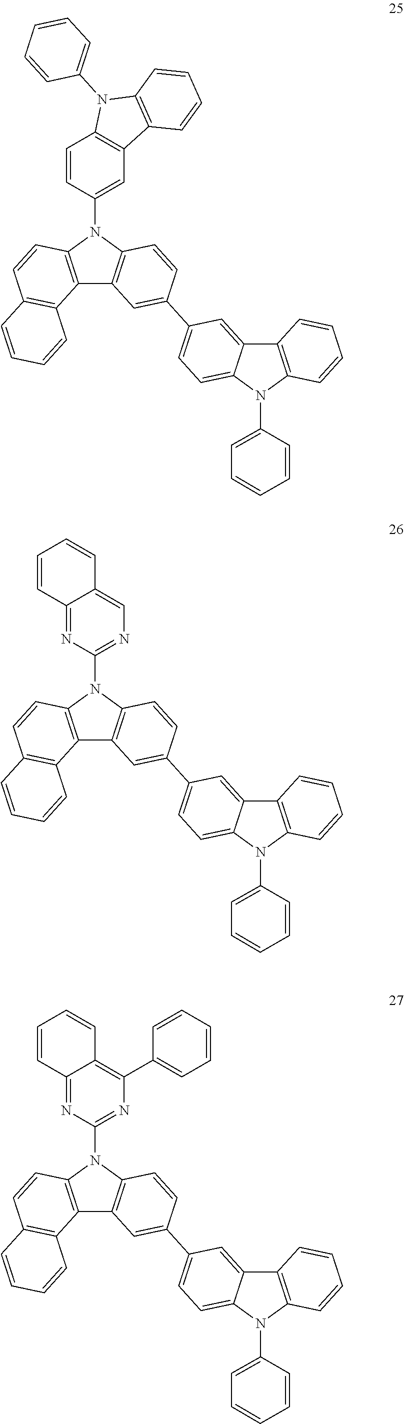 [SMILES: c1ccc(-n2c3ccccc3c3cc(-c4ccc5c(c4)c4c6ccccc6ccc4n5-c4ccc5c(c4)c4ccccc4n5-c4ccccc4)ccc32)cc1 ; c1ccc(-n2c3ccccc3c3cc(-c4ccc5c(c4)c4c6ccccc6ccc4n5-c4ncc5ccccc5n4)ccc32)cc1 ; c1ccc(-c2nc(-n3c4ccc(-c5ccc6c(c5)c5ccccc5n6-c5ccccc5)cc4c4c5ccccc5ccc43)nc3ccccc23)cc1]

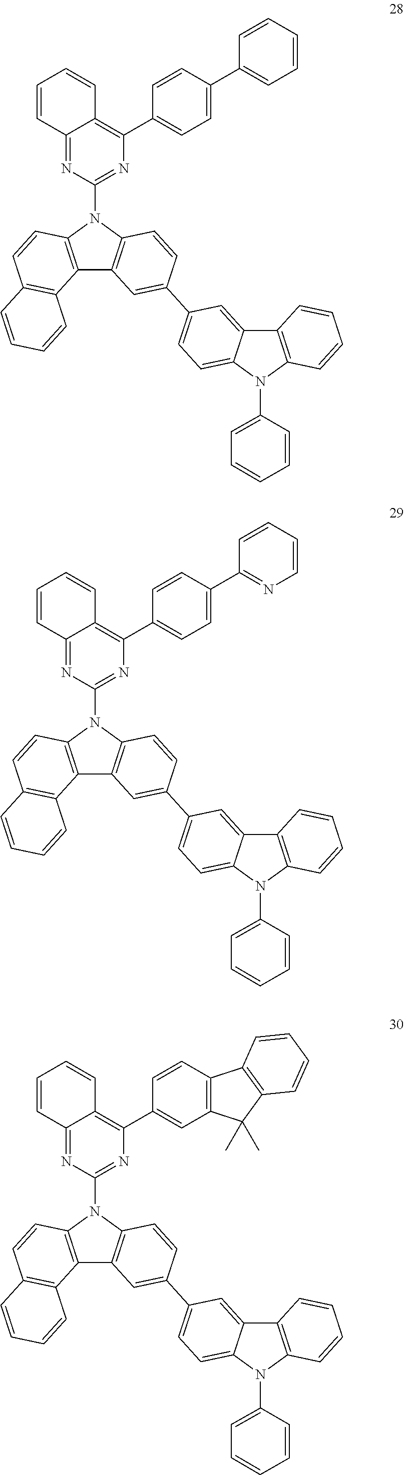

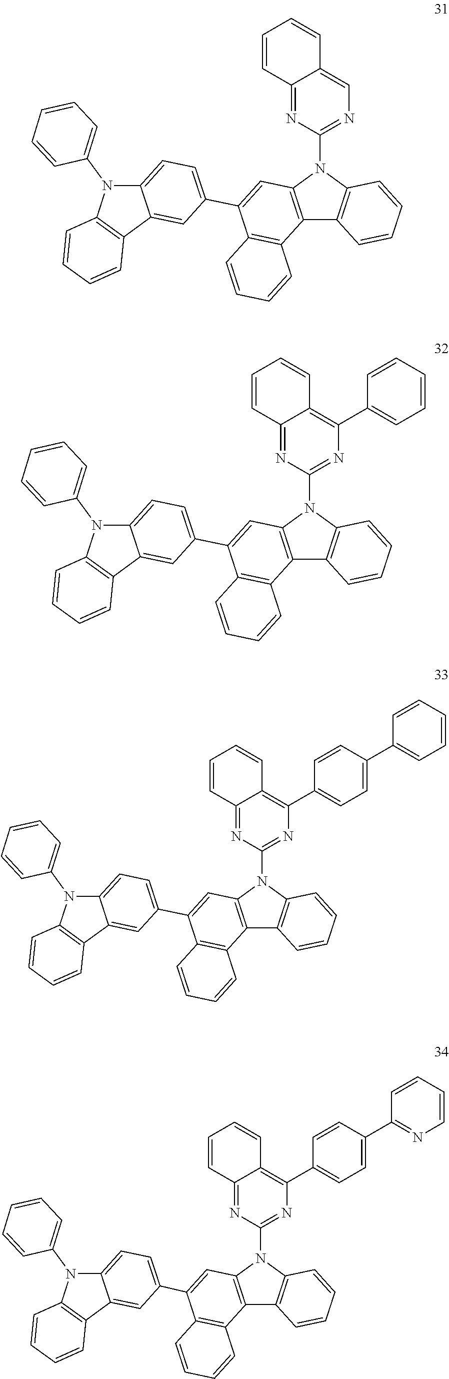 [SMILES: c1ccc(-n2c3ccccc3c3cc(-c4cc5c(c6ccccc46)c4ccccc4n5-c4ncc5ccccc5n4)ccc32)cc1 ; c1ccc(-c2nc(-n3c4ccccc4c4c5ccccc5c(-c5ccc6c(c5)c5ccccc5n6-c5ccccc5)cc43)nc3ccccc23)cc1 ; c1ccc(-c2ccc(-c3nc(-n4c5ccccc5c5c6ccccc6c(-c6ccc7c(c6)c6ccccc6n7-c6ccccc6)cc54)nc4ccccc34)cc2)cc1 ; c1ccc(-n2c3ccccc3c3cc(-c4cc5c(c6ccccc46)c4ccccc4n5-c4nc(-c5ccc(-c6ccccn6)cc5)c5ccccc5n4)ccc32)cc1]

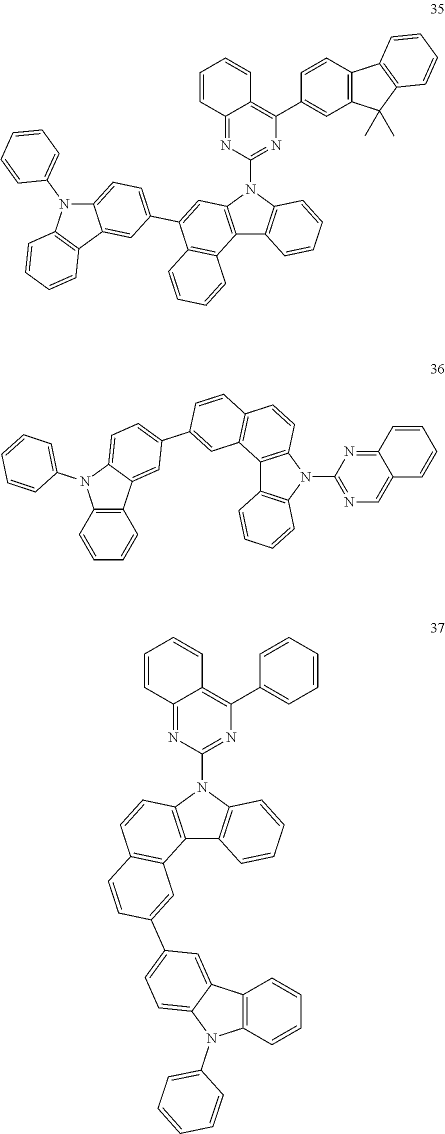 [SMILES: CC1(C)c2ccccc2-c2ccc(-c3nc(-n4c5ccccc5c5c6ccccc6c(-c6ccc7c(c6)c6ccccc6n7-c6ccccc6)cc54)nc4ccccc34)cc21 ; c1ccc(-n2c3ccccc3c3cc(-c4ccc5ccc6c(c5c4)c4ccccc4n6-c4ncc5ccccc5n4)ccc32)cc1 ; c1ccc(-c2nc(-n3c4ccccc4c4c5cc(-c6ccc7c(c6)c6ccccc6n7-c6ccccc6)ccc5ccc43)nc3ccccc23)cc1]

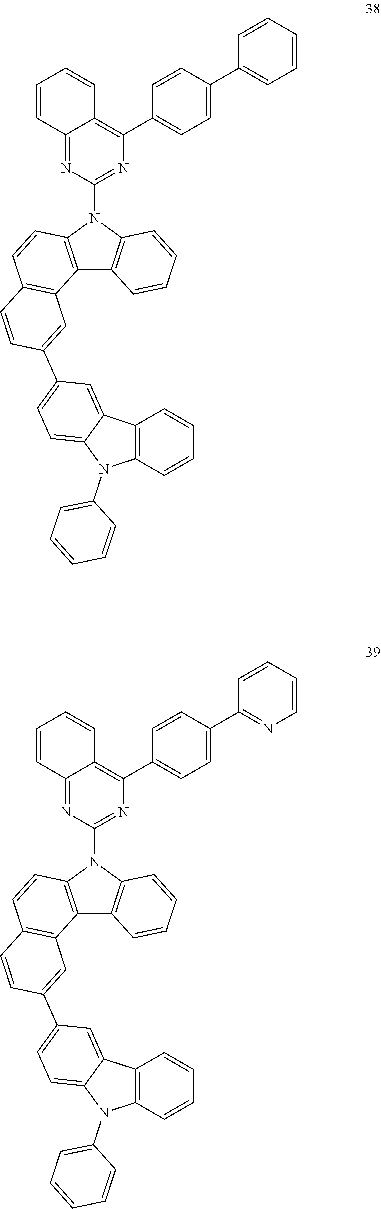 [SMILES: c1ccc(-c2ccc(-c3nc(-n4c5ccccc5c5c6cc(-c7ccc8c(c7)c7ccccc7n8-c7ccccc7)ccc6ccc54)nc4ccccc34)cc2)cc1 ; c1ccc(-n2c3ccccc3c3cc(-c4ccc5ccc6c(c5c4)c4ccccc4n6-c4nc(-c5ccc(-c6ccccn6)cc5)c5ccccc5n4)ccc32)cc1]

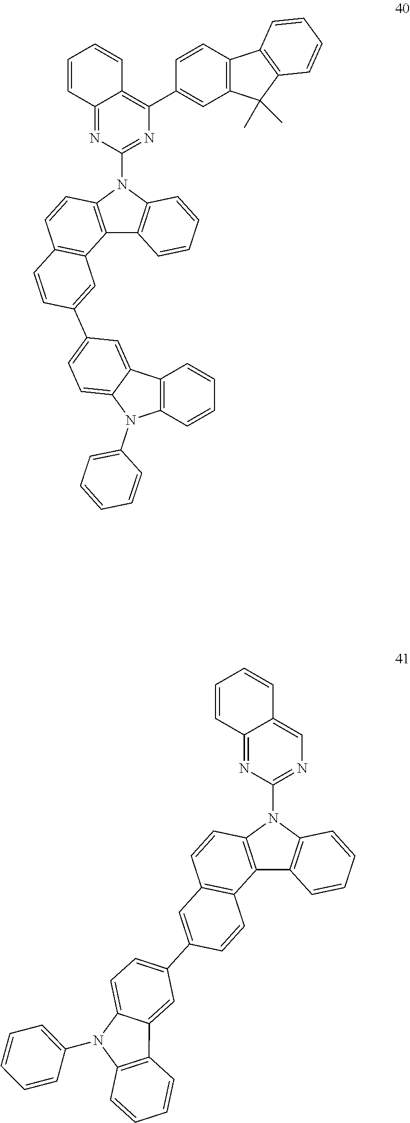 [SMILES: CC1(C)c2ccccc2-c2ccc(-c3nc(-n4c5ccccc5c5c6cc(-c7ccc8c(c7)c7ccccc7n8-c7ccccc7)ccc6ccc54)nc4ccccc34)cc21 ; c1ccc(-n2c3ccccc3c3cc(-c4ccc5c(ccc6c5c5ccccc5n6-c5ncc6ccccc6n5)c4)ccc32)cc1]

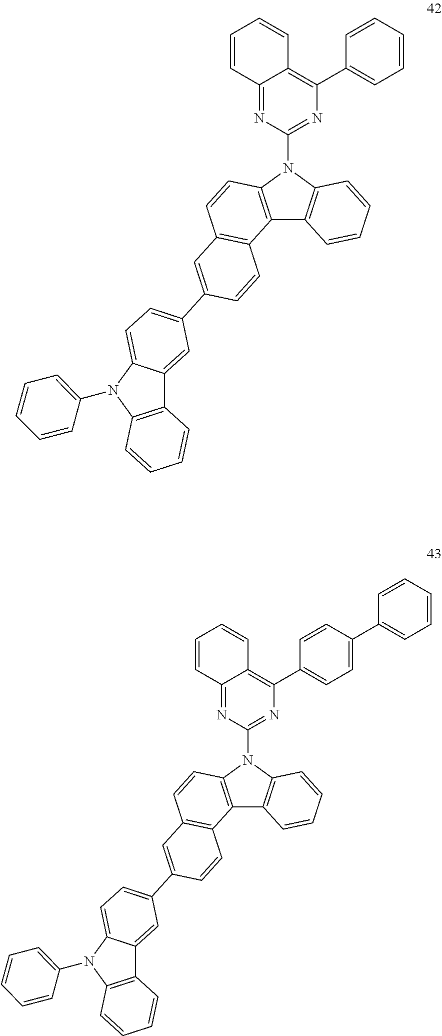 [SMILES: c1ccc(-c2nc(-n3c4ccccc4c4c5ccc(-c6ccc7c(c6)c6ccccc6n7-c6ccccc6)cc5ccc43)nc3ccccc23)cc1 ; c1ccc(-c2ccc(-c3nc(-n4c5ccccc5c5c6ccc(-c7ccc8c(c7)c7ccccc7n8-c7ccccc7)cc6ccc54)nc4ccccc34)cc2)cc1]

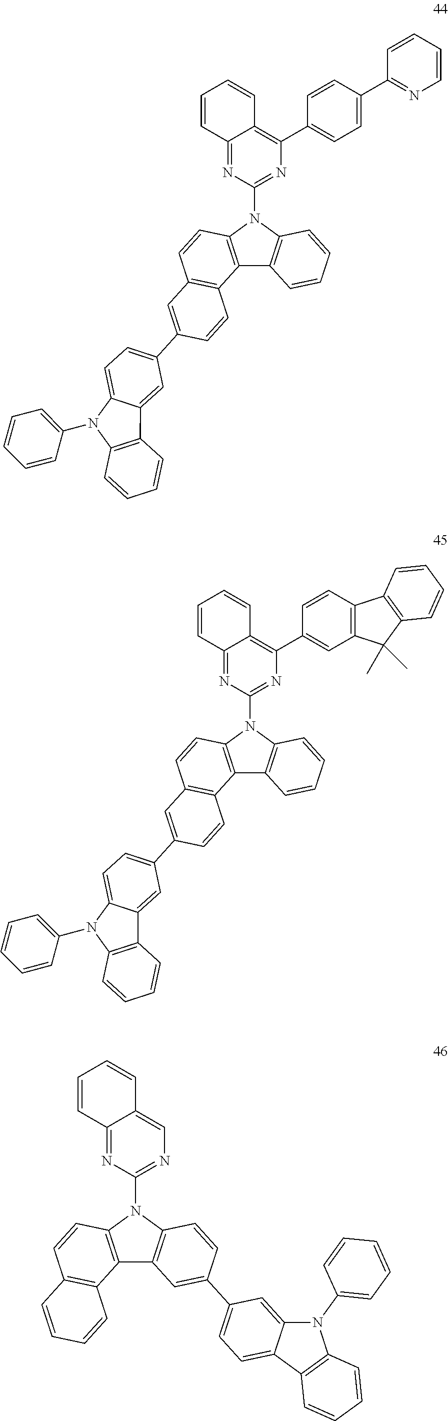 [SMILES: c1ccc(-n2c3ccccc3c3cc(-c4ccc5c(ccc6c5c5ccccc5n6-c5nc(-c6ccc(-c7ccccn7)cc6)c6ccccc6n5)c4)ccc32)cc1 ; CC1(C)c2ccccc2-c2ccc(-c3nc(-n4c5ccccc5c5c6ccc(-c7ccc8c(c7)c7ccccc7n8-c7ccccc7)cc6ccc54)nc4ccccc34)cc21 ; c1ccc(-n2c3ccccc3c3ccc(-c4ccc5c(c4)c4c6ccccc6ccc4n5-c4ncc5ccccc5n4)cc32)cc1]

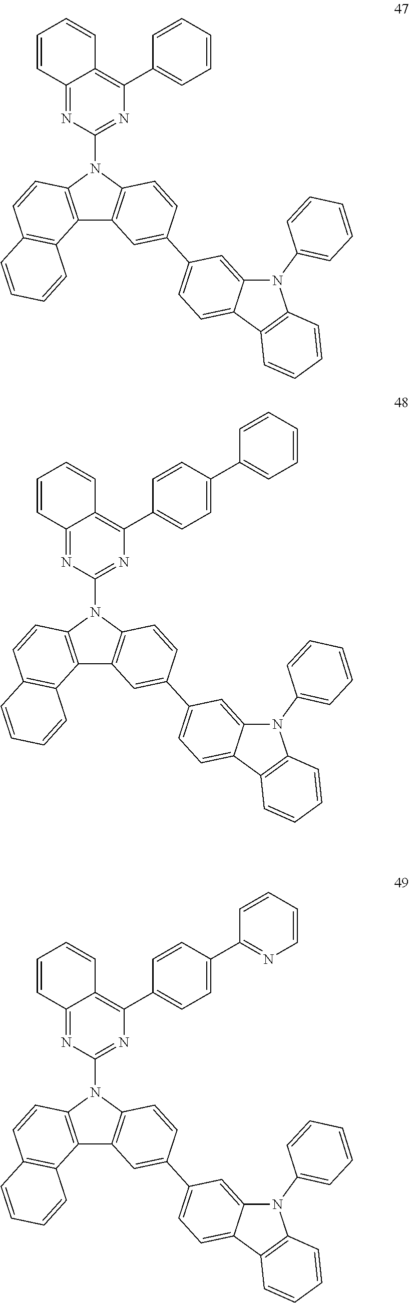

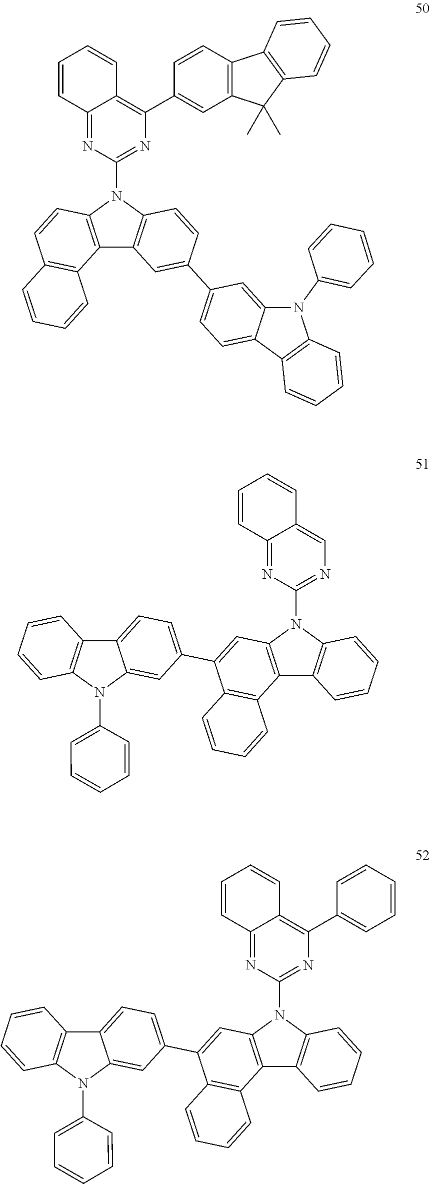 [SMILES: CC1(C)c2ccccc2-c2ccc(-c3nc(-n4c5ccc(-c6ccc7c8ccccc8n(-c8ccccc8)c7c6)cc5c5c6ccccc6ccc54)nc4ccccc34)cc21 ; c1ccc(-n2c3ccccc3c3ccc(-c4cc5c(c6ccccc46)c4ccccc4n5-c4ncc5ccccc5n4)cc32)cc1 ; c1ccc(-c2nc(-n3c4ccccc4c4c5ccccc5c(-c5ccc6c7ccccc7n(-c7ccccc7)c6c5)cc43)nc3ccccc23)cc1]

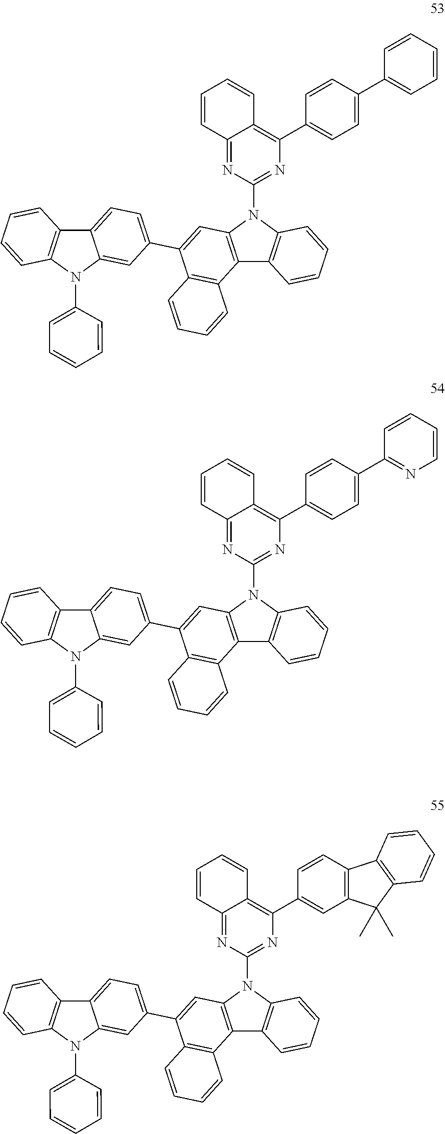 [SMILES: c1ccc(-c2ccc(-c3nc(-n4c5ccccc5c5c6ccccc6c(-c6ccc7c8ccccc8n(-c8ccccc8)c7c6)cc54)nc4ccccc34)cc2)cc1 ; c1ccc(-n2c3ccccc3c3ccc(-c4cc5c(c6ccccc46)c4ccccc4n5-c4nc(-c5ccc(-c6ccccn6)cc5)c5ccccc5n4)cc32)cc1 ; CC1(C)c2ccccc2-c2ccc(-c3nc(-n4c5ccccc5c5c6ccccc6c(-c6ccc7c8ccccc8n(-c8ccccc8)c7c6)cc54)nc4ccccc34)cc21]

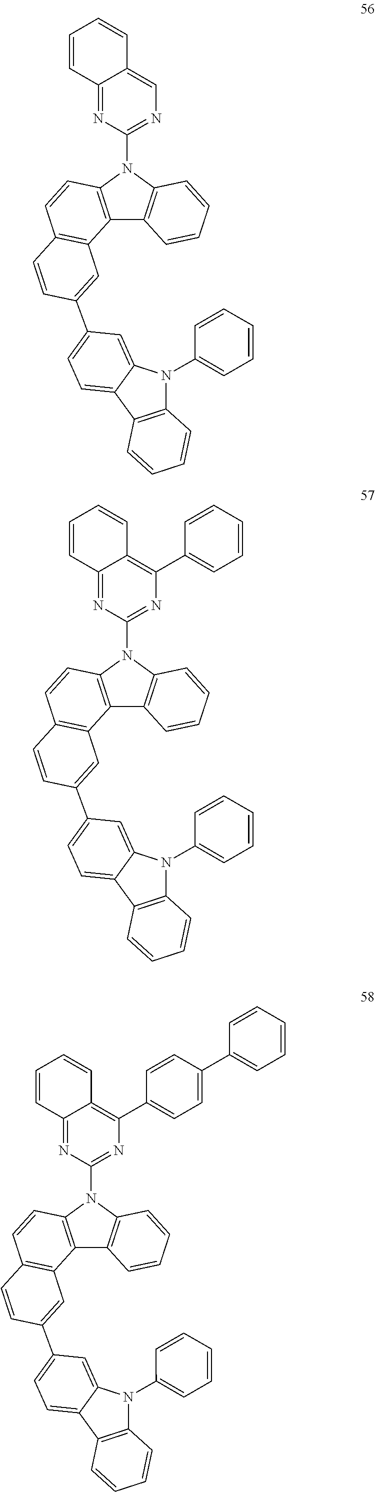 [SMILES: c1ccc(-n2c3ccccc3c3ccc(-c4ccc5ccc6c(c5c4)c4ccccc4n6-c4ncc5ccccc5n4)cc32)cc1 ; c1ccc(-c2nc(-n3c4ccccc4c4c5cc(-c6ccc7c8ccccc8n(-c8ccccc8)c7c6)ccc5ccc43)nc3ccccc23)cc1 ; c1ccc(-c2ccc(-c3nc(-n4c5ccccc5c5c6cc(-c7ccc8c9ccccc9n(-c9ccccc9)c8c7)ccc6ccc54)nc4ccccc34)cc2)cc1]

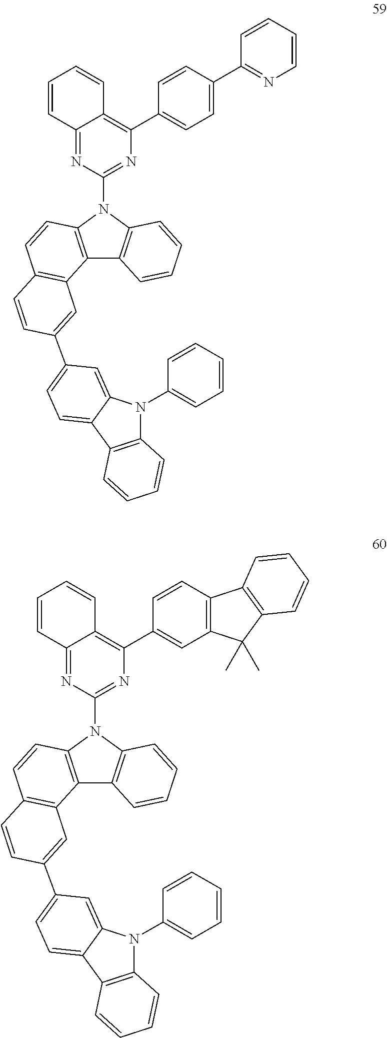 [SMILES: c1ccc(-n2c3ccccc3c3ccc(-c4ccc5ccc6c(c5c4)c4ccccc4n6-c4nc(-c5ccc(-c6ccccn6)cc5)c5ccccc5n4)cc32)cc1 ; CC1(C)c2ccccc2-c2ccc(-c3nc(-n4c5ccccc5c5c6cc(-c7ccc8c9ccccc9n(-c9ccccc9)c8c7)ccc6ccc54)nc4ccccc34)cc21]

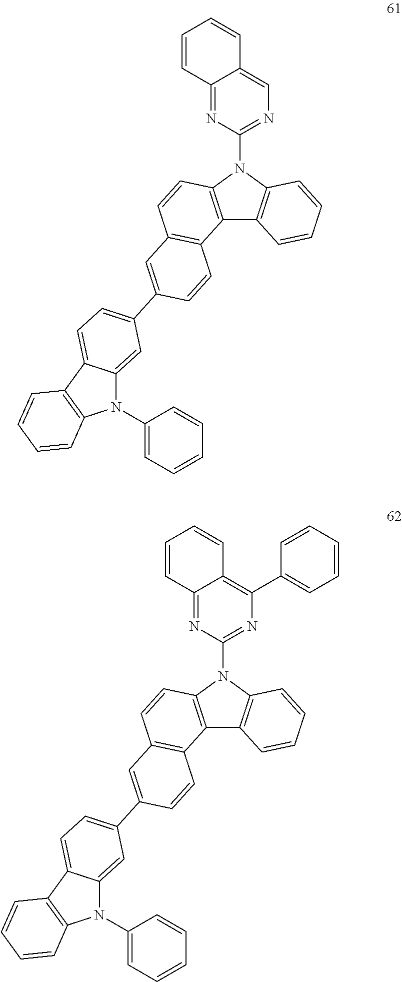 [SMILES: c1ccc(-n2c3ccccc3c3ccc(-c4ccc5c(ccc6c5c5ccccc5n6-c5ncc6ccccc6n5)c4)cc32)cc1 ; c1ccc(-c2nc(-n3c4ccccc4c4c5ccc(-c6ccc7c8ccccc8n(-c8ccccc8)c7c6)cc5ccc43)nc3ccccc23)cc1]

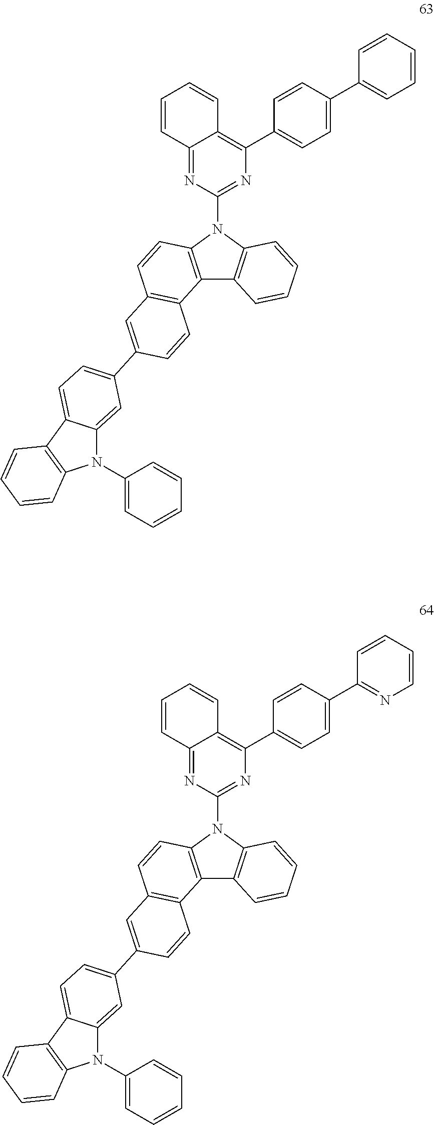 [SMILES: c1ccc(-c2ccc(-c3nc(-n4c5ccccc5c5c6ccc(-c7ccc8c9ccccc9n(-c9ccccc9)c8c7)cc6ccc54)nc4ccccc34)cc2)cc1 ; c1ccc(-n2c3ccccc3c3ccc(-c4ccc5c(ccc6c5c5ccccc5n6-c5nc(-c6ccc(-c7ccccn7)cc6)c6ccccc6n5)c4)cc32)cc1]

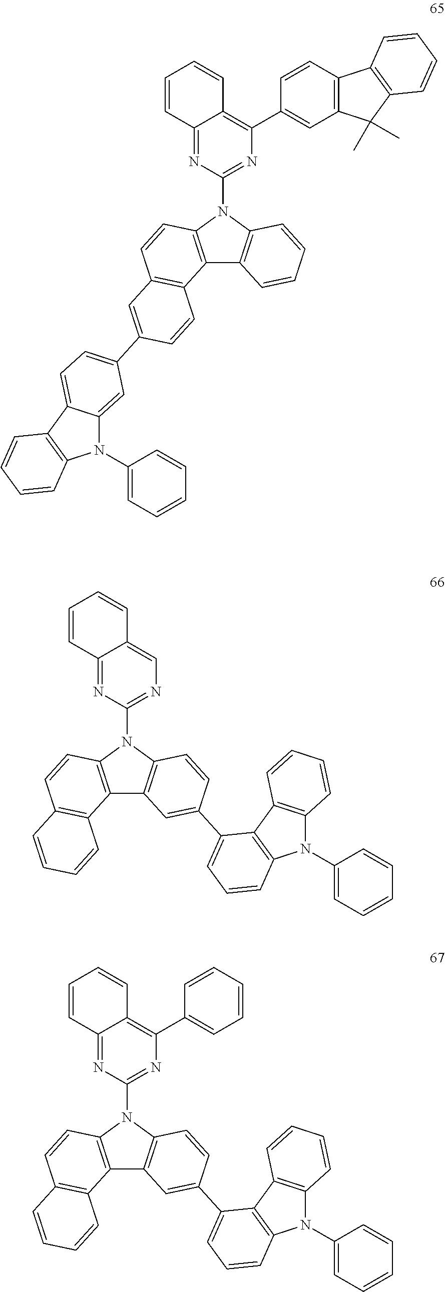 [SMILES: CC1(C)c2ccccc2-c2ccc(-c3nc(-n4c5ccccc5c5c6ccc(-c7ccc8c9ccccc9n(-c9ccccc9)c8c7)cc6ccc54)nc4ccccc34)cc21 ; c1ccc(-n2c3ccccc3c3c(-c4ccc5c(c4)c4c6ccccc6ccc4n5-c4ncc5ccccc5n4)cccc32)cc1 ; c1ccc(-c2nc(-n3c4ccc(-c5cccc6c5c5ccccc5n6-c5ccccc5)cc4c4c5ccccc5ccc43)nc3ccccc23)cc1]

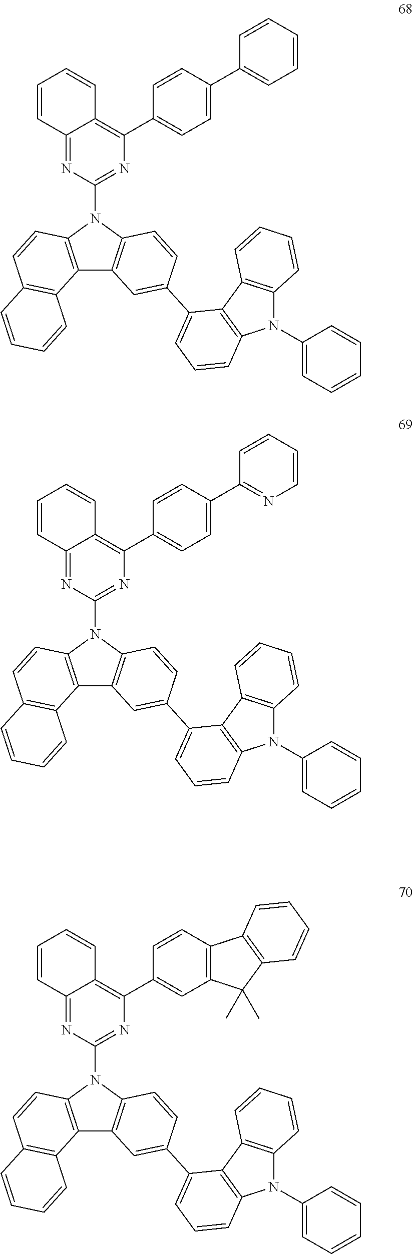 [SMILES: c1ccc(-c2ccc(-c3nc(-n4c5ccc(-c6cccc7c6c6ccccc6n7-c6ccccc6)cc5c5c6ccccc6ccc54)nc4ccccc34)cc2)cc1 ; c1ccc(-n2c3ccccc3c3c(-c4ccc5c(c4)c4c6ccccc6ccc4n5-c4nc(-c5ccc(-c6ccccn6)cc5)c5ccccc5n4)cccc32)cc1 ; CC1(C)c2ccccc2-c2ccc(-c3nc(-n4c5ccc(-c6cccc7c6c6ccccc6n7-c6ccccc6)cc5c5c6ccccc6ccc54)nc4ccccc34)cc21]

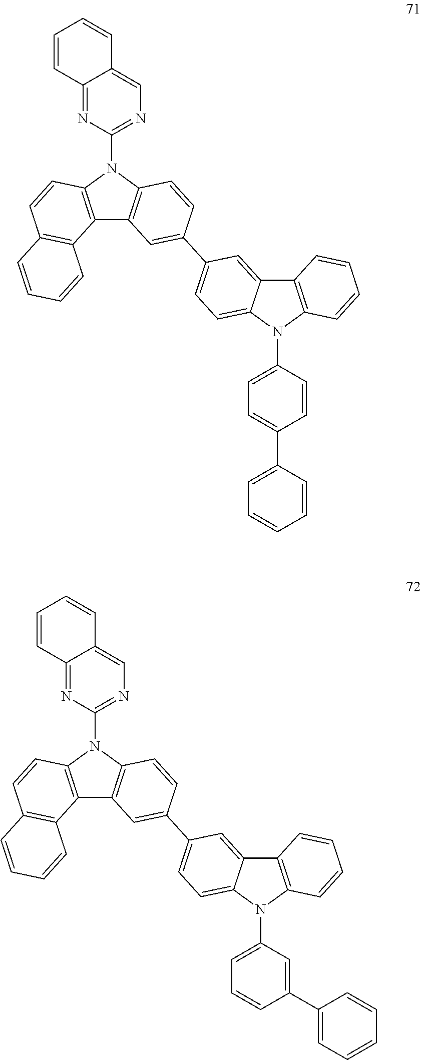 [SMILES: c1ccc(-c2ccc(-n3c4ccccc4c4cc(-c5ccc6c(c5)c5c7ccccc7ccc5n6-c5ncc6ccccc6n5)ccc43)cc2)cc1 ; c1ccc(-c2cccc(-n3c4ccccc4c4cc(-c5ccc6c(c5)c5c7ccccc7ccc5n6-c5ncc6ccccc6n5)ccc43)c2)cc1]

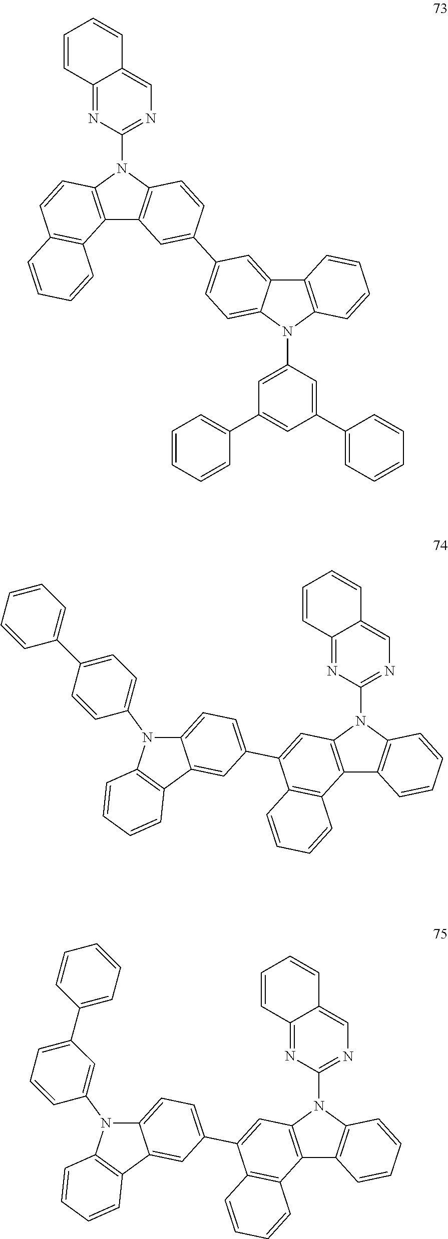 [SMILES: c1ccc(-c2cc(-c3ccccc3)cc(-n3c4ccccc4c4cc(-c5ccc6c(c5)c5c7ccccc7ccc5n6-c5ncc6ccccc6n5)ccc43)c2)cc1 ; c1ccc(-c2ccc(-n3c4ccccc4c4cc(-c5cc6c(c7ccccc57)c5ccccc5n6-c5ncc6ccccc6n5)ccc43)cc2)cc1 ; c1ccc(-c2cccc(-n3c4ccccc4c4cc(-c5cc6c(c7ccccc57)c5ccccc5n6-c5ncc6ccccc6n5)ccc43)c2)cc1]

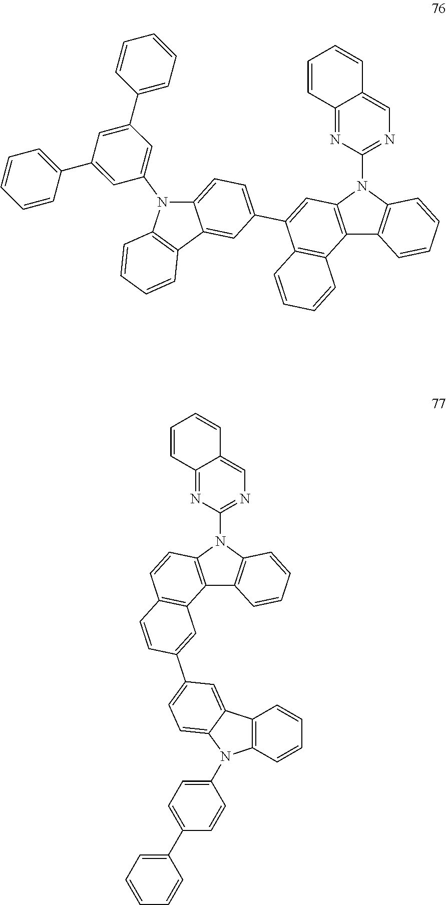 [SMILES: c1ccc(-c2cc(-c3ccccc3)cc(-n3c4ccccc4c4cc(-c5cc6c(c7ccccc57)c5ccccc5n6-c5ncc6ccccc6n5)ccc43)c2)cc1 ; c1ccc(-c2ccc(-n3c4ccccc4c4cc(-c5ccc6ccc7c(c6c5)c5ccccc5n7-c5ncc6ccccc6n5)ccc43)cc2)cc1]

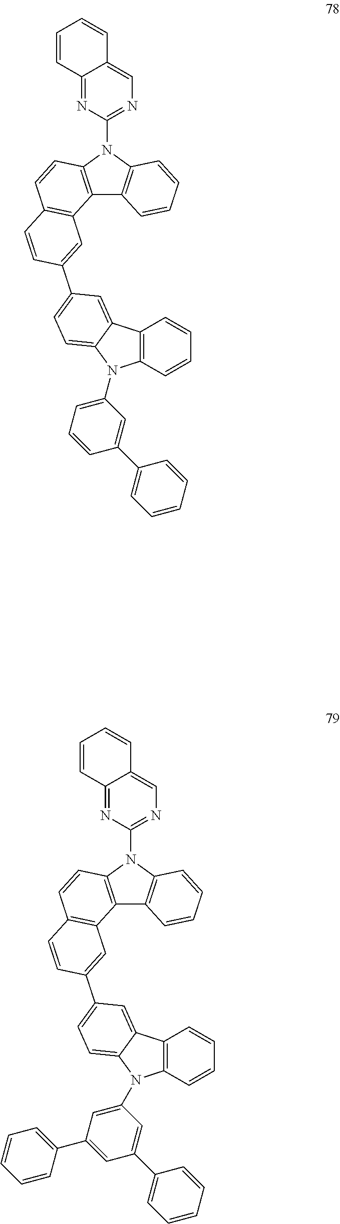 [SMILES: c1ccc(-c2cccc(-n3c4ccccc4c4cc(-c5ccc6ccc7c(c6c5)c5ccccc5n7-c5ncc6ccccc6n5)ccc43)c2)cc1 ; c1ccc(-c2cc(-c3ccccc3)cc(-n3c4ccccc4c4cc(-c5ccc6ccc7c(c6c5)c5ccccc5n7-c5ncc6ccccc6n5)ccc43)c2)cc1]

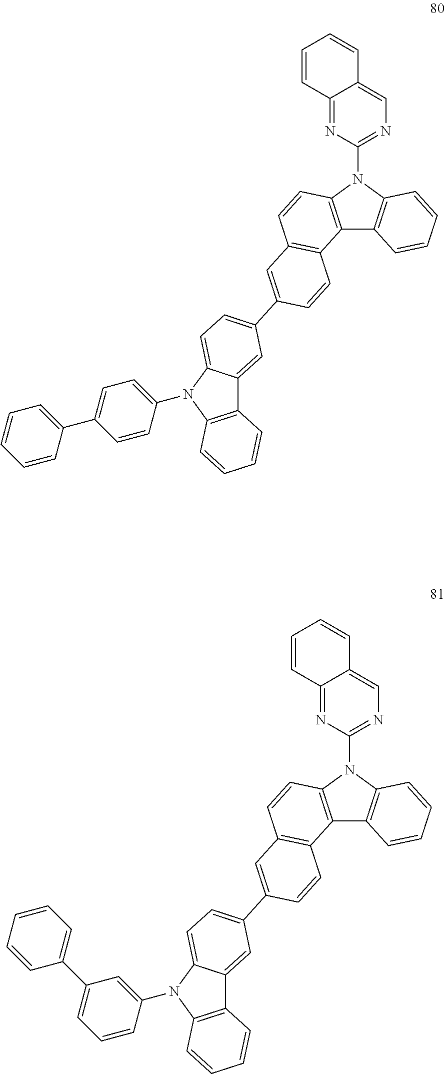 [SMILES: c1ccc(-c2ccc(-n3c4ccccc4c4cc(-c5ccc6c(ccc7c6c6ccccc6n7-c6ncc7ccccc7n6)c5)ccc43)cc2)cc1 ; c1ccc(-c2cccc(-n3c4ccccc4c4cc(-c5ccc6c(ccc7c6c6ccccc6n7-c6ncc7ccccc7n6)c5)ccc43)c2)cc1]

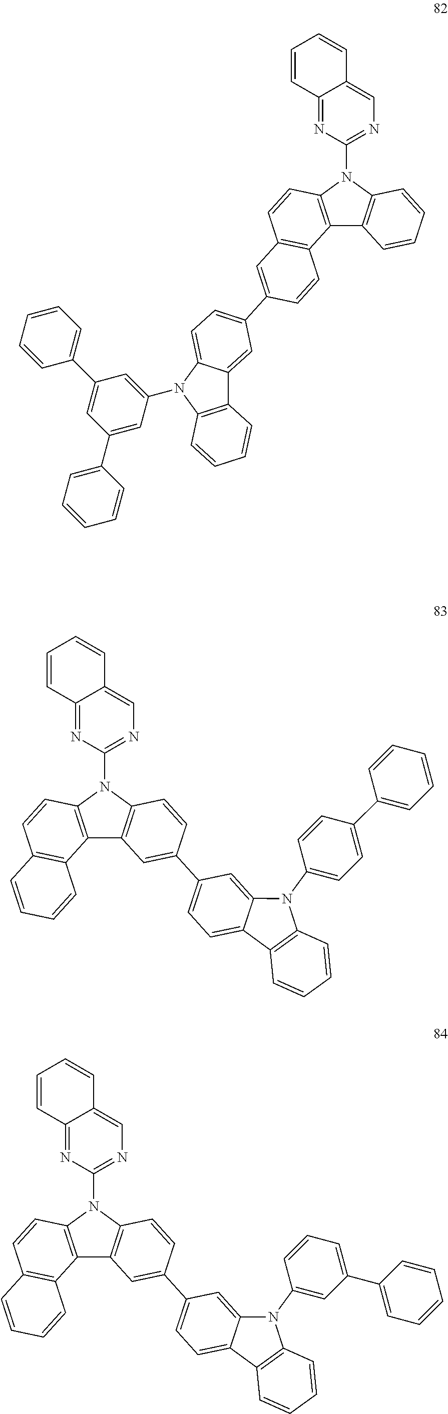 [SMILES: c1ccc(-c2cc(-c3ccccc3)cc(-n3c4ccccc4c4cc(-c5ccc6c(ccc7c6c6ccccc6n7-c6ncc7ccccc7n6)c5)ccc43)c2)cc1 ; c1ccc(-c2ccc(-n3c4ccccc4c4ccc(-c5ccc6c(c5)c5c7ccccc7ccc5n6-c5ncc6ccccc6n5)cc43)cc2)cc1 ; c1ccc(-c2cccc(-n3c4ccccc4c4ccc(-c5ccc6c(c5)c5c7ccccc7ccc5n6-c5ncc6ccccc6n5)cc43)c2)cc1]

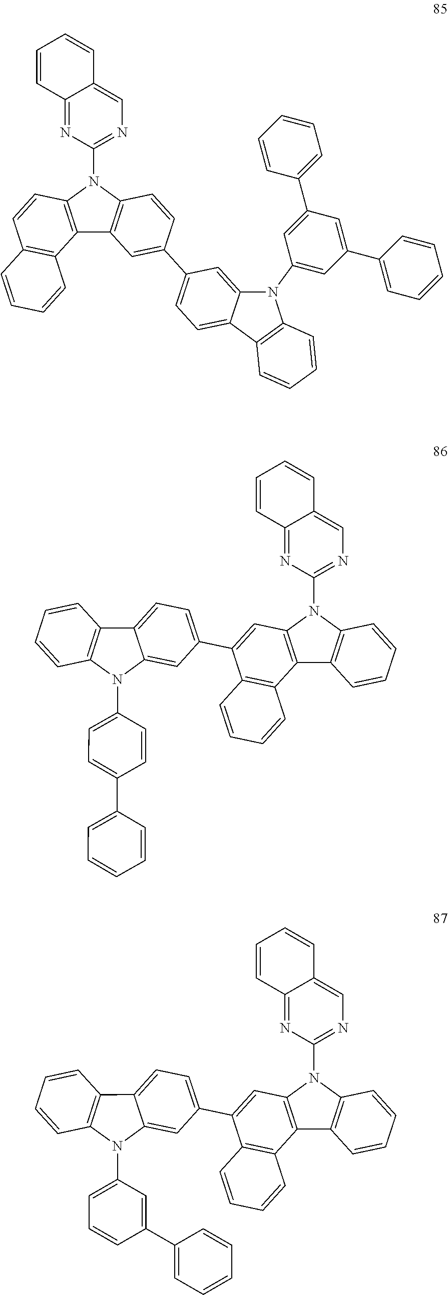 [SMILES: c1ccc(-c2cc(-c3ccccc3)cc(-n3c4ccccc4c4ccc(-c5ccc6c(c5)c5c7ccccc7ccc5n6-c5ncc6ccccc6n5)cc43)c2)cc1 ; c1ccc(-c2ccc(-n3c4ccccc4c4ccc(-c5cc6c(c7ccccc57)c5ccccc5n6-c5ncc6ccccc6n5)cc43)cc2)cc1 ; c1ccc(-c2cccc(-n3c4ccccc4c4ccc(-c5cc6c(c7ccccc57)c5ccccc5n6-c5ncc6ccccc6n5)cc43)c2)cc1]

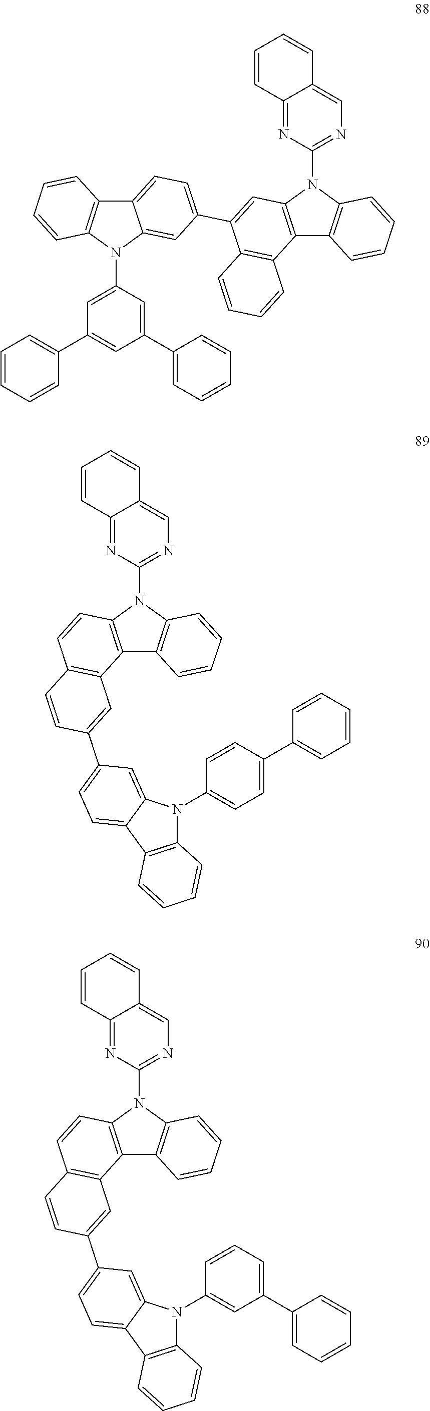 [SMILES: c1ccc(-c2cc(-c3ccccc3)cc(-n3c4ccccc4c4ccc(-c5cc6c(c7ccccc57)c5ccccc5n6-c5ncc6ccccc6n5)cc43)c2)cc1 ; c1ccc(-c2ccc(-n3c4ccccc4c4ccc(-c5ccc6ccc7c(c6c5)c5ccccc5n7-c5ncc6ccccc6n5)cc43)cc2)cc1 ; c1ccc(-c2cccc(-n3c4ccccc4c4ccc(-c5ccc6ccc7c(c6c5)c5ccccc5n7-c5ncc6ccccc6n5)cc43)c2)cc1]

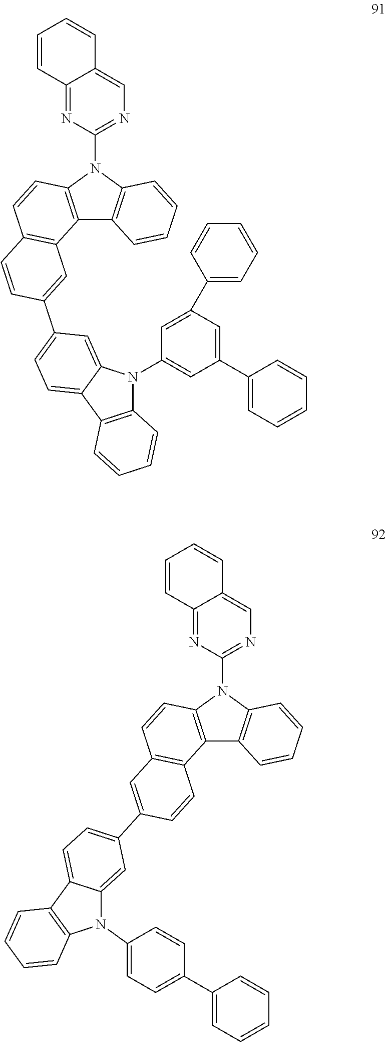 [SMILES: c1ccc(-c2cc(-c3ccccc3)cc(-n3c4ccccc4c4ccc(-c5ccc6ccc7c(c6c5)c5ccccc5n7-c5ncc6ccccc6n5)cc43)c2)cc1 ; c1ccc(-c2ccc(-n3c4ccccc4c4ccc(-c5ccc6c(ccc7c6c6ccccc6n7-c6ncc7ccccc7n6)c5)cc43)cc2)cc1]

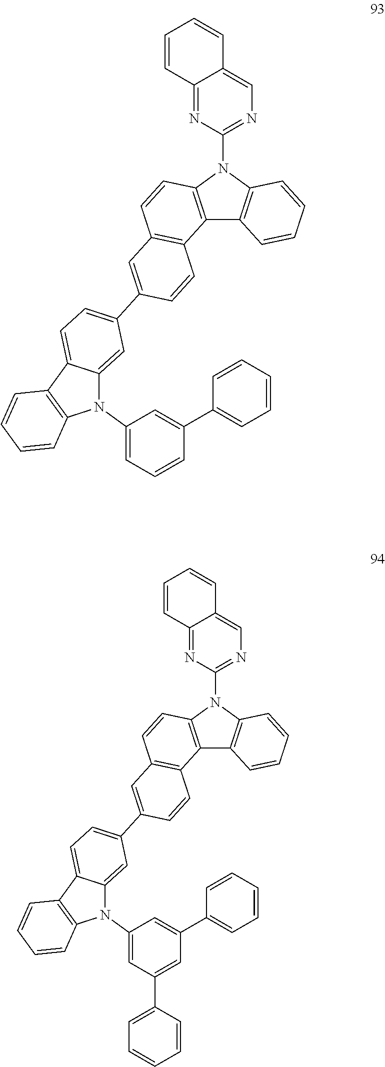 [SMILES: c1ccc(-c2cccc(-n3c4ccccc4c4ccc(-c5ccc6c(ccc7c6c6ccccc6n7-c6ncc7ccccc7n6)c5)cc43)c2)cc1 ; c1ccc(-c2cc(-c3ccccc3)cc(-n3c4ccccc4c4ccc(-c5ccc6c(ccc7c6c6ccccc6n7-c6ncc7ccccc7n6)c5)cc43)c2)cc1]

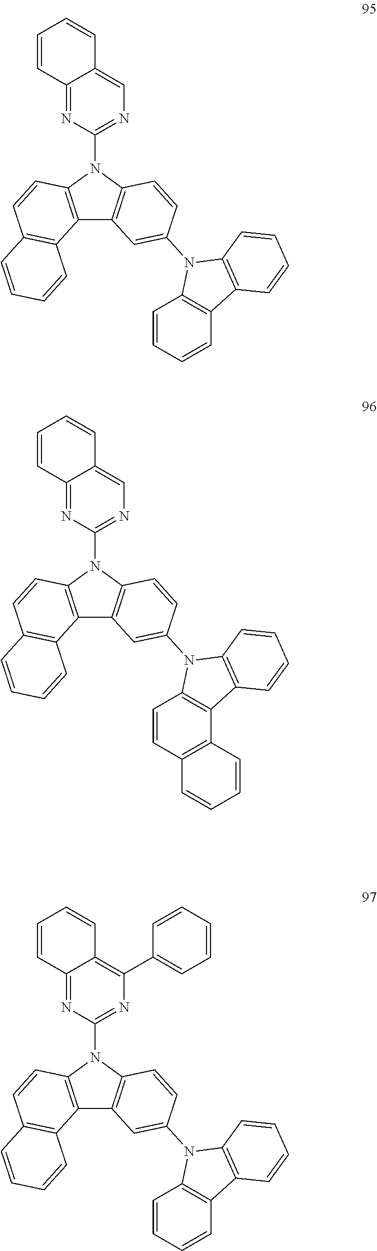 [SMILES: c1ccc2nc(-n3c4ccc(-n5c6ccccc6c6ccccc65)cc4c4c5ccccc5ccc43)ncc2c1 ; c1ccc2nc(-n3c4ccc(-n5c6ccccc6c6c7ccccc7ccc65)cc4c4c5ccccc5ccc43)ncc2c1 ; c1ccc(-c2nc(-n3c4ccc(-n5c6ccccc6c6ccccc65)cc4c4c5ccccc5ccc43)nc3ccccc23)cc1]

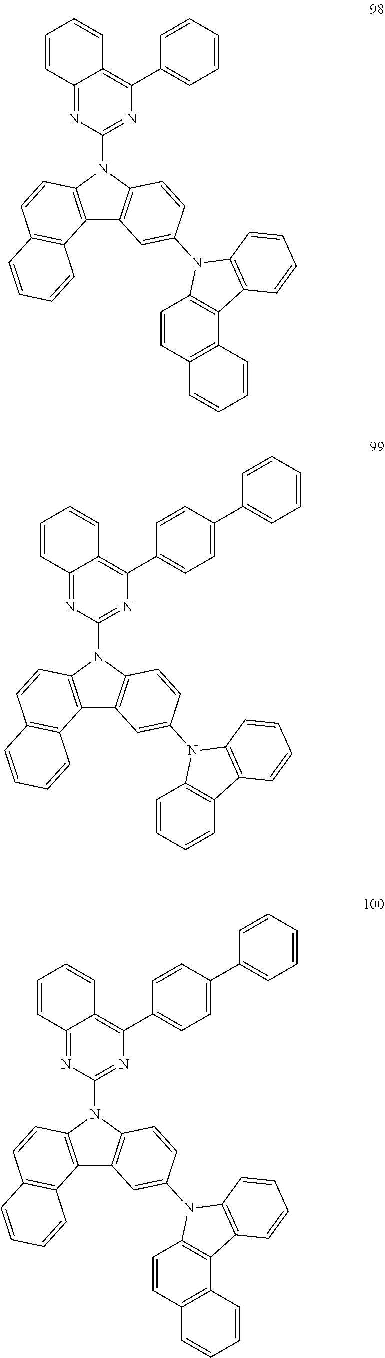 [SMILES: c1ccc(-c2nc(-n3c4ccc(-n5c6ccccc6c6c7ccccc7ccc65)cc4c4c5ccccc5ccc43)nc3ccccc23)cc1 ; c1ccc(-c2ccc(-c3nc(-n4c5ccc(-n6c7ccccc7c7ccccc76)cc5c5c6ccccc6ccc54)nc4ccccc34)cc2)cc1 ; c1ccc(-c2ccc(-c3nc(-n4c5ccc(-n6c7ccccc7c7c8ccccc8ccc76)cc5c5c6ccccc6ccc54)nc4ccccc34)cc2)cc1]

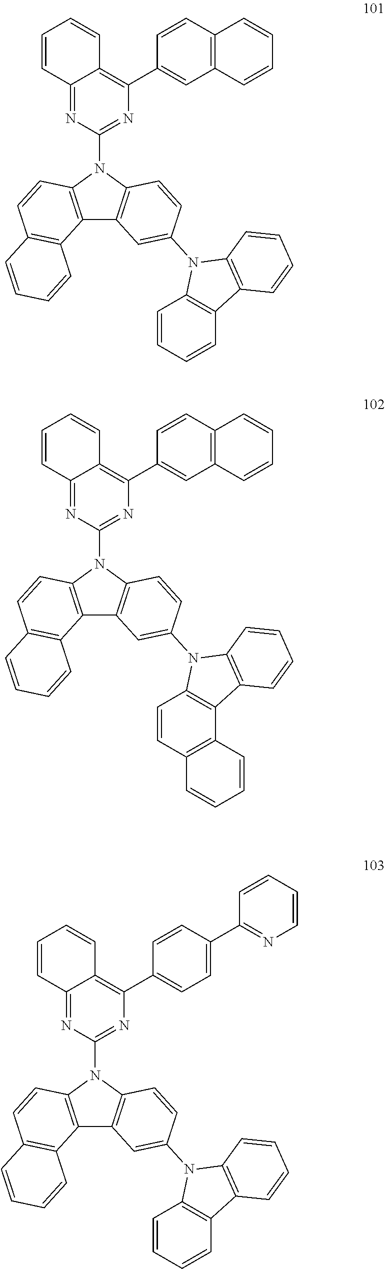 [SMILES: c1ccc2cc(-c3nc(-n4c5ccc(-n6c7ccccc7c7ccccc76)cc5c5c6ccccc6ccc54)nc4ccccc34)ccc2c1 ; c1ccc2cc(-c3nc(-n4c5ccc(-n6c7ccccc7c7c8ccccc8ccc76)cc5c5c6ccccc6ccc54)nc4ccccc34)ccc2c1 ; c1ccc(-c2ccc(-c3nc(-n4c5ccc(-n6c7ccccc7c7ccccc76)cc5c5c6ccccc6ccc54)nc4ccccc34)cc2)nc1]

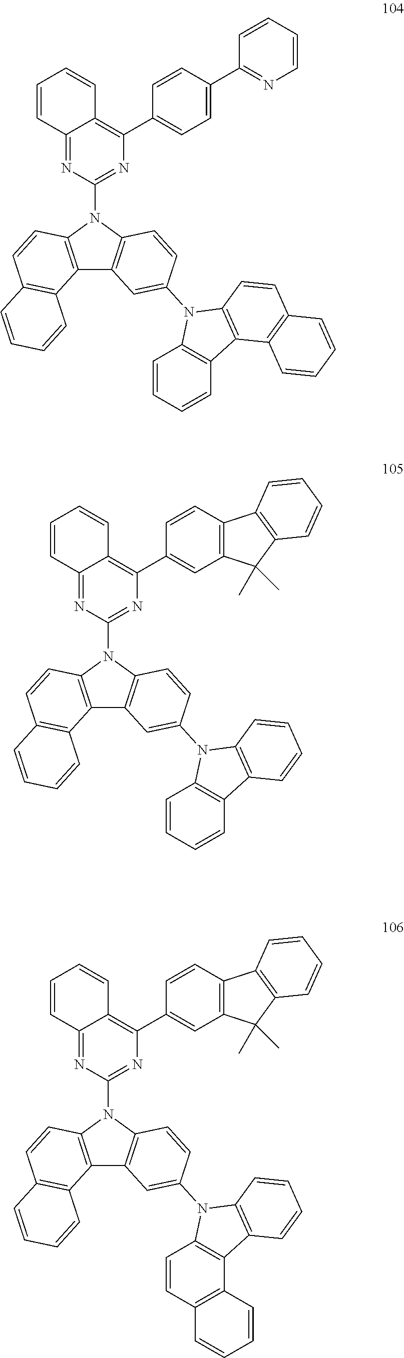 [SMILES: c1ccc(-c2ccc(-c3nc(-n4c5ccc(-n6c7ccccc7c7c8ccccc8ccc76)cc5c5c6ccccc6ccc54)nc4ccccc34)cc2)nc1 ; CC1(C)c2ccccc2-c2ccc(-c3nc(-n4c5ccc(-n6c7ccccc7c7ccccc76)cc5c5c6ccccc6ccc54)nc4ccccc34)cc21 ; CC1(C)c2ccccc2-c2ccc(-c3nc(-n4c5ccc(-n6c7ccccc7c7c8ccccc8ccc76)cc5c5c6ccccc6ccc54)nc4ccccc34)cc21]

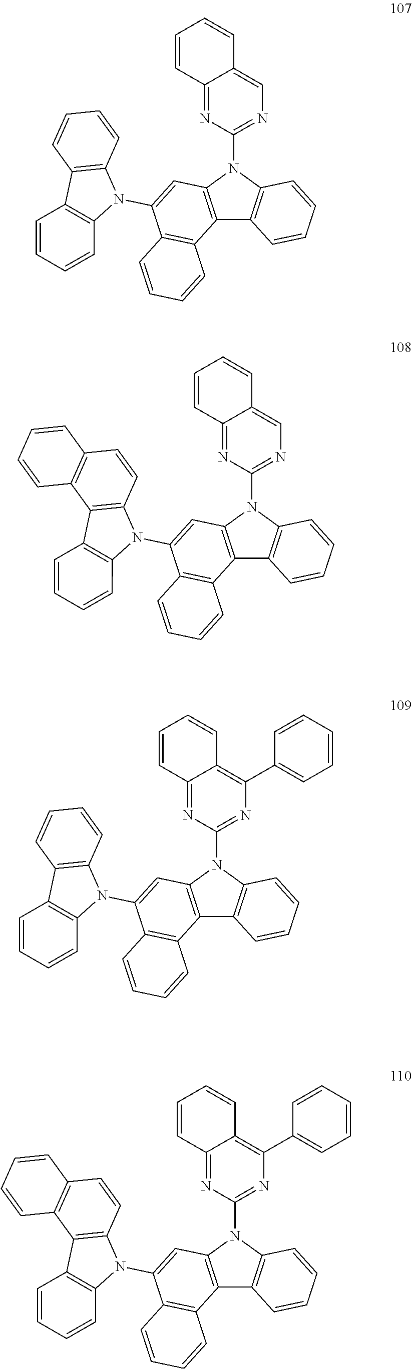 [SMILES: c1ccc2nc(-n3c4ccccc4c4c5ccccc5c(-n5c6ccccc6c6ccccc65)cc43)ncc2c1 ; c1ccc2nc(-n3c4ccccc4c4c5ccccc5c(-n5c6ccccc6c6c7ccccc7ccc65)cc43)ncc2c1 ; c1ccc(-c2nc(-n3c4ccccc4c4c5ccccc5c(-n5c6ccccc6c6ccccc65)cc43)nc3ccccc23)cc1 ; c1ccc(-c2nc(-n3c4ccccc4c4c5ccccc5c(-n5c6ccccc6c6c7ccccc7ccc65)cc43)nc3ccccc23)cc1]

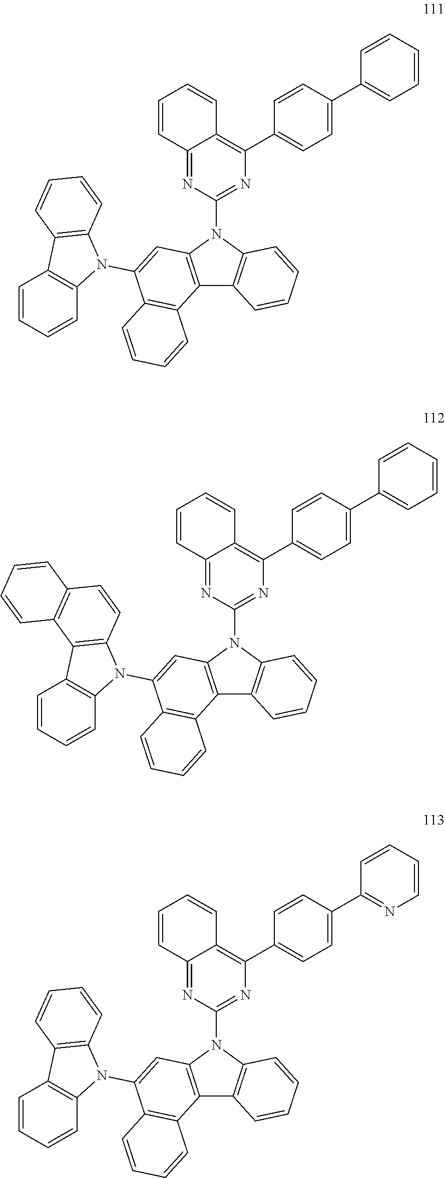 [SMILES: c1ccc(-c2ccc(-c3nc(-n4c5ccccc5c5c6ccccc6c(-n6c7ccccc7c7ccccc76)cc54)nc4ccccc34)cc2)cc1 ; c1ccc(-c2ccc(-c3nc(-n4c5ccccc5c5c6ccccc6c(-n6c7ccccc7c7c8ccccc8ccc76)cc54)nc4ccccc34)cc2)cc1 ; c1ccc(-c2ccc(-c3nc(-n4c5ccccc5c5c6ccccc6c(-n6c7ccccc7c7ccccc76)cc54)nc4ccccc34)cc2)nc1]

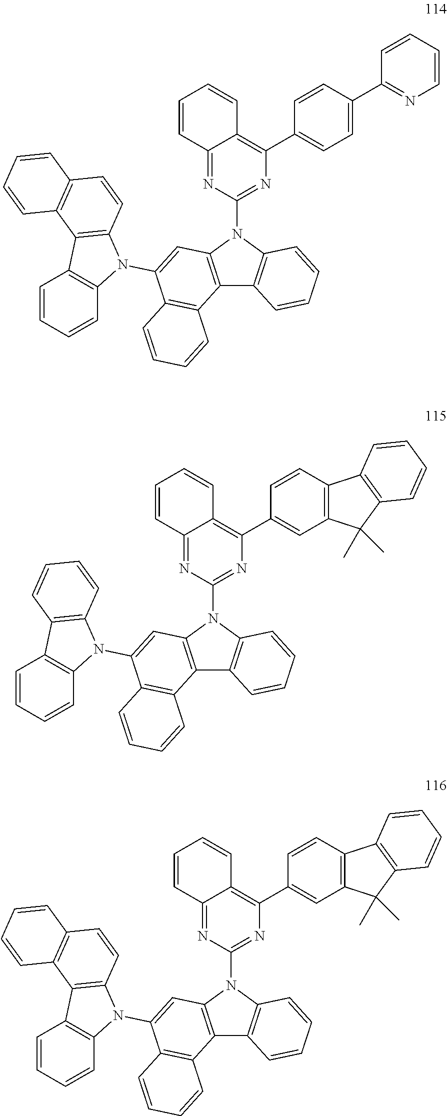 [SMILES: c1ccc(-c2ccc(-c3nc(-n4c5ccccc5c5c6ccccc6c(-n6c7ccccc7c7c8ccccc8ccc76)cc54)nc4ccccc34)cc2)nc1 ; CC1(C)c2ccccc2-c2ccc(-c3nc(-n4c5ccccc5c5c6ccccc6c(-n6c7ccccc7c7ccccc76)cc54)nc4ccccc34)cc21 ; CC1(C)c2ccccc2-c2ccc(-c3nc(-n4c5ccccc5c5c6ccccc6c(-n6c7ccccc7c7c8ccccc8ccc76)cc54)nc4ccccc34)cc21]

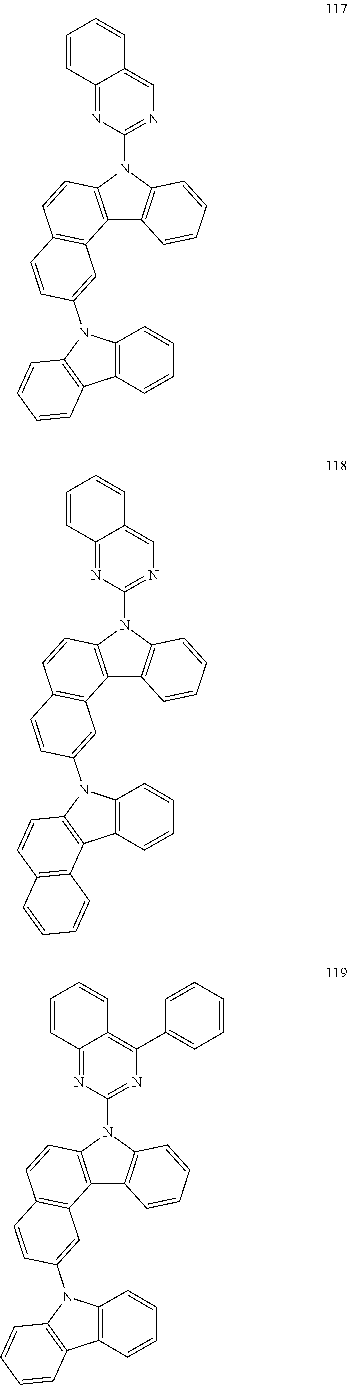 [SMILES: c1ccc2nc(-n3c4ccccc4c4c5cc(-n6c7ccccc7c7ccccc76)ccc5ccc43)ncc2c1 ; c1ccc2nc(-n3c4ccccc4c4c5cc(-n6c7ccccc7c7c8ccccc8ccc76)ccc5ccc43)ncc2c1 ; c1ccc(-c2nc(-n3c4ccccc4c4c5cc(-n6c7ccccc7c7ccccc76)ccc5ccc43)nc3ccccc23)cc1]

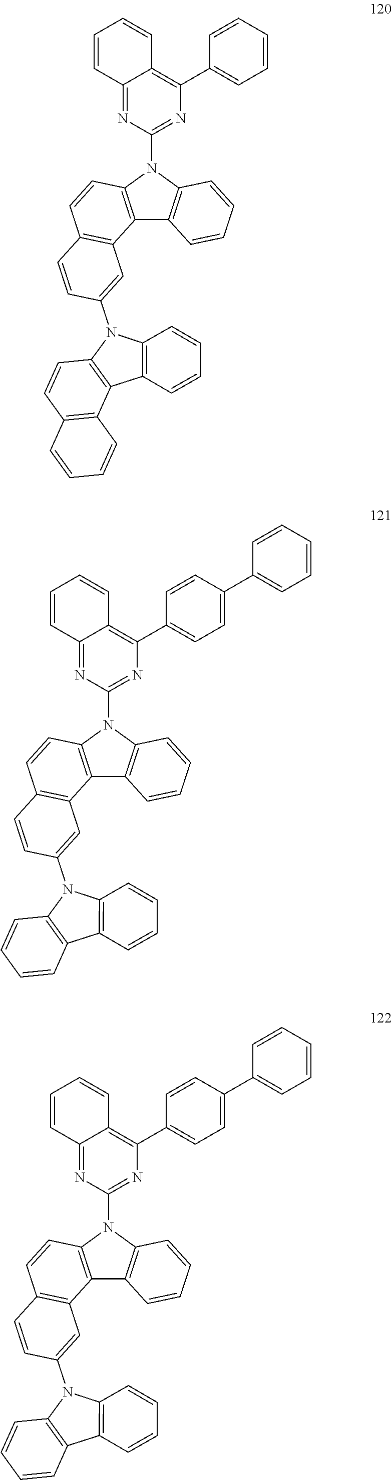 [SMILES: c1ccc(-c2nc(-n3c4ccccc4c4c5cc(-n6c7ccccc7c7c8ccccc8ccc76)ccc5ccc43)nc3ccccc23)cc1 ; c1ccc(-c2ccc(-c3nc(-n4c5ccccc5c5c6cc(-n7c8ccccc8c8ccccc87)ccc6ccc54)nc4ccccc34)cc2)cc1 ; c1ccc(-c2ccc(-c3nc(-n4c5ccccc5c5c6cc(-n7c8ccccc8c8ccccc87)ccc6ccc54)nc4ccccc34)cc2)cc1]

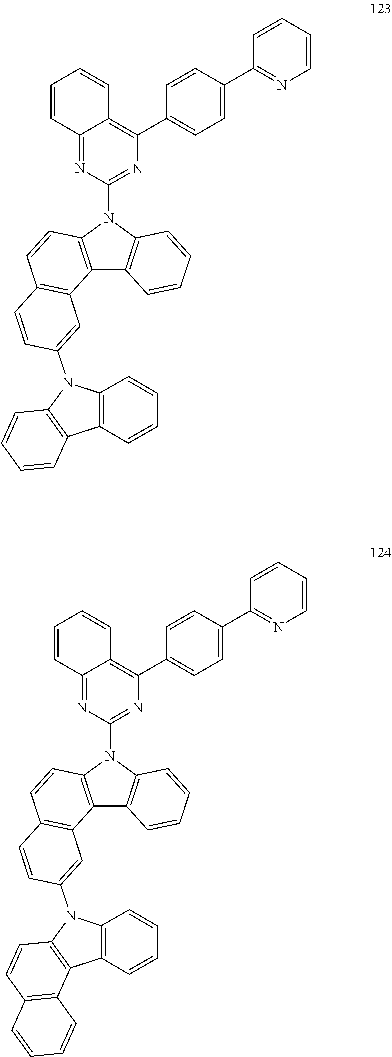 [SMILES: c1ccc(-c2ccc(-c3nc(-n4c5ccccc5c5c6cc(-n7c8ccccc8c8ccccc87)ccc6ccc54)nc4ccccc34)cc2)nc1 ; c1ccc(-c2ccc(-c3nc(-n4c5ccccc5c5c6cc(-n7c8ccccc8c8c9ccccc9ccc87)ccc6ccc54)nc4ccccc34)cc2)nc1]

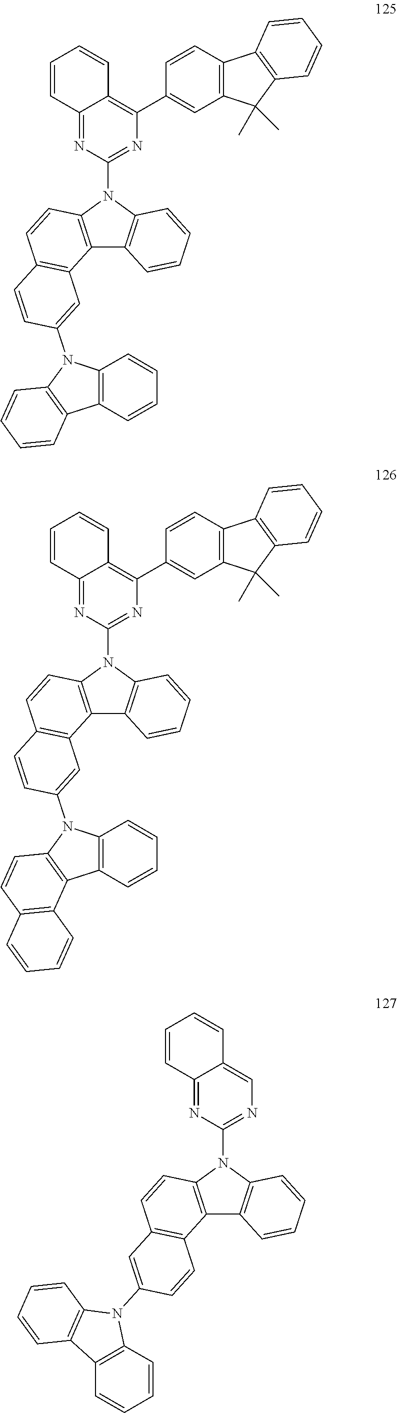 [SMILES: CC1(C)c2ccccc2-c2ccc(-c3nc(-n4c5ccccc5c5c6cc(-n7c8ccccc8c8ccccc87)ccc6ccc54)nc4ccccc34)cc21 ; CC1(C)c2ccccc2-c2ccc(-c3nc(-n4c5ccccc5c5c6cc(-n7c8ccccc8c8c9ccccc9ccc87)ccc6ccc54)nc4ccccc34)cc21 ; c1ccc2nc(-n3c4ccccc4c4c5ccc(-n6c7ccccc7c7ccccc76)cc5ccc43)ncc2c1]

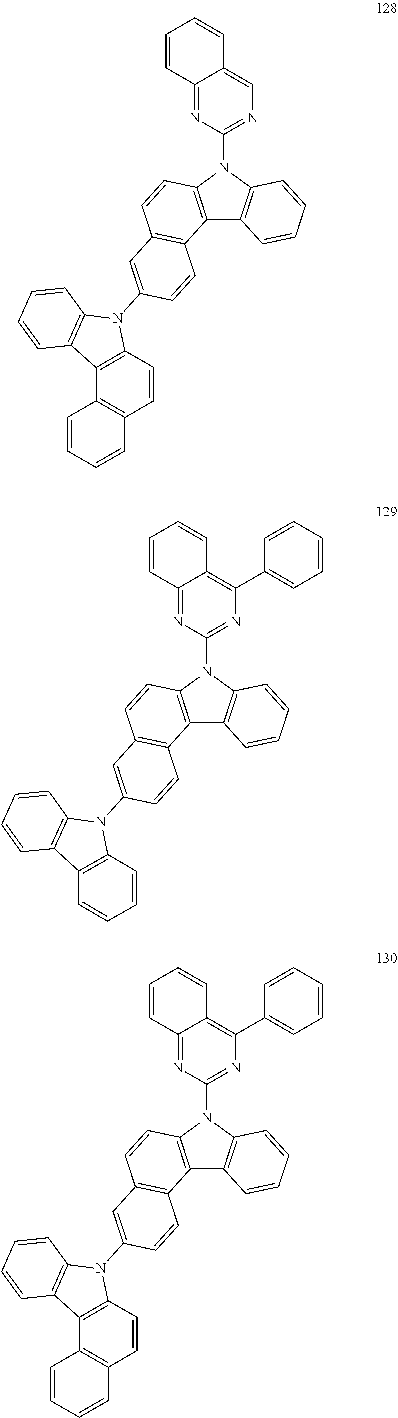 [SMILES: c1ccc2nc(-n3c4ccccc4c4c5ccc(-n6c7ccccc7c7c8ccccc8ccc76)cc5ccc43)ncc2c1 ; c1ccc(-c2nc(-n3c4ccccc4c4c5ccc(-n6c7ccccc7c7ccccc76)cc5ccc43)nc3ccccc23)cc1 ; c1ccc(-c2nc(-n3c4ccccc4c4c5ccc(-n6c7ccccc7c7c8ccccc8ccc76)cc5ccc43)nc3ccccc23)cc1]

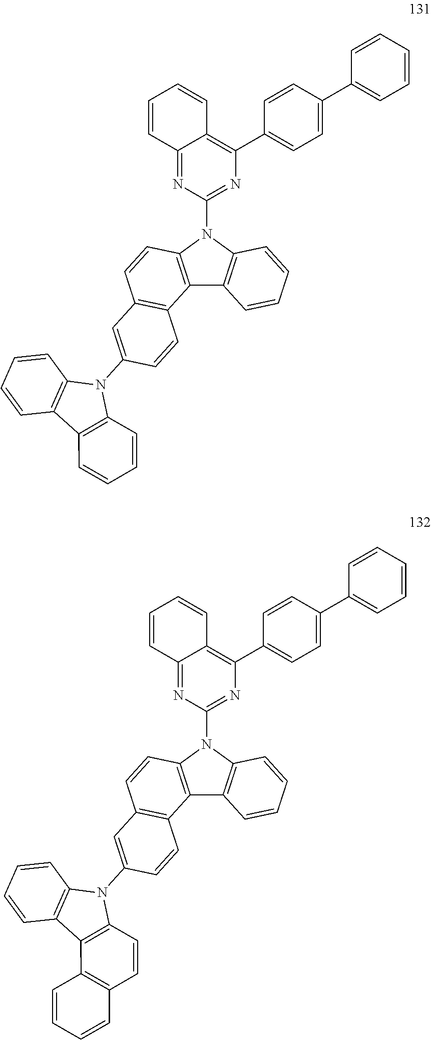 [SMILES: c1ccc(-c2ccc(-c3nc(-n4c5ccccc5c5c6ccc(-n7c8ccccc8c8ccccc87)cc6ccc54)nc4ccccc34)cc2)cc1 ; c1ccc(-c2ccc(-c3nc(-n4c5ccccc5c5c6ccc(-n7c8ccccc8c8c9ccccc9ccc87)cc6ccc54)nc4ccccc34)cc2)cc1]

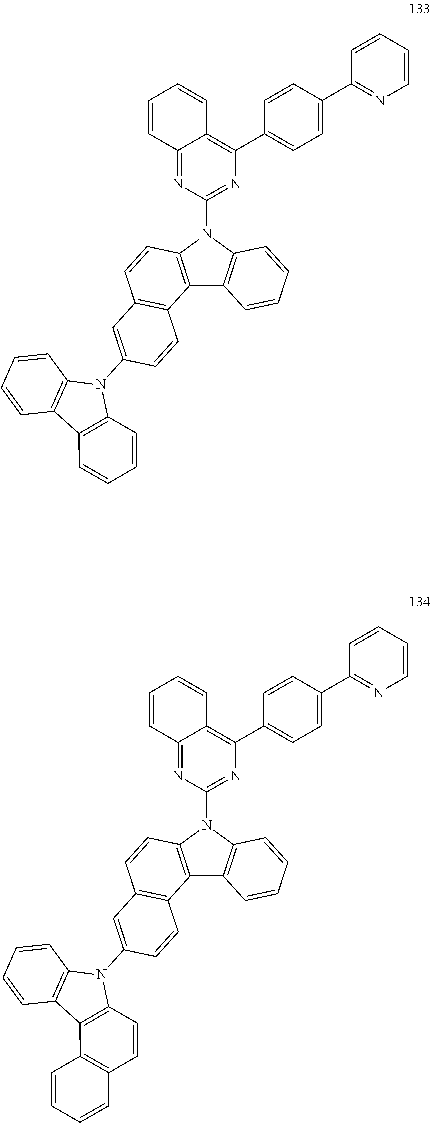 [SMILES: c1ccc(-c2ccc(-c3nc(-n4c5ccccc5c5c6ccc(-n7c8ccccc8c8ccccc87)cc6ccc54)nc4ccccc34)cc2)nc1 ; c1ccc(-c2ccc(-c3nc(-n4c5ccccc5c5c6ccc(-n7c8ccccc8c8c9ccccc9ccc87)cc6ccc54)nc4ccccc34)cc2)nc1]

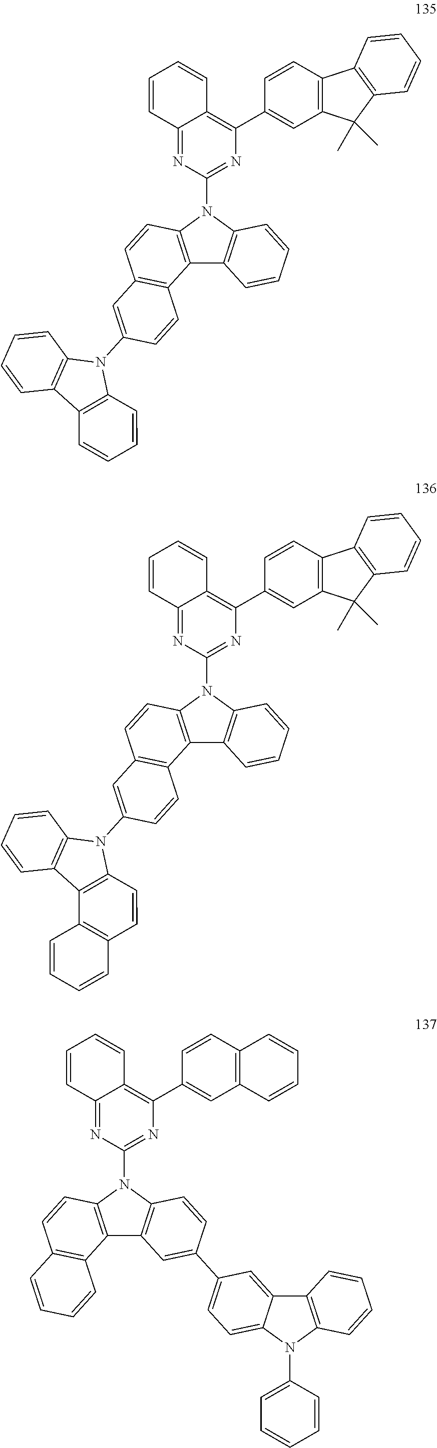

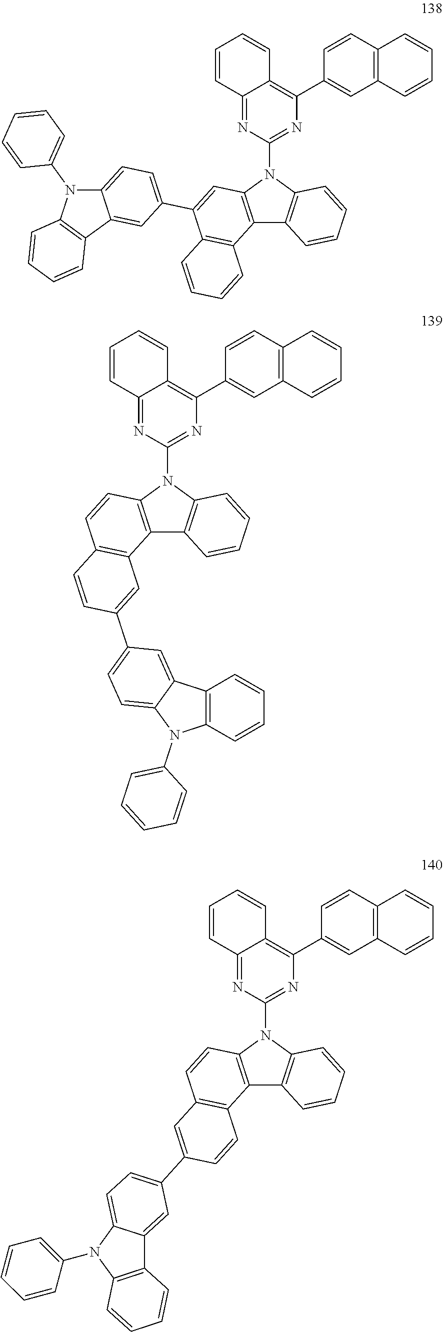 [SMILES: c1ccc(-n2c3ccccc3c3cc(-c4cc5c(c6ccccc46)c4ccccc4n5-c4nc(-c5ccc6ccccc6c5)c5ccccc5n4)ccc32)cc1 ; c1ccc(-n2c3ccccc3c3cc(-c4ccc5ccc6c(c5c4)c4ccccc4n6-c4nc(-c5ccc6ccccc6c5)c5ccccc5n4)ccc32)cc1 ; c1ccc(-n2c3ccccc3c3cc(-c4ccc5c(ccc6c5c5ccccc5n6-c5nc(-c6ccc7ccccc7c6)c6ccccc6n5)c4)ccc32)cc1]

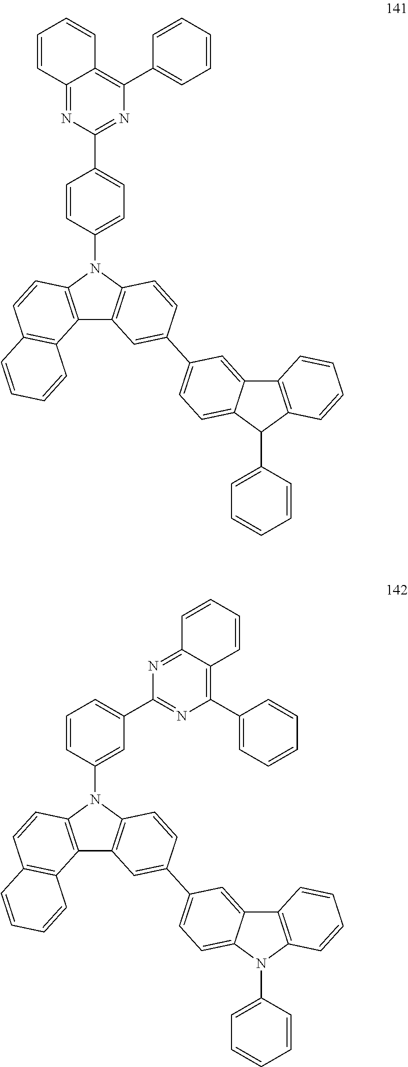 [SMILES: c1ccc(-c2nc(-c3ccc(-n4c5ccc(-c6ccc7c(c6)-c6ccccc6C7c6ccccc6)cc5c5c6ccccc6ccc54)cc3)nc3ccccc23)cc1 ; c1ccc(-c2nc(-c3cccc(-n4c5ccc(-c6ccc7c(c6)c6ccccc6n7-c6ccccc6)cc5c5c6ccccc6ccc54)c3)nc3ccccc23)cc1]

The conjugation length of the compound has a close relationship with an energy band gap. In detail, the energy band gap is reduced as the conjugation length of the compound increases. As described above, since a conjugation is limited in the core of the compound of Formula 1, the core has a large energy band gap.

As described above, in the present specification, various substituent groups may be introduced to L1, L2, X, Y1, or Y2 positions of the core structure having the large energy band gap so as to synthesize compounds having various energy band gaps. Generally, it is easy to control the energy band gap by introducing the substituent groups into the core structure having the large energy band gap, but it is difficult to significantly control the energy band gap by introducing the substituent groups into the core structure having the small energy band gap. Furthermore, in the present specification, it is possible to control HOMO (highest occupied molecular orbital) and LUMO (lowest unoccupied molecular orbital) energy levels of the compound by introducing various substituent groups into the L1, L2, X, Y1, or Y2 positions of the aforementioned core structure.

Additionally, by introducing various substituent groups into the aforementioned core structure, compounds having intrinsic characteristics of the introduced substituent groups may be synthesized. For example, the substituent groups, which are applied to a hole injection layer material, a hole transport layer material, a light emitting layer material, and an electron transport layer material used during the production of the organic light emitting device and the organic electronic device, may be introduced into the core structure so as to synthesize materials capable of satisfying the requirements of each organic material layer.

Furthermore, various substituent groups may be introduced into the core structure so as to precisely control the energy band gap, and to improve interfacial characteristics with organic material layers, and make the purpose of the material various.

In addition, if an appropriate substituent is introduced to the structure of Formula 1, energy band gap and stability may be ensured at a triplet state. From these results, various phosphorescence dopants having a red color to a blue color may be used and applied to light emitting layers of fluorescent and phosphorescent devices.

In the present specification, in the case where the compound of Formula 1 is applied together with the dopant to the light emitting layer, the dopant may be used by selecting any one of the following Dp-1 to Dp-15, but is not limited thereto.

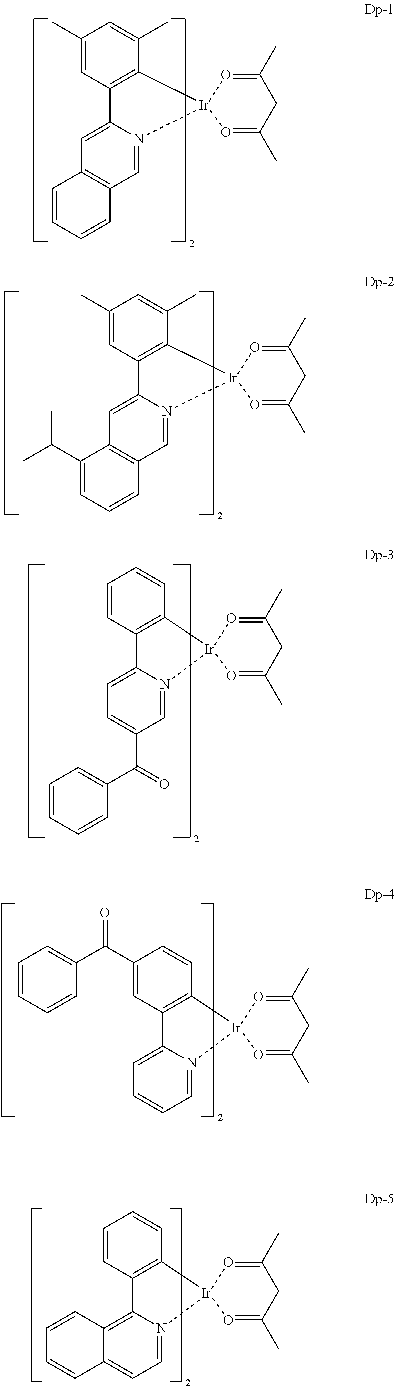

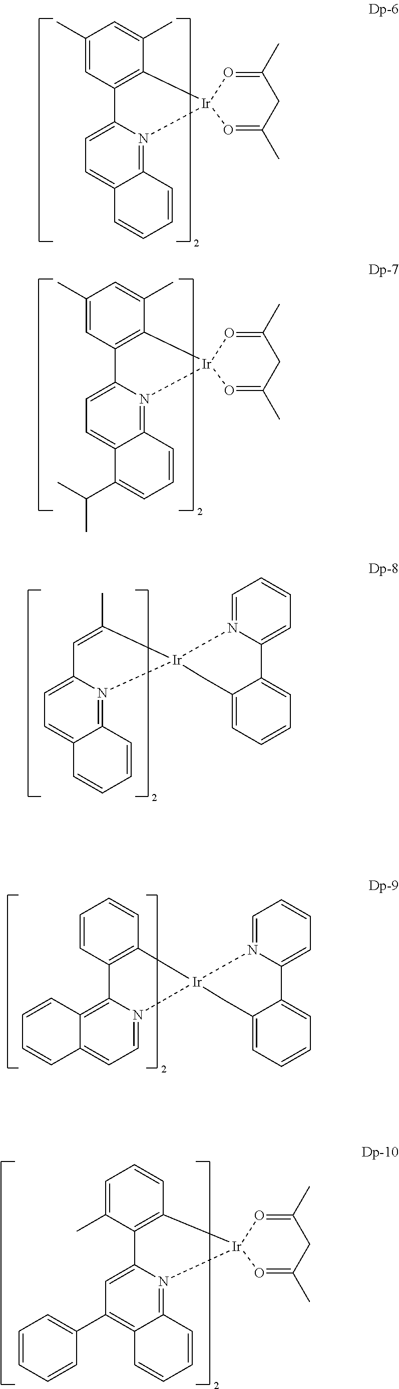

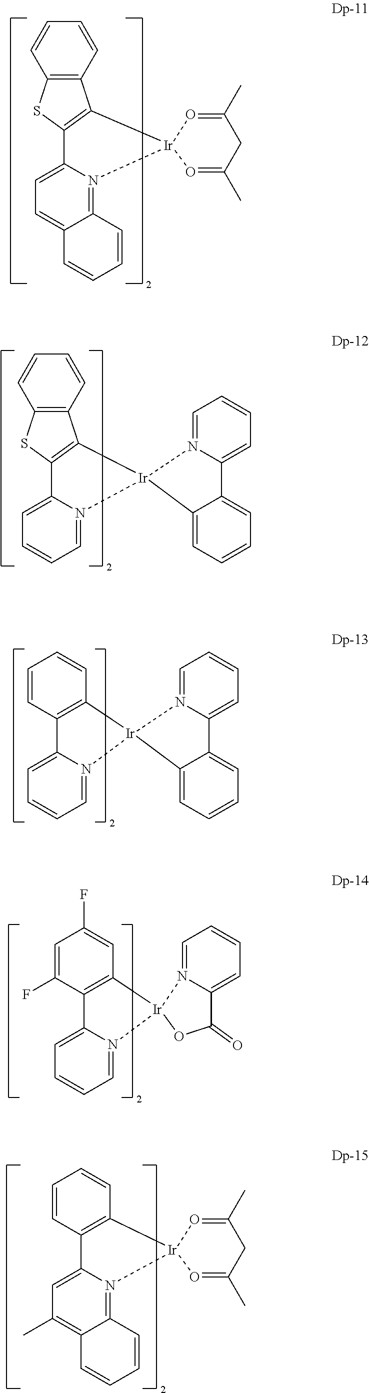

In addition, since the compound of Formula 1 has a high glass transition temperature (Tg), the compound has excellent thermal stability. Such increase in thermal stability is an important factor providing driving stability to the device.

Furthermore, the compound of Formula 1 may be used to form the organic material layer using a vacuum deposition process or a solution coating process during the production of the organic electronic device. In connection with this, examples of the solution coating process include spin coating, dip coating, inkjet printing, screen printing, a spray process, roll coating, and the like, but are not limited thereto.

The organic electronic device of the present specification may be produced using known materials through a known process, modified only in that one or more layers of organic material layers include the compound of the present specification, that is, the compound of Formula 1. The compound according to the present specification may be used as a hole injection material, a hole transport material, a light emitting material, an electron transport material, an electron injection material, and the like, and it is more preferable that the compound be used as the light emitting material in the organic electronic device according to the present specification.

In addition, on the basis of the application of the compound according to the present specification to the organic light emitting device, those who are skilled in the art can use the compound according to the present specification in other organic electronic devices. The organic electronic device according to the present specification includes an organic light emitting device, an organic phosphorescent device, an organic solar cell, an organic photoconductor (OPC), and an organic transistor.

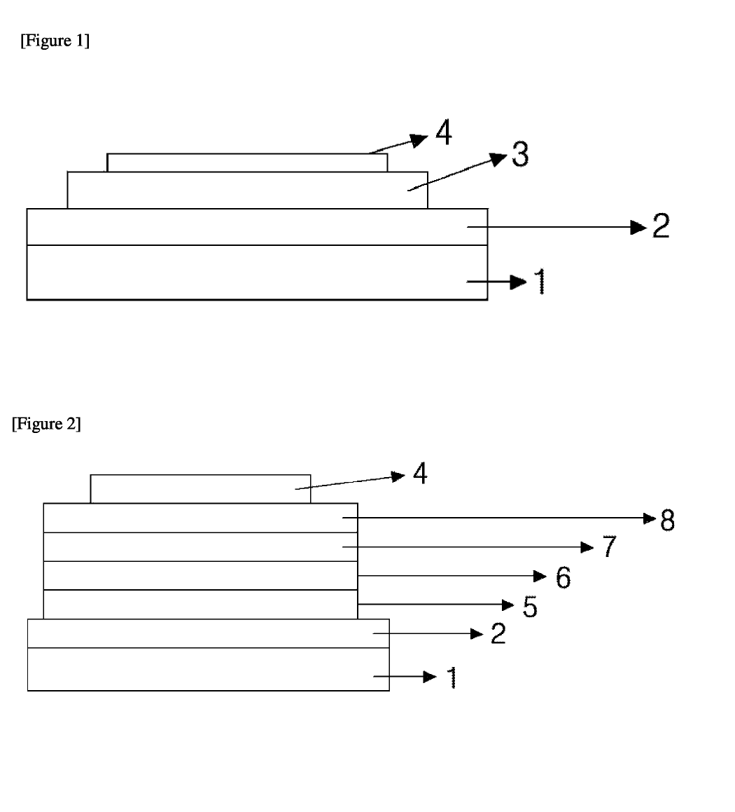

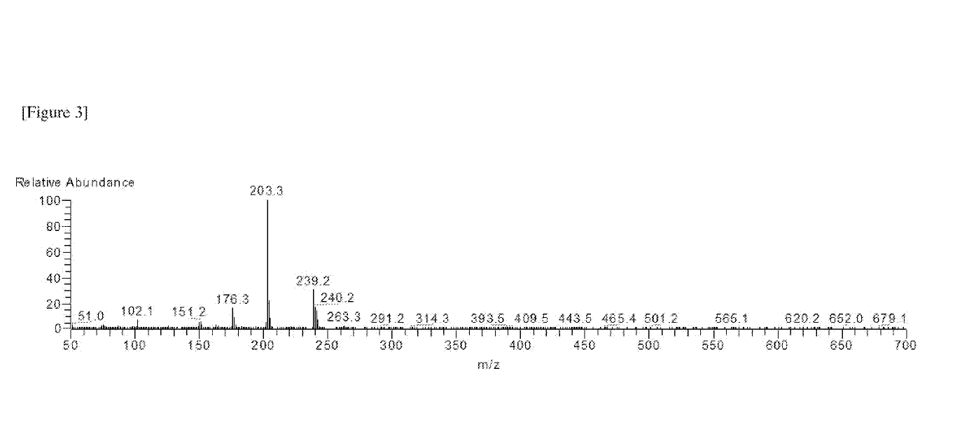

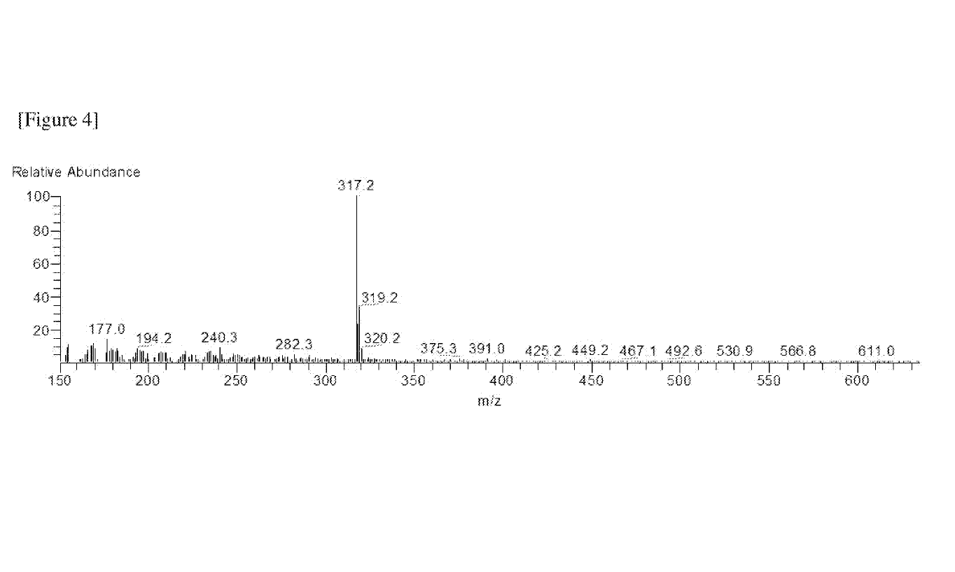

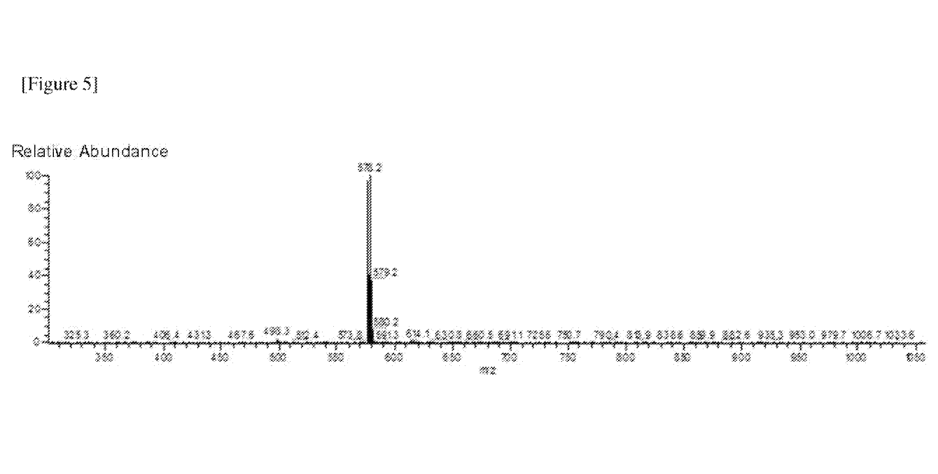

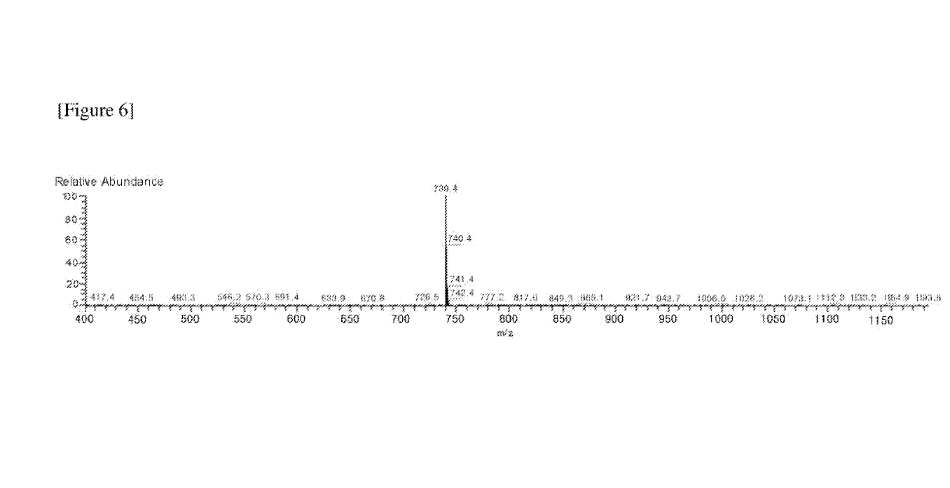

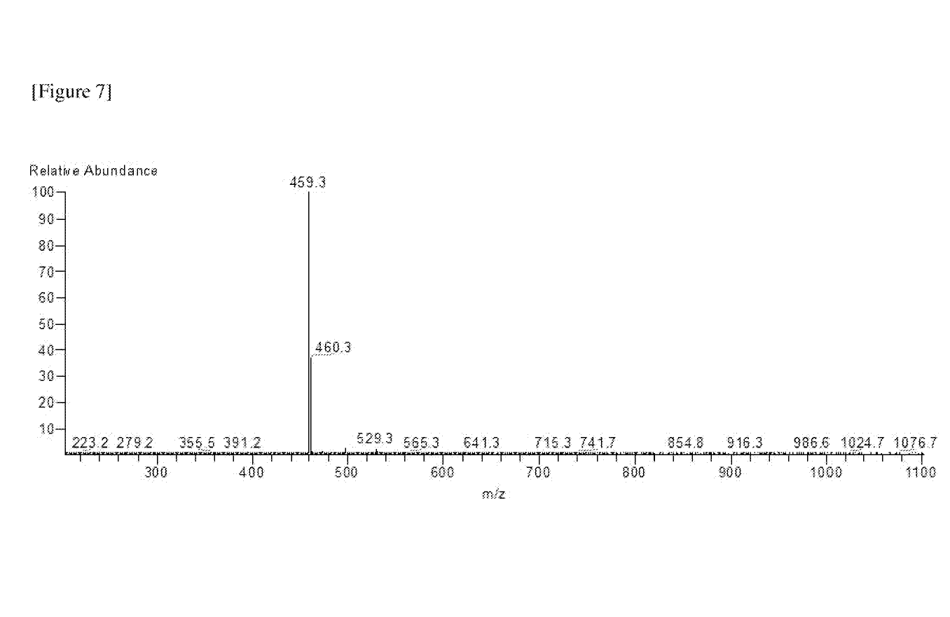

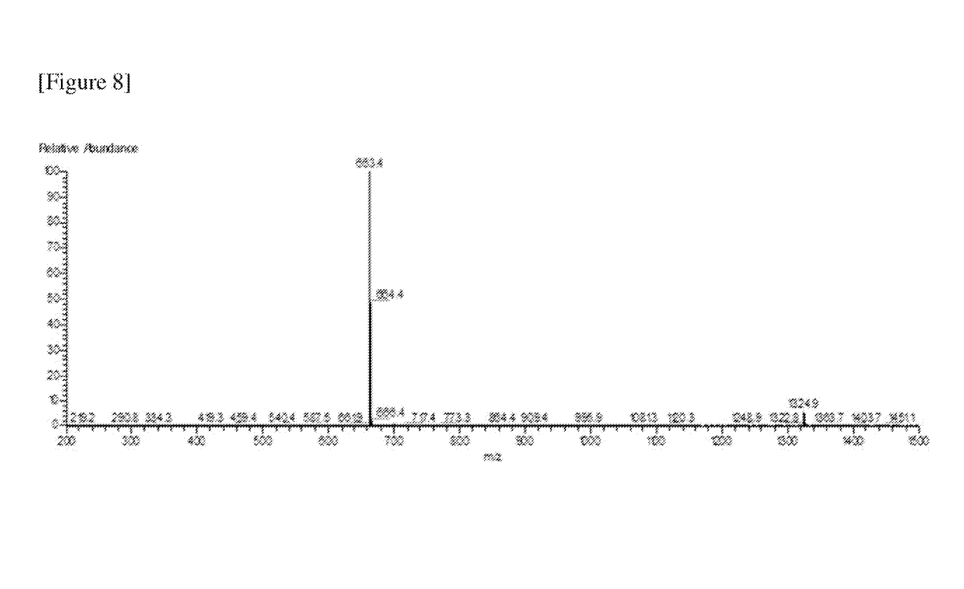

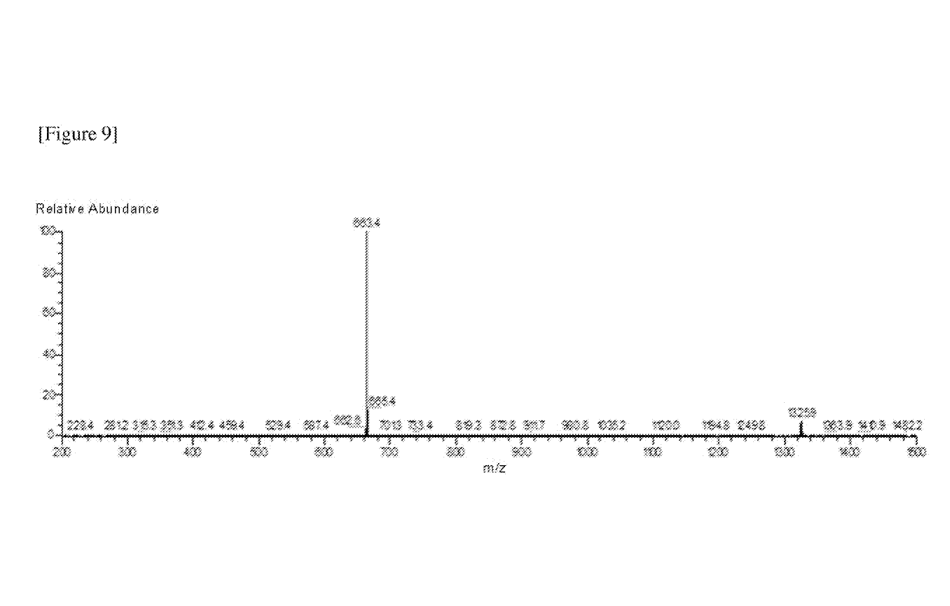

The organic material layer of the organic electronic device of the present specification may have a single layer structure, or alternatively, a multilayered structure in which at least two organic material layers are layered. For example, the organic light emitting device of the present specification may have a structure including a hole injection layer, a hole transport layer, a light emitting layer, an electron transport layer, an electron injection layer, and the like as the organic material layer. However, the structure of the organic light emitting device is not limited thereto, but may include a smaller number of organic material layers. The structure of the organic light emitting device of the present specification is illustrated in FIGS. 1 and 2, but is not limited thereto.

The organic light emitting device of the present specification may be produced, for example, by sequentially layering a first electrode, an organic material layer, and a second electrode on a substrate. In connection with this, a physical vapor deposition (PVD) method, such as a sputtering method or an e-beam evaporation method, may be used, but the method is not limited thereto.

The method for manufacturing the compound of Formula 1 and the manufacturing of an organic light emitting device using the same will be described in detail in the following Preparation Examples and Examples. However, the following Preparation Examples and Examples are set forth to illustrate the present specification, but the scope of the present specification is not limited thereto.

The compound of Formula 1 according to the present specification may be manufactured with multistage chemical reactions. The manufacturing of the compounds will be described in the following Synthesis Examples and Preparation Examples. As described in the following Synthesis Examples, some intermediate compounds are first manufactured, and as described in the Preparation Examples, the compounds of Formula 1 are manufactured from the intermediate compounds.

### Synthesis Example of Intermediate 1-A-2

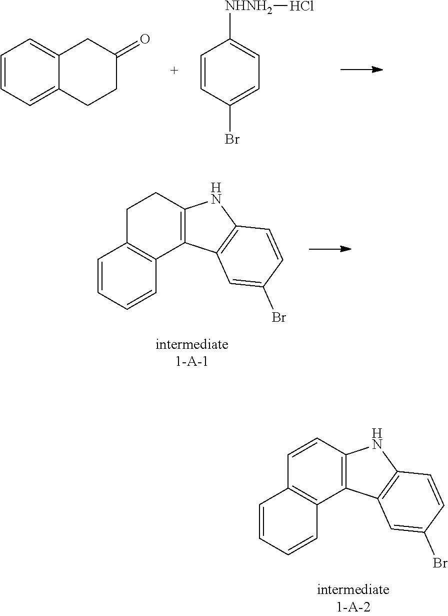

### 1) Synthesis of Intermediate 1-A-1

β-tetralone (CAS#530-93-8, 18 g, 123 mmol), and 4-bromophenylhydrazine hydrochloride (CAS#622-88-8, 29 g, 129 mmol) were put into 300 ml of ethanol (EtOH), and the hydrochloric acid was put thereinto in a small amount, and heated and refluxed for 1 hour under nitrogen atmosphere. After the reaction was finished, cooling to room temperature was performed, the product was filtered to be dried in the vacuum oven for one day and thus obtain 25 g of intermediate 1-A-1 (10-bromo-6,7-dihydro-5H-benzo[c]carbazole) (yield 68.8%). [M+H]=298

### 2) Synthesis of Intermediate 1-A-2

25 g of the intermediate 1-A-1 was put into 400 ml of CH₃CN, and tetrachloro-1,4-benzoquinone (DDQ, chloranil, CAS#118-75-2, 21 g, 84.7 mmol) in the solid state slowly dripped thereinto in the cold bath condition of 0° C. in an amount of the same equivalent as intermediate 1-A-1. After the reaction was finished, NaOH (10%) and water were put into the reaction solution, and the organic layer was extracted. The reaction solution was concentrated and recrystallized with hexane to manufacture 21 g of intermediate 1-A-2 (10-bromo-7H-benzo[c]carbazole) (yield 84.7%). [M+H]=296

### Synthesis Example of Intermediate 1-B-3

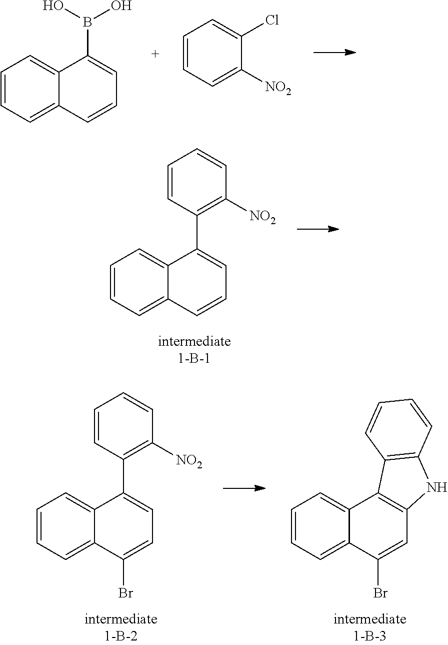 [SMILES: OB(O)c1cccc2ccccc12 ; O=[N+]([O-])c1ccccc1Cl ; O=[N+]([O-])c1ccccc1-c1cccc2ccccc12 ; O=[N+]([O-])c1ccccc1-c1ccc(Br)c2ccccc12 ; Brc1cc2[nH]c3ccccc3c2c2ccccc12]

### 1) Synthesis of Intermediate 1-B-1

After the 1-naphthylboronic acid (CAS#13922-41-3, 17 g, 100 mmol) and 2-chloro-2-nitrobenzene (CAS#88-73-3, 16 g, 100 mmol) were dissolved in 200 ml of toluene and 100 ml of ethanol, potassium carbonate (CAS#584-08-7, 41 g, 300 mmol) was dissolved in water to be put into the reaction solution, and heating and agitation were performed for 30 minutes. After 30 minutes, tetrakis(triphenylphosphine) palladium(0) (CAS#14221-01-3, 1.7 g, 1.5 mmol) was put, and additionally reacted for 2 hours. After the reaction was finished, an excessive amount of water was put, extraction with ethyl acetate (EA) was carried out to obtain the organic layer, and column purification was carried out to obtain 18 g of intermediate 1-B-1 (yield 75.5%). [M]=249

### 2) Synthesis of Intermediate 1-B-2

20 g of obtained intermediate 1-B-1 (80 mmol) was put into 200 ml of dichloromethane (CH₂Cl₂), and bromine (Br₂, CAS#7726-95-6, 4.3 ml, 84 mmol) slowly dripped in the ice bath at 0° C. for 20 minutes. After addition was finished, the reaction solution was agitated in the room temperature state for about one day. After the reaction was finished, in the reaction solution, residual bromine was removed with water and sodium thiosulfate (Na₂S₂O₃, CAS#10102-17-7) in the aqueous solution state, and extraction with dichloromethane was carried out. After extraction, the solvent was concentrated by the rotary evaporator, and 22.8 g of compound 1-B-2 (yield 86.4%) was obtained through column purification. [M+H]=328

### 3) Synthesis of Intermediate 1-B-3

20 g of obtained intermediate 1-B-2 was put into triethylphosphite (P(OEt)₃, CAS#122-52-1, 42 ml), and heating and agitation were carried out at 180° C. for 8 hours. After the reaction was finished, residual P(OEt)₃ was removed through vacuum distillation, and extraction was carried out by using EA. Anhydrous magnesium sulfate (MgSO₄, CAS#7487-88-9) was put into extracted EA to remove water, and column purification was carried out to obtain 11.6 g of intermediate 1-B-3 (5-bromo-7H-benzo[c]carbazole) (yield 64.3%).

### Synthesis Example of Intermediate 1-C-3

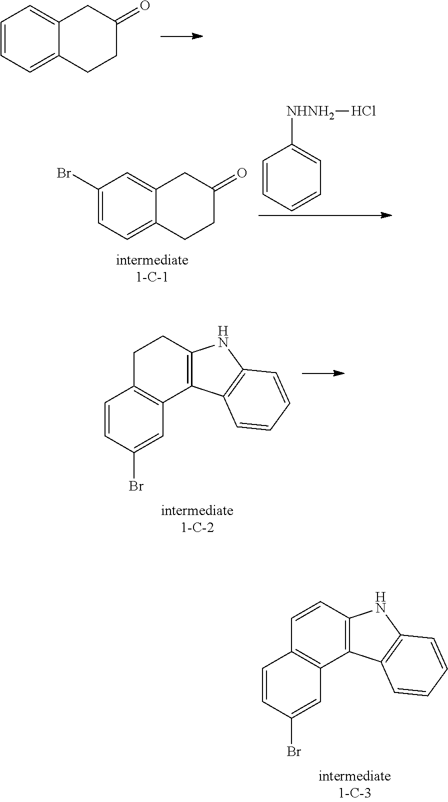

### 1) Synthesis of Intermediate 1-C-1

By the same method as the method mentioned in US Patent Laid-Open No. 2009-0076076, aluminum chloride (AlCl₃, CAS#7446-70-0, 31.9 g, 239 mmol) was put into 30 ml of CH₂Cl₂ under nitrogen atmosphere, and agitated at 0° C. for 10 minutes, and β-tetralone (17.5 g, 120 mmol) was then added. Agitation was carried out for 20 minutes, and Br₂ (6.74 ml, 131 mmol) was slowly added at the same temperature. After addition of bromine was finished, the reaction solution was further agitated at room temperature for 1 hour. After the reaction was finished, the reaction solution was poured into the ice bath and extracted with EA. After the extracted organic material was dried by MgSO₄ and concentrated by the rotary evaporator, the concentrated solution was subjected to column purification to obtain 19 g of intermediate 1-C-1 (7-bromo-3,4-dihydronaphthalen-2(1H)-one) (yield 71.1%). [M]=225

### 2) Synthesis of Intermediate 1-C-2

23 g of intermediate 1-C-2 (2-bromo-6,7-dihydro-5H-benzo[c]carbazole) (yield 88.7%) was obtained by the same synthesis method as intermediate 1-A-1 using intermediate 1-C-1 (20 g, 89 mmol) and phenylhydrazine hydrochloride (CAS#59-88-1, 12.9 g, 89 mmol). [M+H]=299

### 3) Synthesis of Intermediate 1-C-3

Intermediate 1-C-2 (20 g, 67 mmol) was subjected to the same procedure as the synthesis method of intermediate 1-A-2 to obtain 13 g of intermediate 1-C-3 (2-bromo-7H-benzo[c]carbazole) (yield 64.7%).

### Synthesis Example of Intermediate 1-D-2

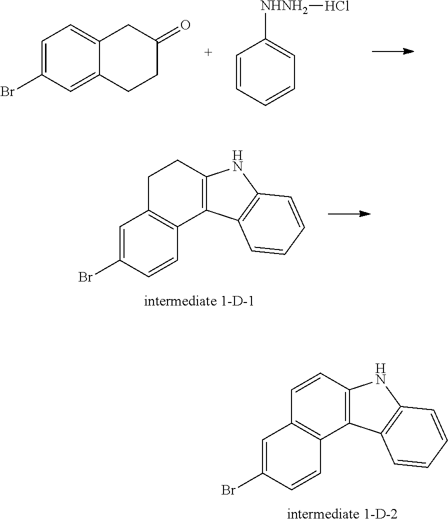

### 1) Synthesis of Intermediate 1-D-1

6-bromo-2-tetralone (CAS#4133-35-1, 30 g, 133 mmol) and phenylhydrazine hydrochloride (19 g, 133 mmol) were subjected to the same procedure as the synthesis method of intermediate 1-A-1 to obtain intermediate 1-D-1 (3-bromo-6,7-dihydro-5H-benzo[c]carbazole). [M+H]=298

### 2) Synthesis of Intermediate 1-D-2

All intermediate 1-D-1 and DDQ (30 g, 133 mmol) were used, and the same procedure as the synthesis method of intermediate 1-A-2 was carried out to obtain 25.5 g of intermediate 1-D-2 (3-bromo-7H-benzo[c]carbazole) (total yield of 1-D-1 and 1-D-2 64.6%).

### Synthesis Example of Intermediate 1-E-1

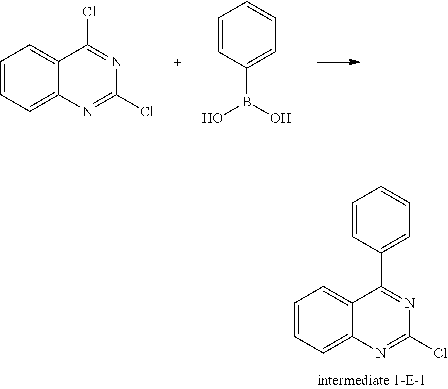 [SMILES: Clc1nc(Cl)c2ccccc2n1 ; OB(O)c1ccccc1 ; Clc1nc(-c2ccccc2)c2ccccc2n1]

The same procedure as the synthesis method of intermediate 1-B-1 was carried out by using 2,4-dichloroqinazoline (CAS#607-68-1, 10 g, 50 mmol) and phenylboronic acid (PBA, CAS#98-80-6, 6.10 g, 50 mmol) to obtain 8.3 g of intermediate 1-E-1 (yield 68.7%). [M]=240

### Synthesis Example of Intermediate 1-E-2

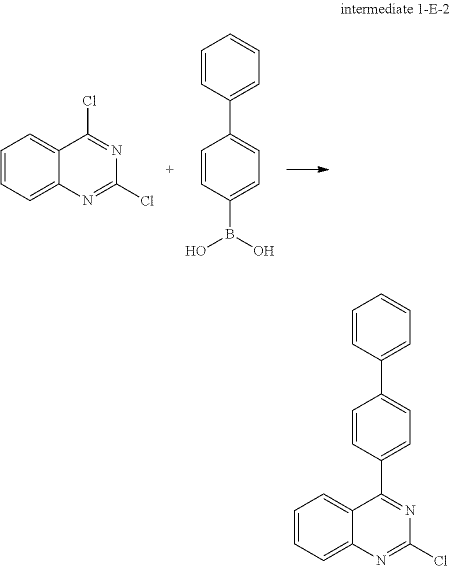 [SMILES: Clc1nc(Cl)c2ccccc2n1 ; OB(O)c1ccc(-c2ccccc2)cc1 ; Clc1nc(-c2ccc(-c3ccccc3)cc2)c2ccccc2n1]

The same procedure as the synthesis method of intermediate 1-B-1 was carried out by using 2,4-dichloroqinazoline (CAS#607-68-1, 20 g, 100 mmol) and 4-biphenylboronic acid (PBA, CAS#5122-94-1, 20 g, 100 mmol) to obtain 23.3 g of intermediate 1-E-2 (yield 73.2%). [M]=317

### Synthesis Example of Intermediate 1-E-3

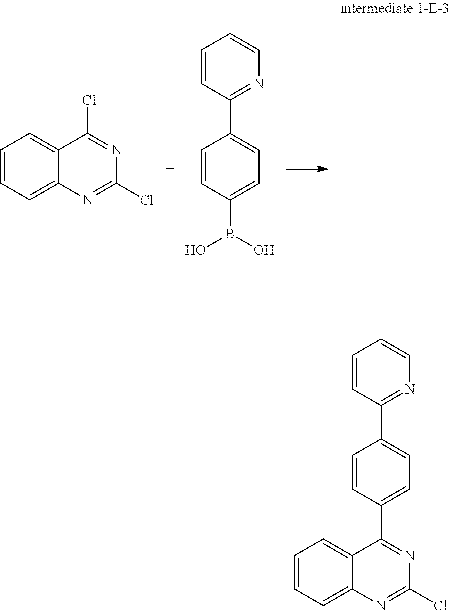 [SMILES: Clc1nc(Cl)c2ccccc2n1 ; OB(O)c1ccc(-c2ccccn2)cc1 ; Clc1nc(-c2ccc(-c3ccccn3)cc2)c2ccccc2n1]

The same procedure as the synthesis method of intermediate 1-B-1 was carried out by using 2,4-dichloroqinazoline (CAS#607-68-1, 20 g, 100 mmol)) and 4-(2-pyridyl)-phenylboronic acid (CAS#170230-27-0, 20 g, 100 mmol) to obtain 23.8 g of intermediate 1-E-3 (yield 74.9%). [M]=317

### Synthesis Example of Intermediate 1-E-4

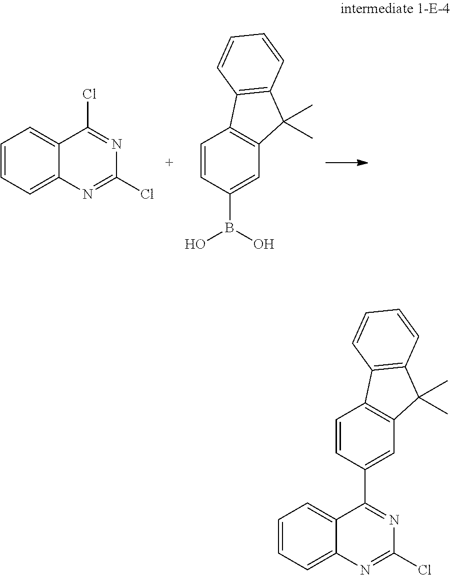 [SMILES: Clc1nc(Cl)c2ccccc2n1 ; CC1(C)c2ccccc2-c2ccc(B(O)O)cc21 ; CC1(C)c2ccccc2-c2ccc(-c3nc(Cl)nc4ccccc34)cc21]

The same procedure as the synthesis method of intermediate 1-B-1 was carried out by using 2,4-dichloroqinazoline (CAS#607-68-1, 20 g, 100 mmol) and 9,9-dimethyl-9H-fluoren-2-yl boronic acid (CAS#333432-28-3, 23.8 g, 100 mmol) to obtain 18.6 g of intermediate 1-E-4 (yield 52.1%). [M]=356

### Synthesis Example of Intermediate 1-E-5

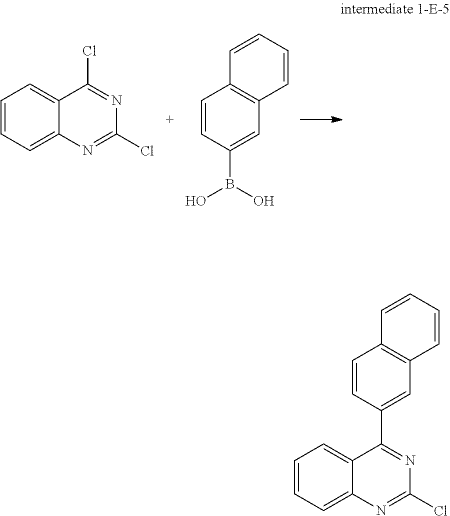 [SMILES: Clc1nc(Cl)c2ccccc2n1 ; OB(O)c1ccc2ccccc2c1 ; Clc1nc(-c2ccc3ccccc3c2)c2ccccc2n1]

The same procedure as the synthesis method of intermediate 1-B-1 was carried out by using 2,4-dichloroqinazoline (CAS#607-68-1, 20 g, 100 mmol) and 2-naphthyl boronic acid (CAS#32316-92-0, 18.1 g, 100 mmol) to obtain 26.7 g of intermediate 1-E-5 (yield 91.3%). [M]=290

### Synthesis Example of Intermediate 2-E-1

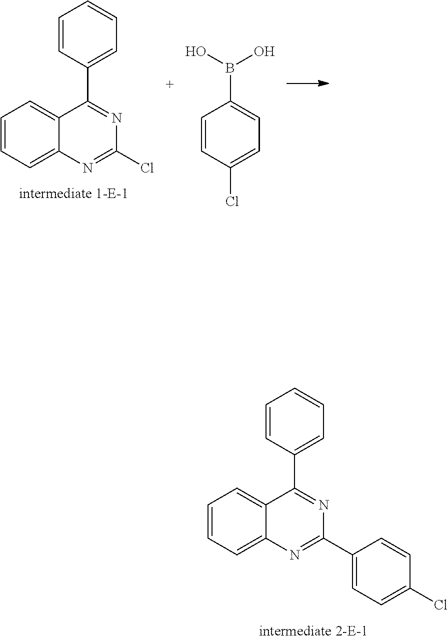 [SMILES: Clc1nc(-c2ccccc2)c2ccccc2n1 ; OB(O)c1ccc(Cl)cc1 ; Clc1ccc(-c2nc(-c3ccccc3)c3ccccc3n2)cc1]

12 g of synthesized intermediate 1-E-1 (50 mmol) and 4-chlorophenyl boronic acid (CAS#1679-18-1, 8.6 g, 55 mmol) were subjected to the same procedure as the synthesis method of intermediate 1-B-1 to obtain 11.8 g of intermediate 2-E-1 (yield 74.4%). [M]=316

### Synthesis Example of Intermediate 2-A-1

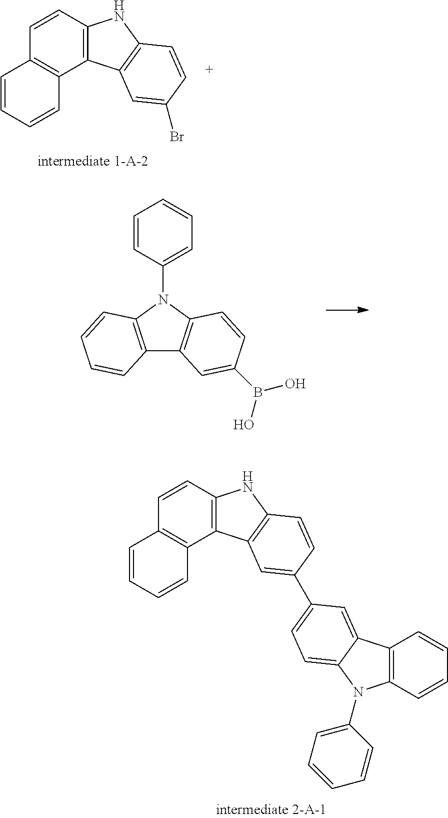 [SMILES: Brc1ccc2[nH]c3ccc4ccccc4c3c2c1 ; OB(O)c1ccc2c(c1)c1ccccc1n2-c1ccccc1 ; c1ccc(-n2c3ccccc3c3cc(-c4ccc5[nH]c6ccc7ccccc7c6c5c4)ccc32)cc1]

25.5 g of intermediate 2-A-1 (yield 82.4%) was obtained by using 20 g of intermediate 1-A-2 (67.5 mmol) and N-phenyl-9H-carbazole-3-yl boronic acid (CAS#854952-58-2, 20.4 g, 70.9 mmol) under the same condition as the synthesis method of intermediate 1-B-1. [M+H]=458

### Synthesis Example of Intermediate 2-A-2

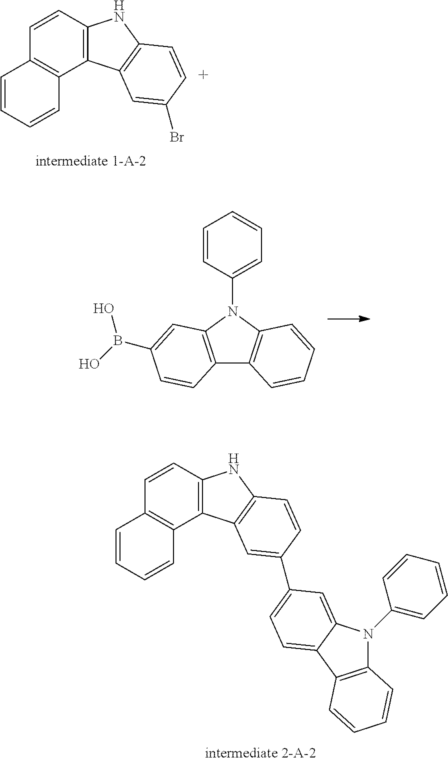 [SMILES: Brc1ccc2[nH]c3ccc4ccccc4c3c2c1 ; OB(O)c1ccc2c3ccccc3n(-c3ccccc3)c2c1 ; c1ccc(-n2c3ccccc3c3ccc(-c4ccc5[nH]c6ccc7ccccc7c6c5c4)cc32)cc1]

22.2 g of intermediate 2-A-2 (yield 71.6%) was obtained by using 20 g of intermediate 1-A-2 (67.5 mmol) and N-phenyl-9H-carbazole-2-yl boronic acid (CAS#1001911-63-2, 20.4 g, 70.9 mmol) under the same condition as the synthesis method of intermediate 1-B-1. [M+H]=458

### Synthesis Example of Intermediate 2-B-1

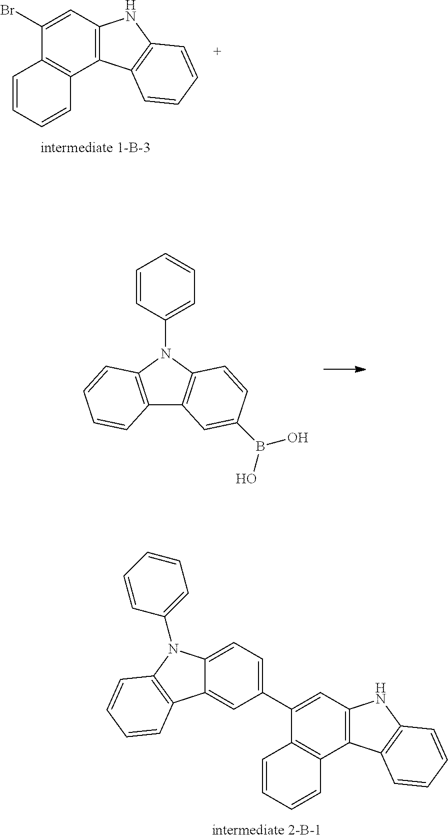 [SMILES: Brc1cc2[nH]c3ccccc3c2c2ccccc12 ; OB(O)c1ccc2c(c1)c1ccccc1n2-c1ccccc1 ; c1ccc(-n2c3ccccc3c3cc(-c4cc5[nH]c6ccccc6c5c5ccccc45)ccc32)cc1]

13.9 g of intermediate 2-B-1 (yield 74.7%) was obtained by using 12 g of intermediate 1-B-3 (41 mmol) and N-phenyl-9H-carbazole-3-yl boronic acid (12.2 g, 43 mmol) under the same condition as the synthesis method of intermediate 1-B-1. [M+H]=458

### Synthesis Example of Intermediate 2-B-2

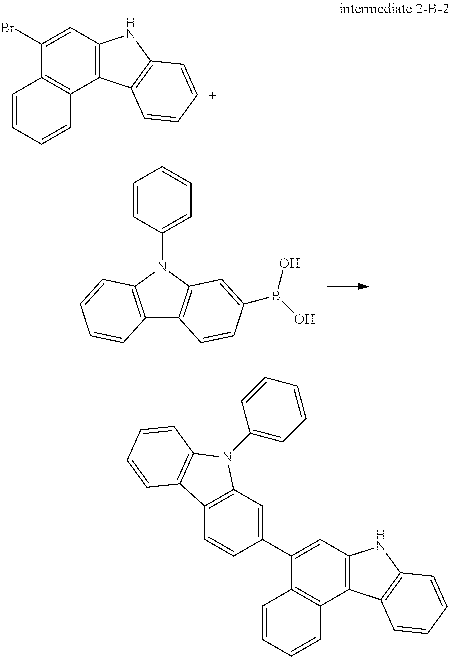 [SMILES: Brc1cc2[nH]c3c(c2c2ccccc12)C=C[C+]=C3 ; OB(O)c1ccc2c3ccccc3n(-c3ccccc3)c2c1 ; c1ccc(-n2c3ccccc3c3ccc(-c4cc5[nH]c6ccccc6c5c5ccccc45)cc32)cc1]

17.4 g of intermediate 2-B-2 (yield 75.1%) was obtained by using 15 g of intermediate 1-B-3 (50.6 mmol) and N-phenyl-9H-carbazole-2-yl boronic acid (15.3 g, 53.2 mmol) under the same condition as the synthesis method of intermediate 1-B-1. [M+H]=458

### Synthesis Example of Intermediate 2-C-1

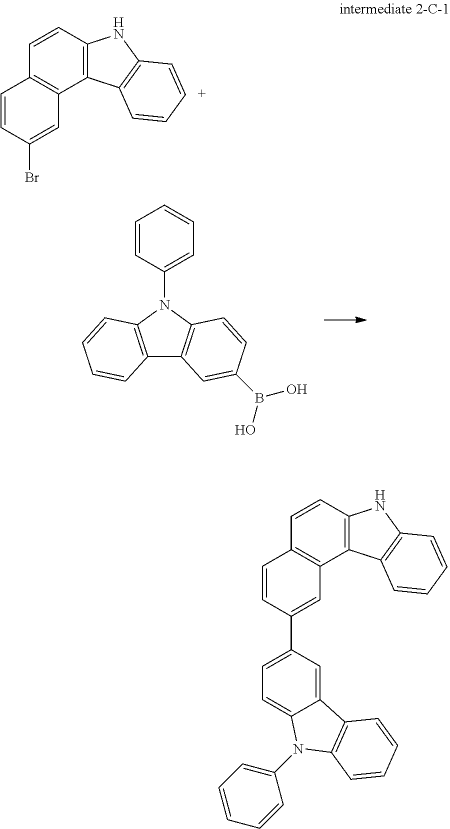 [SMILES: Brc1ccc2ccc3[nH]c4ccccc4c3c2c1 ; OB(O)c1ccc2c(c1)c1ccccc1n2-c1ccccc1 ; c1ccc(-n2c3ccccc3c3cc(-c4ccc5ccc6[nH]c7ccccc7c6c5c4)ccc32)cc1]

10.8 g of intermediate 2-C-1 (yield 69.8%) was obtained by using 10 g of intermediate 1-C-3 (34 mmol) and N-phenyl-9H-carbazole-3-yl boronic acid (10.7 g, 37 mmol) under the same condition as the synthesis method of intermediate 1-B-1. [M+H]=458

### Synthesis Example of Intermediate 2-C-2

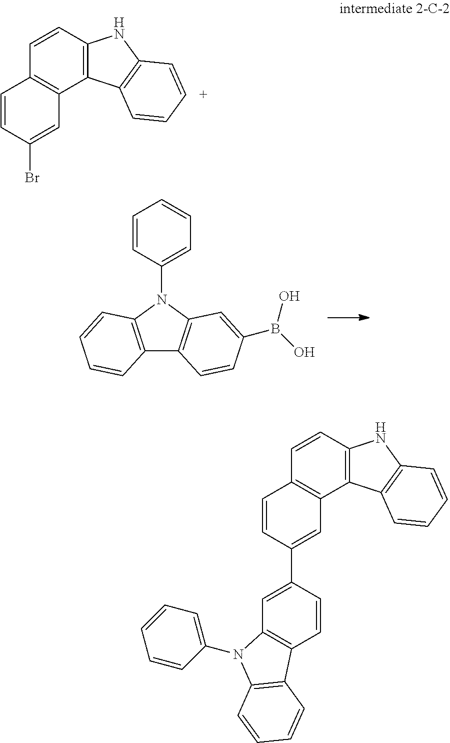 [SMILES: Brc1ccc2ccc3[nH]c4ccccc4c3c2c1 ; OB(O)c1ccc2c3ccccc3n(-c3ccccc3)c2c1 ; c1ccc(-n2c3ccccc3c3ccc(-c4ccc5ccc6[nH]c7ccccc7c6c5c4)cc32)cc1]

8.7 g of intermediate 2-C-2 (yield 70.1%) was obtained by using 8 g of intermediate 1-C-3 (27 mmol) and N-phenyl-9H-carbazole-2-yl boronic acid (8.1 g, 28.3 mmol) under the same condition as the synthesis method of intermediate 1-B-1. [M+H]=458

### Synthesis Example of Intermediate 2-D-1

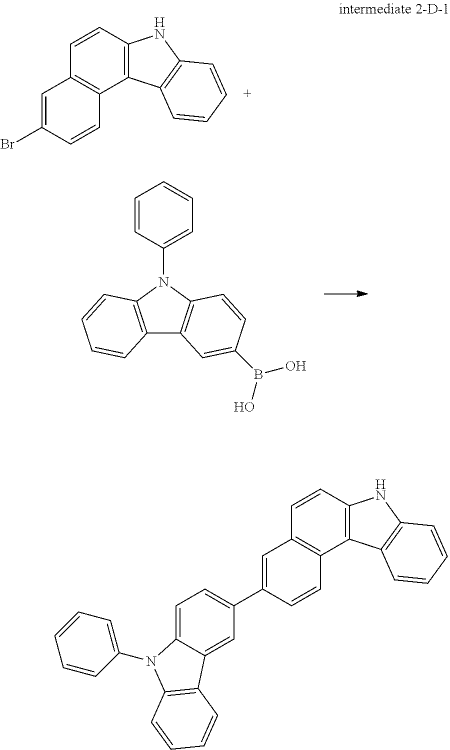 [SMILES: Brc1ccc2c(ccc3[nH]c4ccccc4c32)c1 ; OB(O)c1ccc2c(c1)c1ccccc1n2-c1ccccc1 ; c1ccc(-n2c3ccccc3c3cc(-c4ccc5c(ccc6[nH]c7ccccc7c65)c4)ccc32)cc1]

10.7 g of intermediate 2-D-1 (yield 69.0%) was obtained by using 10 g of intermediate 1-D-2 (34 mmol) and N-phenyl-9H-carbazole-3-yl boronic acid (10.2 g, 37 mmol) under the same condition as the synthesis method of intermediate 1-B-1. [M+H]=458

### Synthesis Example of Intermediate 2-D-2

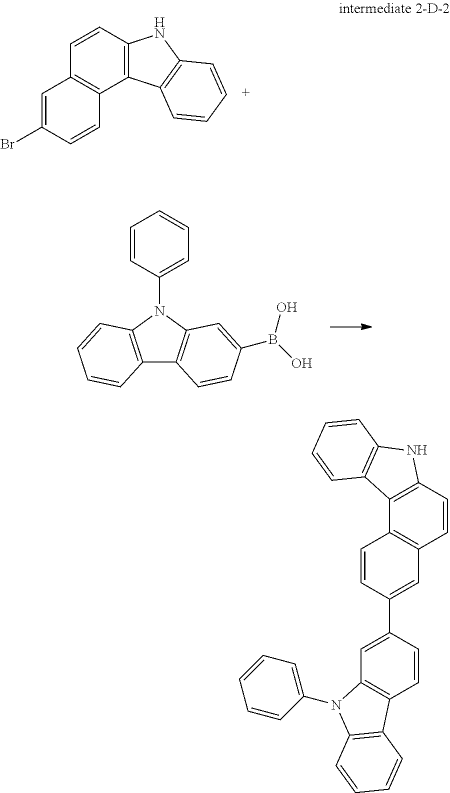 [SMILES: Brc1ccc2c(ccc3[nH]c4ccccc4c32)c1 ; OB(O)c1ccc2c3ccccc3n(-c3ccccc3)c2c1 ; c1ccc(-n2c3ccccc3c3ccc(-c4ccc5c(ccc6[nH]c7ccccc7c65)c4)cc32)cc1]

11.2 g of intermediate 2-D-2 (yield 65.7%) was obtained by using 11 g of intermediate 1-D-2 (37 mmol) and N-phenyl-9H-carbazole-2-yl boronic acid (11.2 g, 39 mmol) under the same condition as the synthesis method of intermediate 1-B-1. [M+H]=458

The method of manufacturing the compounds of Formula 1 manufactured by using the intermediate compounds manufactured in the Synthesis Examples is described below, but is not limited thereto.

### Preparation Example 1

### Synthesis of Compound 1

10 g of synthesized intermediate 2-A-1 (21.8 mmol) was put together with copper (Cu, CAS#7440-50-8, 2.77 g, 43.6 mmol) and potassium phosphate (K₃PO₄, 13.8 g, 65.4 mmol) into the iodobenzene (CAS#591-50-4) solvent (hereinafter, Ullmann condition), and heating and agitation were carried out for one day. After the reaction was finished, the reaction solution was cooled to room temperature, an excessive amount of ethanol (EtOH) was put to precipitate the compound, extraction with CHCl₃ was carried out, water was removed, and recrystallization was carried out by using EA to obtain 9.6 g of compound 1 (yield 82.1%). [M]=534

### Preparation Example 2

### Synthesis of Compound 11

7 g of synthesized intermediate 2-B-1 (15.2 mmol) and 4-iodobiphenyl (CAS#1591-31-7, 4.7 g, 16.8 mmol) were put into xylene, sodium t-butoxide (NaOtBu, CAS#865-48-5, 2.9 g, 30.5 mmol) was put thereinto, and heating and agitation were carried out for 30 minutes. After agitation for 30 minutes, bis(tri-tert-butylphosphine)palladium(0) (BTP, 0.02 g, 3.05□mol) was put thereinto, and heating and agitation were further carried out for one day (hereinafter, Buchwald condition). After the reaction was finished, cooling to room temperature was carried out, an excessive amount of ethanol (EtOH) was put to precipitate the precipitate, the precipitate was put into N-methyl-2-pyrollidone (NMP, CAS#872-50-4), heated and refluxed for 2 hours, and cooled to room temperature to generate the precipitate again. The generated precipitate was washed with ethanol (EtOH) to obtain 6.2 g of compound II (yield 66.3%). [M]=610

### Preparation Example 3

### Synthesis of Compound 21

The same procedure as synthesis of compound 11 was carried out by using 8 g of synthesized intermediate 2-C-1 (17.4 mmol) and 2-bromonaphthalene (CAS#580-13-2, 4.0 g, 19.1 mmol) to obtain 7.2 g of compound 21 (yield 70.1%). [M]=584

### Preparation Example 4

### Synthesis of Compound 26

10 g of synthesized intermediate 2-A-1 (21.8 mmol) was slowly put together with sodium hydride (NaH (hereinafter), CAS#7646-69-7, 1.7 g, 26.1 mmol) into anhydrous dimethylacetamide (DMF (hereinafter), CAS#68-12-2) under nitrogen atmosphere. After agitation at room temperature for 1 hour, 2-chloroquinazoline (CAS#6141-13-5, 3.8 g, 23.0 mmol) was put thereinto, and agitated at room temperature for one day. After the reaction was finished, the generated precipitate was filtered, washed with EtOH, and extracted with EA to obtain 9.8 g of compound 26 (yield 76.3%). [M]=587

### Preparation Example 5

### Synthesis of Compound 27

The same procedure as the synthesis method of the aforementioned compound 26 was carried out by using 9 g of synthesized intermediate 2-A-1 (19.6 mmol) and 5.0 g of synthesized intermediate 1-E-1 (20.6 mmol) to obtain 10.6 g of compound 27 (yield 81.7%). [M+H]=663

### Preparation Example 6

### Synthesis of Compound 28

The same procedure as the synthesis method of the aforementioned compound 26 was carried out by using 8 g of synthesized intermediate 2-A-1 (17.4 mmol) and 5.8 g of synthesized intermediate 1-E-2 (18.3 mmol) to obtain 10.0 g of compound 28 (yield 77.4%). [M+H]=739

### Preparation Example 7

### Synthesis of Compound 32

The same procedure as the method of the aforementioned compound 26 was carried out by using 12 g of synthesized intermediate 2-B-1 (26.1 mmol) and 6.6 g of synthesized intermediate 1-E-1 (27.4 mmol) to obtain 13.9 g of compound 32 (yield 80.3%). [M+H]=663

### Preparation Example 8

### Synthesis of Compound 37

The same procedure as the method of the aforementioned compound 26 was carried out by using 15.4 g of synthesized intermediate 2-C-1 (33.8 mmol) and 8.1 g of synthesized intermediate 1-E-1 (33.8 mmol) to obtain 14 g of compound 37 (yield 62.9%). [M+H]=663

### Preparation Example 9

### Synthesis of Compound 42

The same procedure as the method of the aforementioned compound 26 was carried out by using 11 g of synthesized intermediate 2-D-1 (23 mmol) and 5.9 g of synthesized intermediate 1-E-1 (24 mmol) to obtain 12 g of compound 42 (yield 78.3%). [M+H]=663

### Preparation Example 10

### Synthesis of Compound 49

The same procedure as the method of the aforementioned compound 26 was carried out by using 6.5 g of synthesized intermediate 2-A-2 (14.1 mmol) and 4.7 g of synthesized intermediate 1-E-3 (14.9 mmol) to obtain 7.7 g of compound 49 (yield 82.7%). [M+H]=740

### Preparation Example 11

### Synthesis of Compound 58

The same procedure as the method of the aforementioned compound 26 was carried out by using 8.3 g of synthesized intermediate 2-C-2 (18.1 mmol) and 6.8 g of synthesized intermediate 1-E-2 (19.0 mmol) to obtain 10.8 g of compound 58 (yield 76.3%). [M+H]=780

### Preparation Example 12

### Synthesis of Compound 67

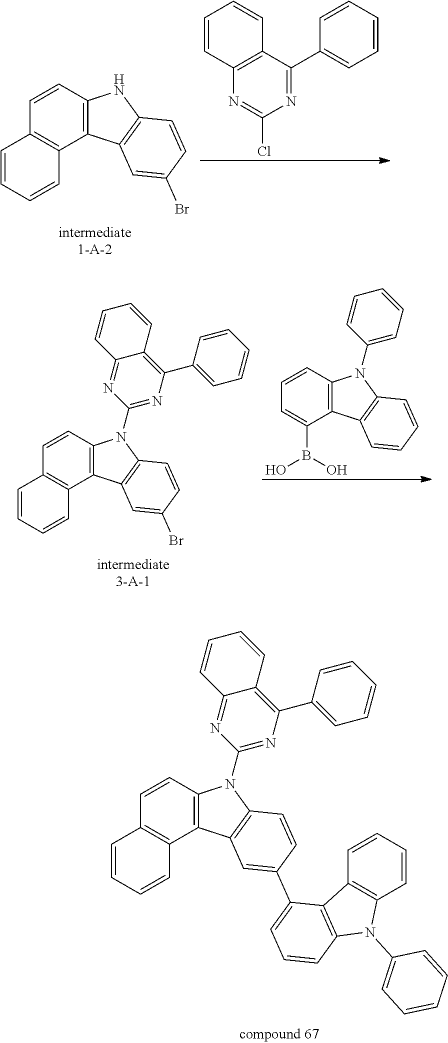

### 1) Synthesis of Intermediate 3-A-1

The same procedure as the method of the aforementioned compound 26 was carried out by using 7 g of synthesized intermediate 1-A-2 (15.2 mmol) and 5.9 g of synthesized intermediate 1-E-1 (24 mmol) to obtain 7.2 g of intermediate 3-A-1 (yield 94.7%). [M]=500

### 2) Synthesis of Compound 67

The same procedure as the method of the aforementioned intermediate 1-B-1 was carried out by using 7 g of synthesized intermediate 3-A-1 (14.0 mmol) and 9-phenyl-9H-carbazol-4-yl boronic acid (CAS#1370555-65-9, 4.2 g, 14.7 mmol) to obtain 7 g of compound 67 (yield 70%). [M+H]=663

### Preparation Example 13

### Synthesis of Compound 71

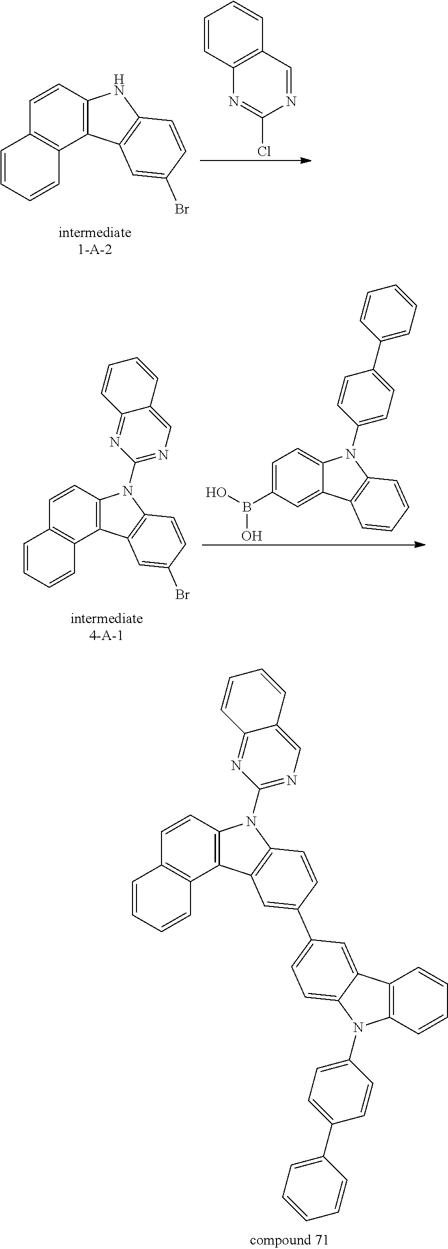 [SMILES: Brc1ccc2[nH]c3ccc4ccccc4c3c2c1 ; Clc1ncc2ccccc2n1 ; Brc1ccc2c(c1)c1c3ccccc3ccc1n2-c1ncc2ccccc2n1 ; OB(O)c1ccc2c(c1)c1ccccc1n2-c1ccc(-c2ccccc2)cc1 ; c1ccc(-c2ccc(-n3c4ccccc4c4cc(-c5ccc6c(c5)c5c7ccccc7ccc5n6-c5ncc6ccccc6n5)ccc43)cc2)cc1]

### 1) Synthesis of Intermediate 4-A-1

The same procedure as the method of the aforementioned compound 26 was carried out by using 10 g of synthesized intermediate 1-A-2 (33.8 mmol) and 2-chloroquinazoline (CAS#6141-13-5, 5.8 g, 35.4 mmol) to obtain 13.3 g of intermediate 4-A-1 (yield 92.3%). [M]=424

### 2) Synthesis of Compound 71

The same procedure as the method of the aforementioned intermediate 1-B-1 was carried out by using 10 g of synthesized intermediate 4-A-1 (23.6 mmol) and 4-biphenyl-9H-carbazolyl-3-boronic acid (CAS#1028648-22-7, 9.0 g, 24.7 mmol) to obtain 17 g of compound 71 (yield 79.3%). [M+H]=663

### Preparation Example 14

### Synthesis of Compound 97

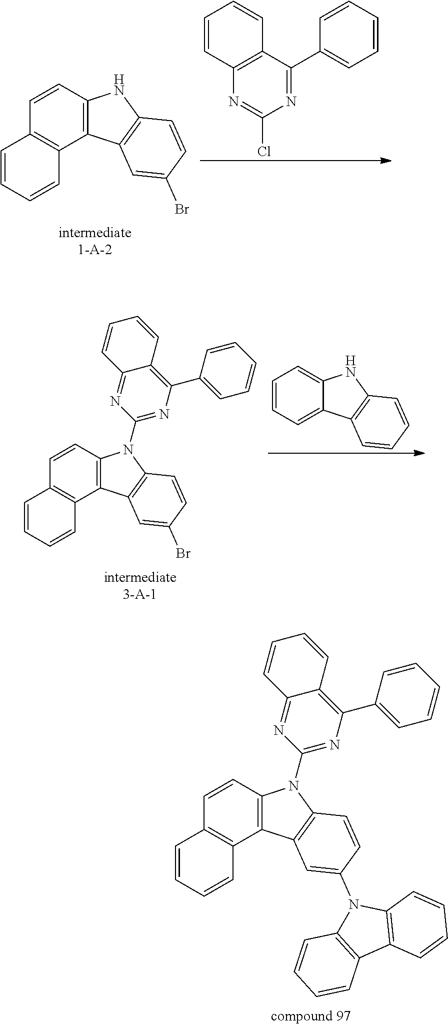

10 g of synthesized intermediate 3-A-1 (20.0 mmol), 9H-carbazole (CAS#86-74-8, 3.5 g, 21 mmol), and 8.5 g of K₃PO₄ (40 mmol) were put into 70 ml of xylene, and heated and refluxed for 1 hour under nitrogen atmosphere. After one hour, bis(dibenzylideneacetone)palladium(o) (Pd(dba)₂ (hereinafter), CAS#32005-36-0, 0.34 g, 0.6 mmol) and 4,5-bis(diphenylphosphinyl)-9,9-dimethylxathene (xanphos (hereinafter), CAS#161265-03-8, 0.34 g, 0.6 mmol) were simultaneously put into the reaction solution, and heated and refluxed for one day. After the reaction was finished, cooling to room temperature was carried out, an excessive amount of EtOH was put to generate the precipitate and thus filter the precipitate. The filtered precipitate was agitated with an excessive amount of water and THF, and then recrystallized with EA to obtain 8 g of compound 97 (yield 69.1%). [M]=586

### Preparation Example 15

### Synthesis of Compound 98

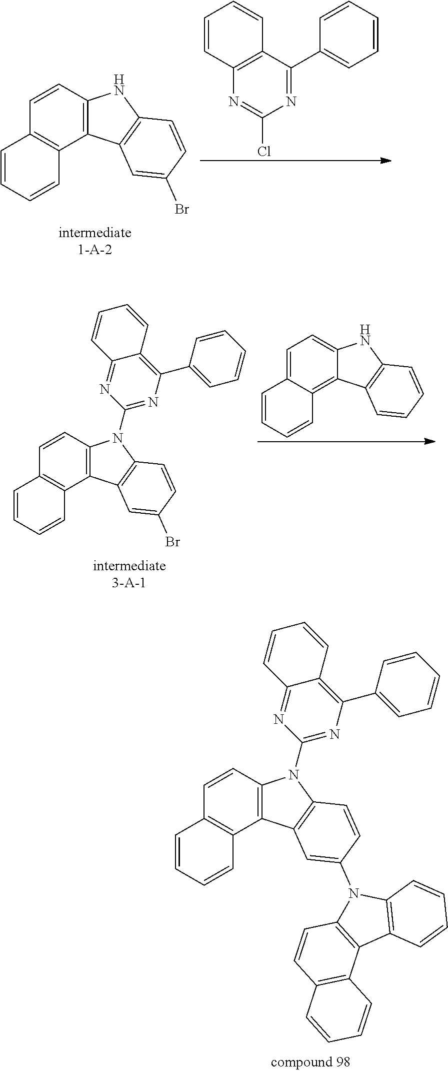

The same procedure as the method of the aforementioned compound 97 was carried out by using 10 g of synthesized intermediate 3-A-1 (20 mmol) and 7H-benzo[c]carbazole (CAS#205-25-4, 4.6 g, 21 mmol) to obtain 7.7 g of compound 98 (yield 58.4%). [M+H]=663

### Preparation Example 16

### Synthesis of Compound 99

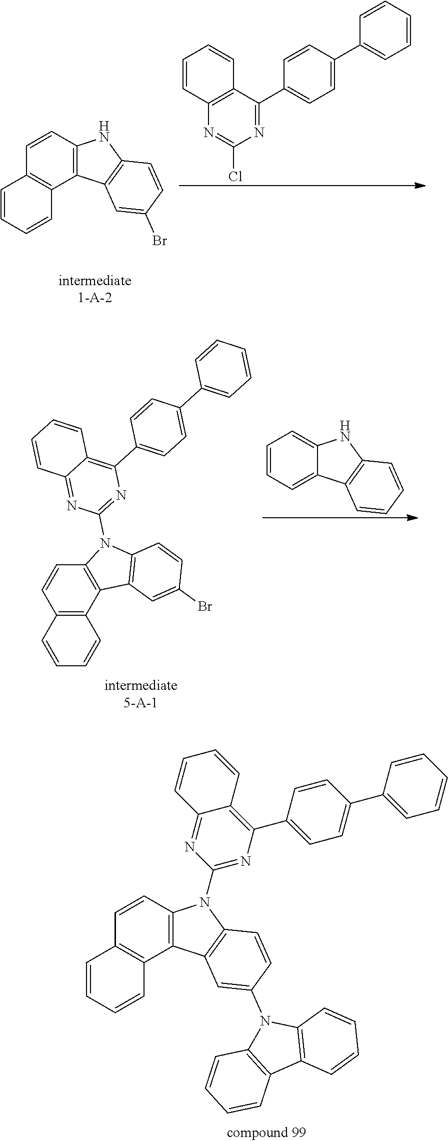 [SMILES: Brc1ccc2[nH]c3ccc4ccccc4c3c2c1 ; Clc1nc(-c2ccc(-c3ccccc3)cc2)c2ccccc2n1 ; Brc1ccc2c(c1)c1c3ccccc3ccc1n2-c1nc(-c2ccc(-c3ccccc3)cc2)c2ccccc2n1 ; c1ccc2c(c1)[nH]c1ccccc12 ; c1ccc(-c2ccc(-c3nc(-n4c5ccc(-n6c7ccccc7c7ccccc76)cc5c5c6ccccc6ccc54)nc4ccccc34)cc2)cc1]

### 1) Synthesis of Intermediate 5-A-1

The same procedure as the method of the aforementioned compound 26 was carried out by using 10 g of synthesized intermediate 1-A-2 (33.8 mmol) and 11 g of intermediate 1-E-2 (35.4 mmol) to obtain 18.1 g of intermediate 5-A-1 (yield 90.4%). [M]=576

### 2) Synthesis of Compound 99

The same procedure as the method of the aforementioned compound 97 was carried out by using 15 g of synthesized intermediate 5-A-1 (26 mmol) to obtain 10.6 g of compound 99 (yield 61.3%). [M+H]=663

### Preparation Example 17

### Synthesis of Compound 115

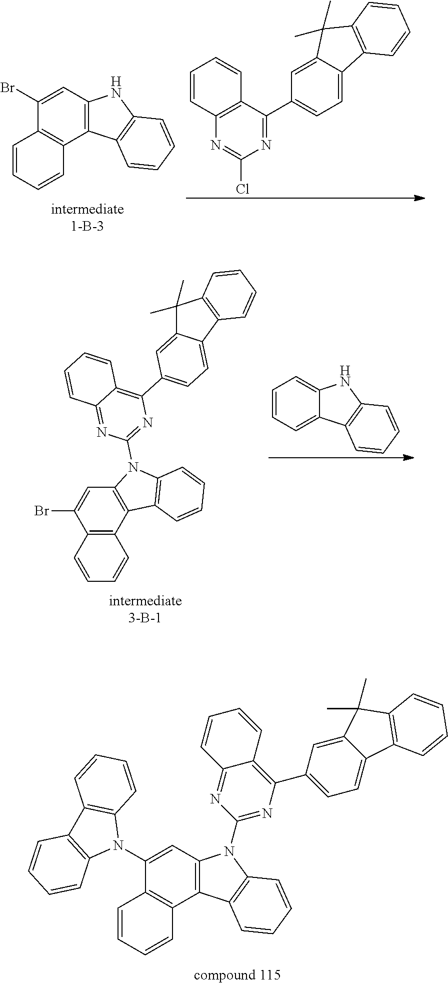

### 1) Synthesis of Intermediate 3-B-1

The same procedure as the method of the aforementioned compound 26 was carried out by using 7 g of synthesized intermediate 1-B-3 (23.6 mmol) and 8.9 g of intermediate 1-E-4 (24.8 mmol) to obtain 13.9 g of intermediate 3-B-1 (yield 95.4%). [M]=616

### 2) Synthesis of Compound 115

The same procedure as the method of the aforementioned compound 97 was carried out by using 10 g of synthesized intermediate 3-B-1 (16.2 mmol) to obtain 8.5 g of compound 115 (yield 74.2%). [M+H]=703

### Preparation Example 18

### Synthesis of Compound 123

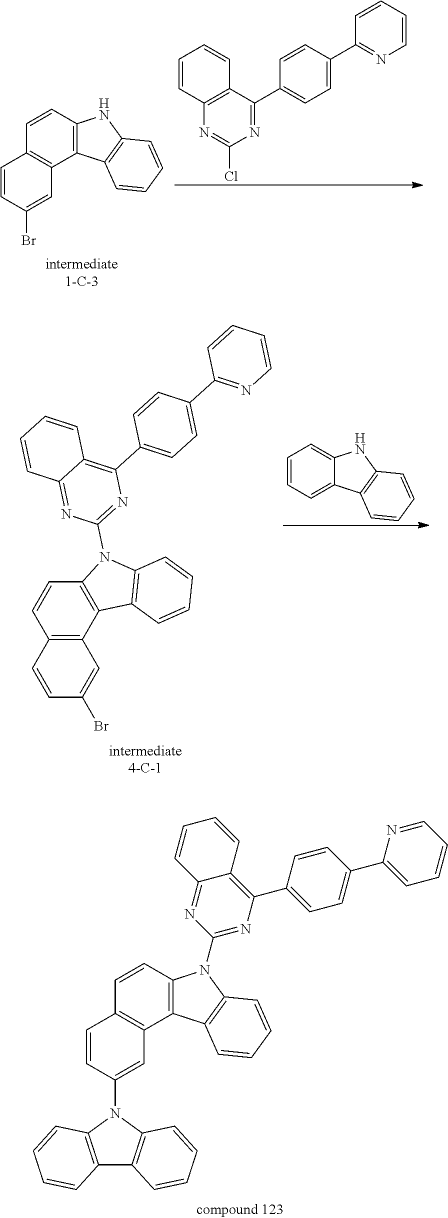 [SMILES: Brc1ccc2ccc3[nH]c4ccccc4c3c2c1 ; Clc1nc(-c2ccc(-c3ccccn3)cc2)c2ccccc2n1 ; Brc1ccc2ccc3c(c2c1)c1ccccc1n3-c1nc(-c2ccc(-c3ccccn3)cc2)c2ccccc2n1 ; c1ccc2c(c1)[nH]c1ccccc12 ; c1ccc(-c2ccc(-c3nc(-n4c5ccccc5c5c6cc(-n7c8ccccc8c8ccccc87)ccc6ccc54)nc4ccccc34)cc2)nc1]

### 1) Synthesis of Intermediate 4-C-1

The same procedure as the method of the aforementioned compound 26 was carried out by using 7 g of synthesized intermediate 1-C-3 (23.6 mmol) and 7.9 g of intermediate 1-E-3 (24.8 mmol) to obtain 12.8 g of intermediate 4-C-1 (yield 94.1%). [M]=577

### 2) Synthesis of Compound 123

The same procedure as the method of the aforementioned compound 97 was carried out by using 10 g of synthesized intermediate 4-C-1 (17.3 mmol) to obtain 8.3 g of compound 123 (yield 71.9%). [M+H]=664

### Preparation Example 19

### Synthesis of Compound 137

The same procedure as the method of the aforementioned compound 26 was carried out by using 17.4 g of synthesized intermediate 2-A-1 (37.9 mmol) and 11 g of synthesized intermediate 1-E-5 (37.9 mmol) to obtain 21.0 g of compound 137 (yield 77.6%). [M+H]=713

### Preparation Example 20

### Synthesis of Compound 141

The same procedure as the synthesis method of compound 11 was carried out by using 7 g of synthesized intermediate 2-A-1 (15.3 mmol) and 5.1 g of synthesized intermediate 2-E-1 (16.0 mmol) to obtain 5.5 g of compound 141 (yield 48.7%). [M+H]=739

### Example

The glass substrate (corning 7059 glass) on which a thin film of indium tin oxide (ITO) was applied in a thickness of 1,000 Å was put into distilled water having the dispersing agent dissolved therein, and washed with ultrasonic waves. The detergent used herein was a product commercially available from Fisher Co., and distilled water was one which had been twice filtered by using a filter commercially available from Millipore Co. ITO was washed for 30 minutes, and washing with ultrasonic waves was then repeated twice for 10 minutes by using distilled water. After washing with distilled water was finished, washing with ultrasonic waves was performed by using isopropyl alcohol, acetone, and methanol solvents in the order, and drying was performed.

Hexanitrile hexaazatriphenylene (HAT-CN) was vacuum deposited by heat in a thicknesses of 500 Å on the ITO transparent electrode thus prepared to form the hole injecting layer. After HT1 (400 Å) transporting holes was vacuum deposited thereon, the compound described in the following Table 1 as the host was deposited under the vacuum in a thickness of 300 Å together with the dopant Dp-6 compound as the light emitting layer. Thereafter, the E1 compounds (300 Å) were sequentially vacuum deposited by heat as electron injection and transport layers. On the electron injection and transport layers, lithium fluoride (LiF) in a thickness of 12 Å and aluminum in a thickness of 2,000 Å were subsequently deposited to form the cathode, thereby manufacturing the organic light emitting device.

In the aforementioned process, the deposition speed of the organic material was maintained at 1 Å/sec, the deposition speed of LiF was maintained at 0.2 Å/sec, and the deposition speed of aluminum was maintained at 3 Å/sec to 7 Å/sec.

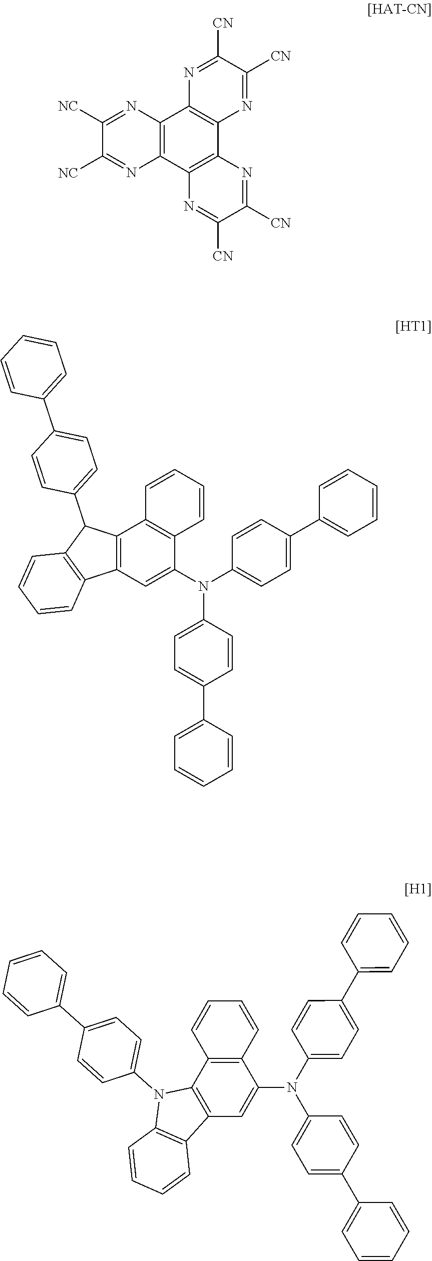 [SMILES: N#Cc1nc2c3nc(C#N)c(C#N)nc3c3nc(C#N)c(C#N)nc3c2nc1C#N ; c1ccc(-c2ccc(C3c4ccccc4-c4cc(N(c5ccc(-c6ccccc6)cc5)c5ccc(-c6ccccc6)cc5)c5ccccc5c43)cc2)cc1 ; c1ccc(-c2ccc(N(c3ccc(-c4ccccc4)cc3)c3cc4c5ccccc5n(-c5ccc(-c6ccccc6)cc5)c4c4ccccc34)cc2)cc1]

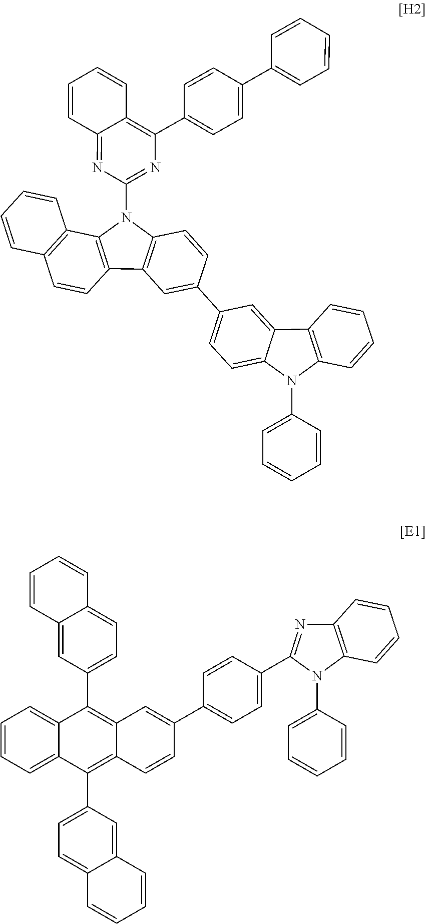 [SMILES: c1ccc(-c2ccc(-c3nc(-n4c5ccc(-c6ccc7c(c6)c6ccccc6n7-c6ccccc6)cc5c5ccc6ccccc6c54)nc4ccccc34)cc2)cc1 ; c1ccc(-n2c(-c3ccc(-c4ccc5c(-c6ccc7ccccc7c6)c6ccccc6c(-c6ccc7ccccc7c6)c5c4)cc3)nc3ccccc32)cc1]

Examples of evaluation of the devices with respect to each material are described below.

TABLE 1

| | | Actuating | Current | Power | | | |
|---|---|---|---|---|---|---|---|
| | | voltage | efficiency | efficiency | Lifespan | X | Y |
| | Compound | (V) | (cd/A) | (lm/w) | (T95@10 mA) | coordinate | coordinate |
| Comparative | H1 | 4.71 | 23.76 | 16.32 | 73 | 0.666 | 0.332 |
| Example | H2 | 5.32 | 22.21 | 13.50 | 93 | 0.661 | 0.331 |
| Example | 26 | 5.00 | 22.95 | 14.20 | 255 | 0.658 | 0.337 |
| | 27 | 5.17 | 24.20 | 14.71 | 310 | 0.660 | 0.338 |
| | 28 | 4.95 | 25.41 | 15.00 | 250 | 0.655 | 0.344 |
| | 32 | 4.94 | 23.00 | 15.00 | 315 | 0.663 | 0.335 |
| | 37 | 5.15 | 24.22 | 13.74 | 280 | 0.662 | 0.335 |
| | 42 | 5.20 | 23.88 | 13.20 | 260 | 0.661 | 0.334 |
| | 52 | 4.92 | 24.21 | 15.11 | 299 | 0.657 | 0.332 |
| | 97 | 5.69 | 25.25 | 14.11 | 199 | 0.660 | 0.336 |
| | 99 | 5.28 | 24.06 | 14.67 | 245 | 0.662 | 0.336 |
| | 98 | 5.52 | 23.55 | 13.41 | 185 | 0.662 | 0.336 |
| | 115 | 5.18 | 23.64 | 12.89 | 263 | 0.657 | 0.337 |

What is claimed is:

1. A compound that is represented by the following Formula 1: 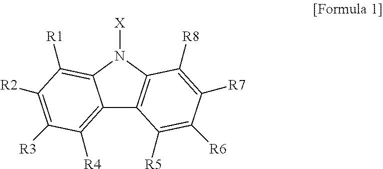
wherein in Formula 1, R3 and R4 are bonded to each other to form an aromatic ring,
at least one of a group at which an aromatic ring is not formed among R1 to R4, a substituent group that is substituted at an aromatic ring that is formed by bonding R3 and R4 to each other, and R5 to R8 is -(L1)p-(Y1)q, herein, p is an integer of 0 to 10, q is an integer of 1 to 10, the remains are each independently -(L2)r-(Y2)s, herein, r is an integer of 0 to 10, and s is an integer of 1 to 10,
X is -(A)m-(B)n, herein, m is an integer of 0 to 10, and n is independently an integer of 1 to 10,
A is an arylene group having 6 to 12 carbon atoms; an alkenylene group; a fluorenylene group; or a heteroarylene group including one or more of N, O, and S atoms,
in the case where m is 0, B is hydrogen; deuterium; an alkyl group; an alkenyl group; a silyl group; a boron group; an aryl group having 6 to 12 carbon atoms; a fluorenyl group; or a hetero ring group including one or more of N, O, and S atoms, in the case where m is not 0, B is hydrogen; deuterium; a halogen group; a nitrile group; a nitro group; a hydroxy group; an alkyl group; a cycloalkyl group; an alkoxy group; an alkylthioxy group; an alkylsulfoxy group; an alkenyl group; a silyl group; a boron group; an aryl group having 6 to 12 carbon atoms; a fluorenyl group; or a hetero ring group including one or more of N, O, and S atoms and unsubstituted or substituted by an aryl group having 6 to 12 carbon atoms,
L1 and L2 are the same as or different from each other, and are each independently an arylene group having 6 to 12 carbon atoms; an alkenylene group; a fluorenylene group; a carbazolylene group; or a heteroarylene group including one or more of N, O, and S atoms,
Y1 is a carbazole group unsubstituted or substituted by at least one of a phenyl group, a biphenyl group, a terphenyl group, a naphthyl group, an anthracenyl group, a phenanthryl group, a perylenyl group, a chrysenyl group, a hetero ring group, and an alkylamine group; or a benzocarbazole group unsubstituted or substituted by at least one of a phenyl group, a biphenyl group, a terphenyl group, a naphthyl group, an anthracenyl group, a phenanthryl group, a perylenyl group, a chrysenyl group, a hetero ring group, and an alkylamine group,
Y2 is hydrogen; deuterium; a halogen group; a nitrile group; a nitro group; a hydroxy group; an alkyl group; a cycloalkyl group; an alkoxy group; an alkylthioxy group; an alkylsulfoxy group; an alkenyl group; a silyl group; a boron group; an alkylamine group; a fluorenyl group; a carbazole group; or a hetero ring group including one or more of N, O, and S atoms, and
in the case where two or more of A, B, L1, L2, Y1, or Y2 are provided, they are the same as or different from each other.

2. The compound of claim 1, wherein Y1 is any one of the following Formulas 2 to 5: 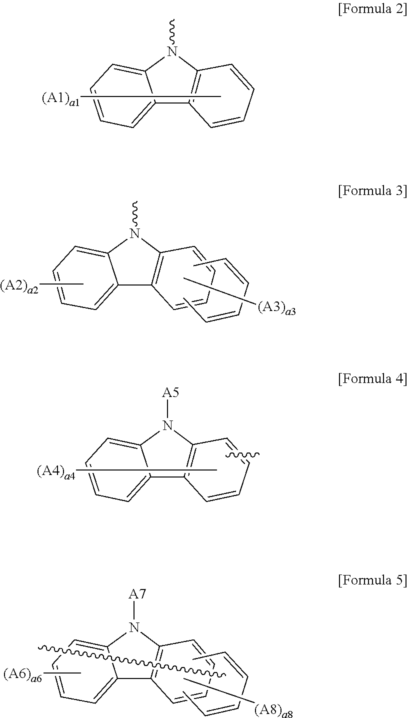
wherein in Formulas 2 to 5, A1 to A8 are each independently a phenyl group, a biphenyl group, a terphenyl group, a naphthyl group, an anthracenyl group, a phenanthryl group, a perylenyl group, a chrysenyl group, a hetero ring group, or an alkylamine group, a1 is an integer of 0 to 8, a2 is an integer of 0 to 4, a3 is an integer of 0 to 6, a4 is an integer of 0 to 7, a6 is an integer of 0 to 4, a8 is an integer of 0 to 6, 0≦a6+a8≦9, and
in the case where two or more of A1, A2, A3, A4, A6, and A8 are provided, they are the same as or different from each other.

3. The compound of claim 2, wherein A5 and A7 are each independently a phenyl group, a biphenyl group, a terphenyl group, a naphthyl group, an anthracenyl group, a phenanthryl group, a perylenyl group, or a chrysenyl group.

4. The compound of claim 1, wherein the compound represented by Formula 1 is represented by the following Formula 6: 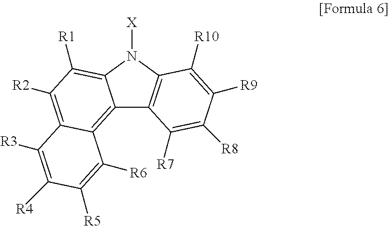
wherein in Formula 6, at least one of R1 to R10 is -(L1)p-(Y1)q, the remains are each independently -(L2)r-(Y2)s, and herein, X, L1, L2, Y1, Y2, p, q, r, and s are the same as those defined by Formula 1.

5. The compound of claim 1, wherein L1 and L2 are a direct bond.

6. The compound of claim 1, wherein Y2 is hydrogen.

7. The compound of claim 1, wherein the compound represented by Formula 1 is represented by any one of the following Formulas 7 to 14: 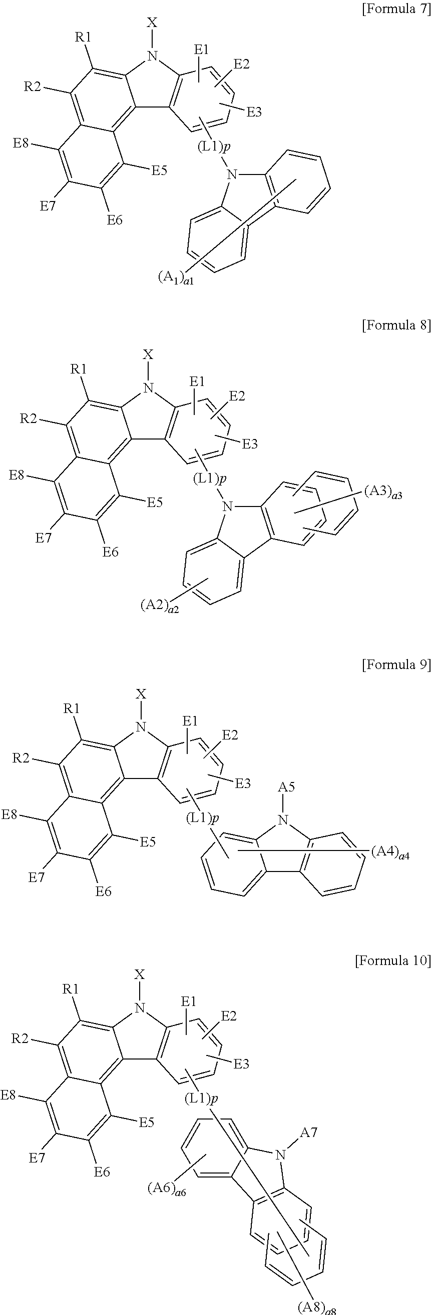 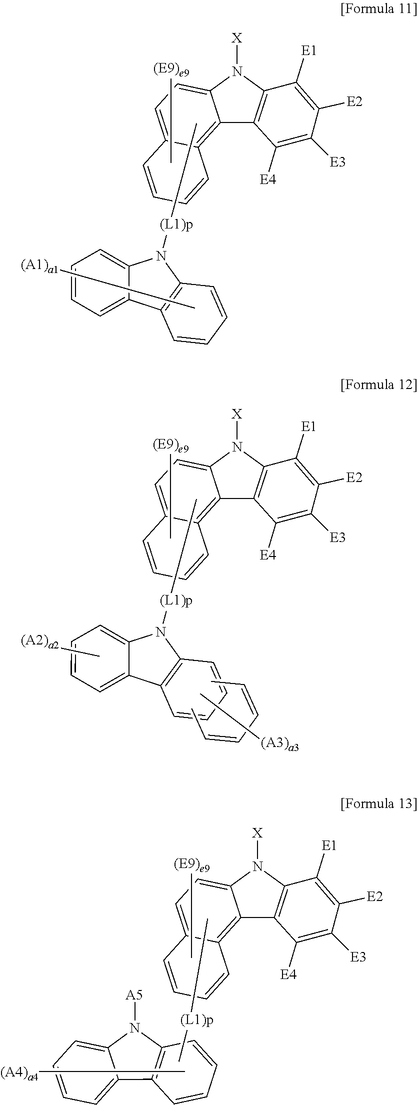 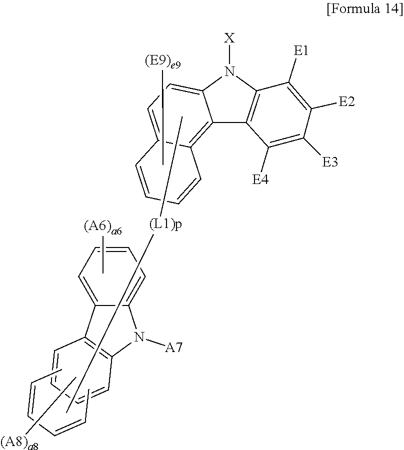
wherein in Formulas 7 to 14, R1, R2, and E1 to E9 are each independently -(L1)p-(Y1)q or -(L2)r-(Y2)s,
wherein A1 to A8 are each independently a phenyl group, a biphenyl group, a terphenyl group, a naphthyl group, an anthracenyl group, a phenanthryl group, a perylenyl group, a chrysenyl group, a hetero ring group, or an alkylamine group, a1 is an integer of 0 to 8, a2 is an integer of 0 to 4, a3 is an integer of 0 to 6, a4 is an integer of 0 to 7, a6 is an integer of 0 to 4, a8 is an integer of 0 to 6, 0≦a6+a8≦9, e9 is an integer of 0 to 5,
in the case where two or more of A1, A2, A3, A4, A6, A8, and E9 are provided, they are the same as or different from each other, and
herein, X, L1, L2, Y1, Y2, p, q, r, and s are the same as those defined by Formula 1.

8. The compound of claim 7, wherein A5 and A7 are each independently a phenyl group, a biphenyl group, a terphenyl group, a naphthyl group, an anthracenyl group, a phenanthryl group, a perylenyl group, or a chrysenyl group.

9. The compound of claim 7, wherein at least one of R1, R2, and E1 to E9 is hydrogen.

10. The compound of claim 1, wherein A is an arylene group having 6 to 12 carbon atoms; or a heteroarylene group including one or more of N, O, and S atoms, in the case where m is 0, B is an aryl group having 6 to 12 carbon atoms; a fluorenyl group; or a hetero ring group including one or more of N, O, and S atoms, and in the case where m is not 0, B is hydrogen; a nitrile group; a silyl group; an aryl group having 6 to 12 carbon atoms; a fluorenyl group; or a hetero ring group including one or more of N, O, and S atoms and unsubstituted or substituted by an aryl group having 6 to 12 carbon atoms.

11. The compound of claim 1, wherein m is an integer of 0 to 2, and n is 1.

12. The compound of claim 1, wherein the compound represented by Formula 1 is represented by any one of the following Formulas 15 to 30: 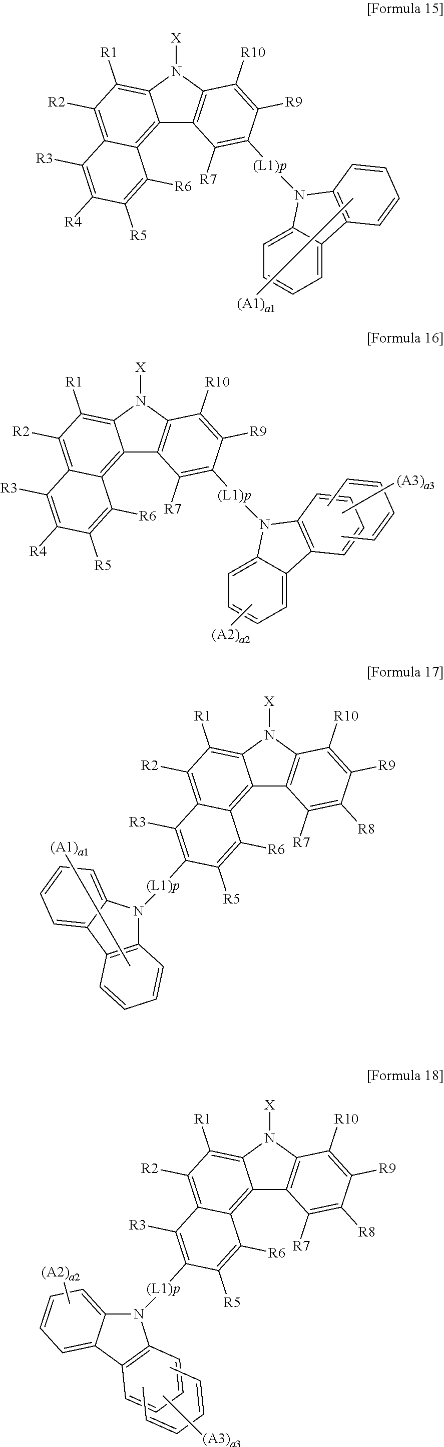 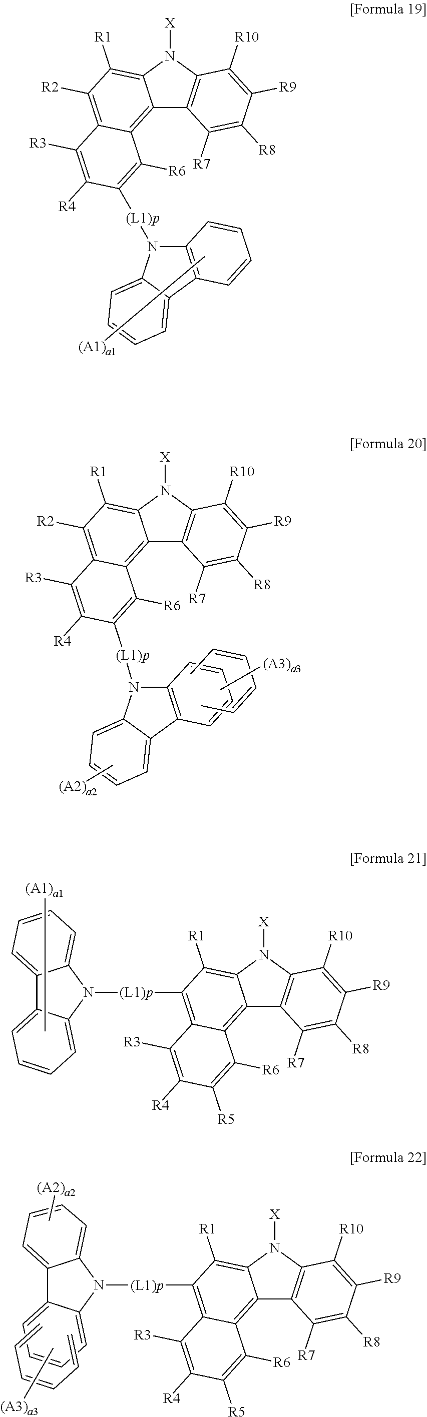 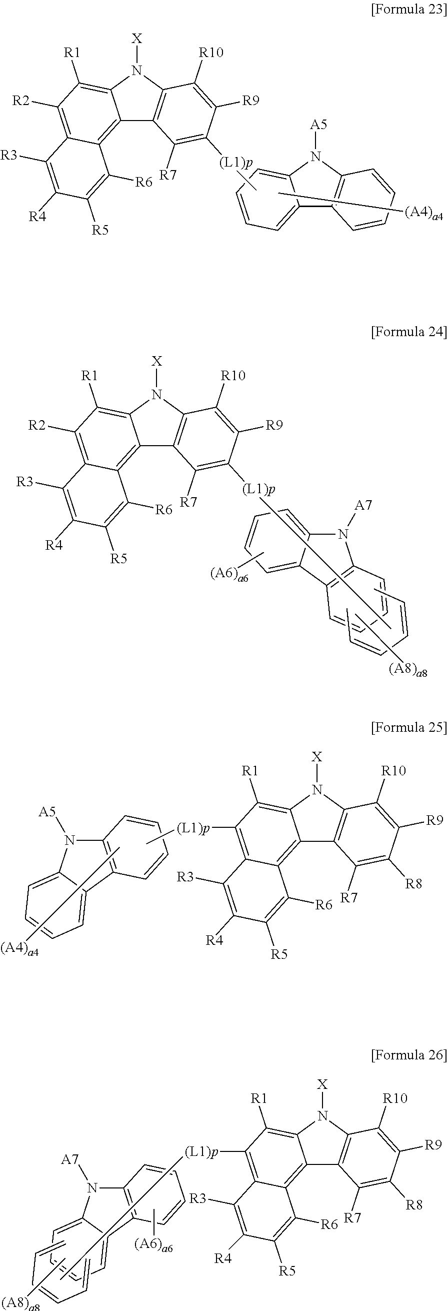 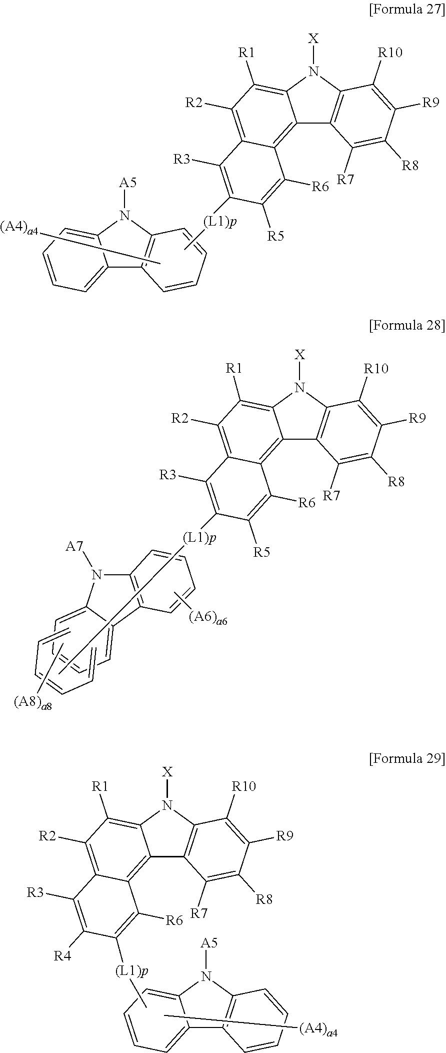 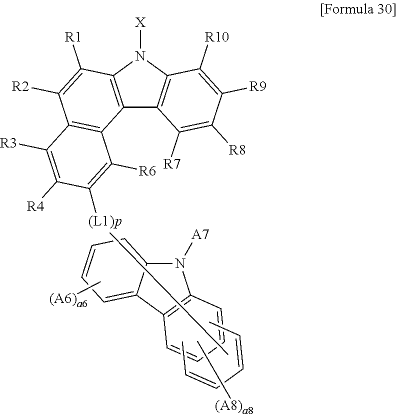
wherein in Formulas 15 to 30, R1 to R10 are each independently -(L1)p-(Y1)q or -(L2)r-(Y2)s,
A1 to A8 are each independently a phenyl group, a biphenyl group, a terphenyl group, a naphthyl group, an anthracenyl group, a phenanthryl group, a perylenyl group, a chrysenyl group, a hetero ring group, or an alkylamine group, a1 is an integer of 0 to 8, a2 is an integer of 0 to 4, a3 is an integer of 0 to 6, a4 is an integer of 0 to 7, a6 is an integer of 0 to 4, a8 is an integer of 0 to 6, 0≦a6+a8≦9,
in the case where two or more of A1, A2, A3, A4, A6, and A8 are provided, they are the same as or different from each other, and
herein, X, L1, L2, Y1, Y2, p, q, r, and s are the same as those defined by Formula 1.

13. The compound of claim 1, wherein the compound represented by Formula 1 is represented by any one of the following Formulas 31 to 38: 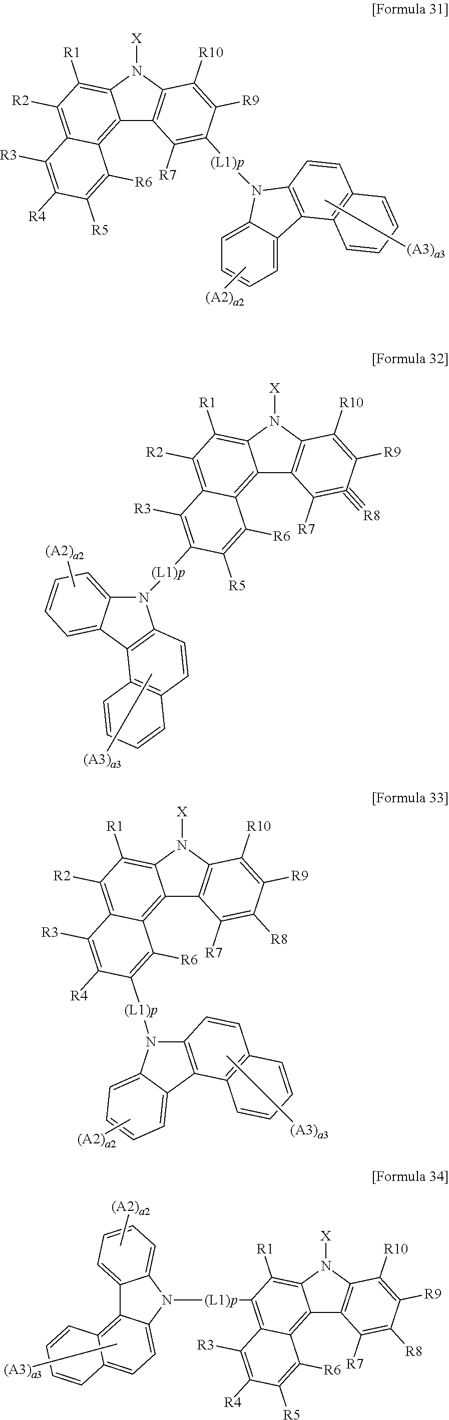 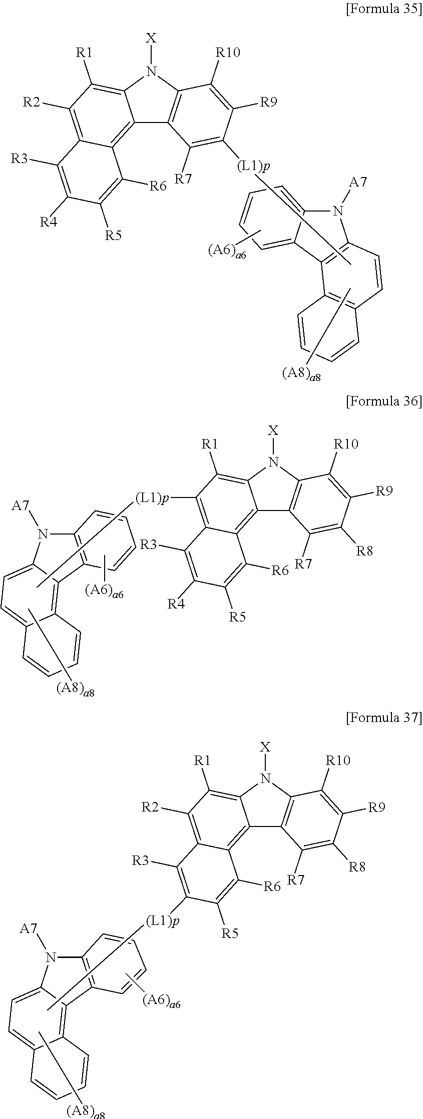 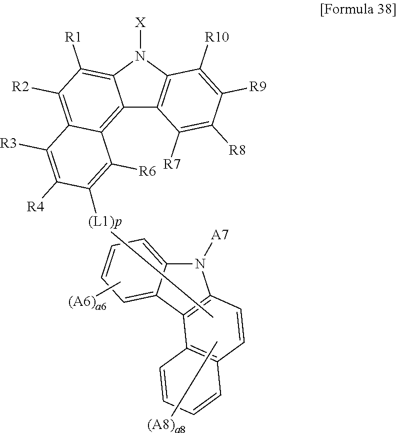 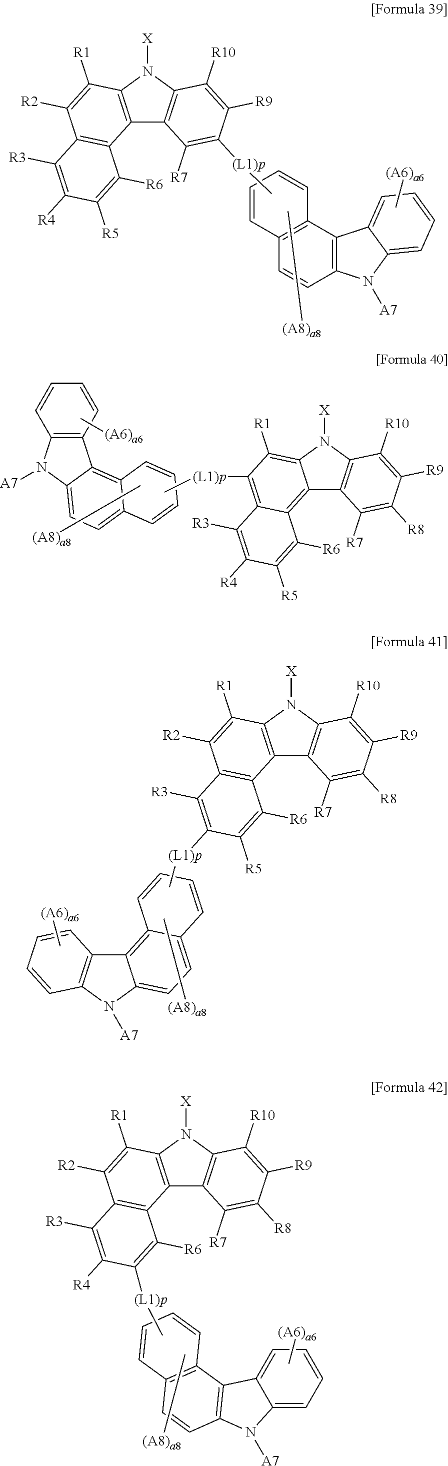
wherein in Formulas 31 to 42, R1 to R10 are each independently -(L1)p-(Y1)q or -(L2)r-(Y2)s,
A2, A3 and A6 to A8 are each independently a phenyl group, a biphenyl group, a terphenyl group, a naphthyl group, an anthracenyl group, a phenanthryl group, a perylenyl group, a chrysenyl group, a hetero ring group, or an alkylamine group, a2 is an integer of 0 to 4, a3 is an integer of 0 to 6, a6 is an integer of 0 to 4, a8 is an integer of 0 to 6, 0≦a6+a8≦9,
in the case where two or more of A2, A3, A6 and A8 are provided, they are the same as or different from each other, and
herein, X, L1, L2, Y1, Y2, p, q, r, and s are the same as those defined by Formula 1.

14. The compound of claim 1, wherein the heteroarylene group of A is a heteroarylene group including one or more N atoms.

15. The compound of claim 1, wherein the heteroarylene group of A is a divalent quinazoline group, a divalent carbazole group, or a divalent pyridine group.

16. The compound of claim 1, wherein X of Formula 1 is selected from substituent groups described in the following [Table A-1]:
TABLE A-1

| | |
|---|---|
| 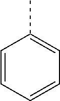 | 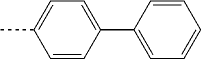 |
| 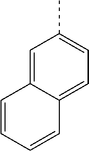 | 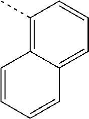 |
| 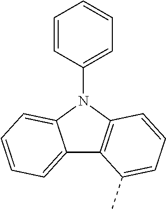 | 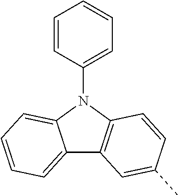 |
| 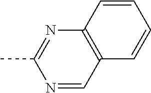 | 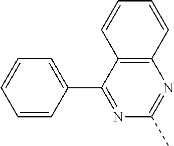 |

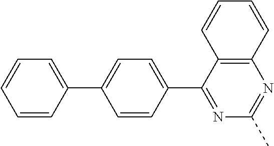

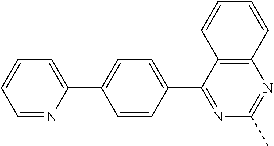

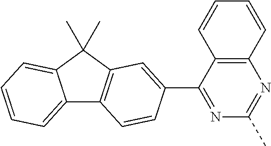

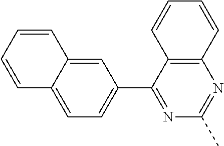

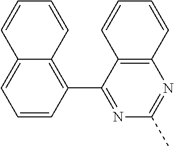
| | |
|---|---|
| 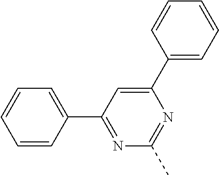 | 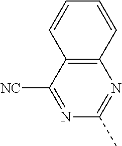 |
| 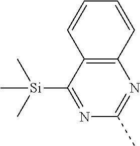 | |

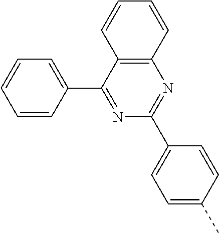

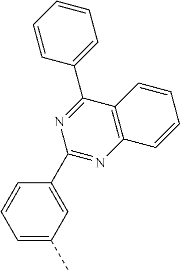

17. The compound of claim 1, wherein -(L1)ₚ—(Y1)_{q} of Formula 1 is selected from substituent groups described in the following [Table Y-1]:
TABLE Y-1
—(L1)p—(Y1)q

| | |
|---|---|
| 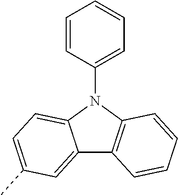 | 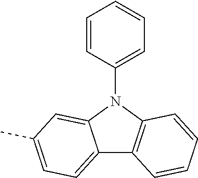 |
| 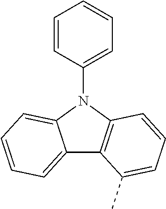 | 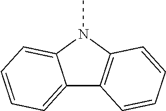 |
| 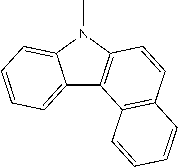 [SMILES: Cn1c2ccccc2c2c3ccccc3ccc21] | 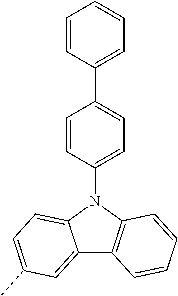 |
| 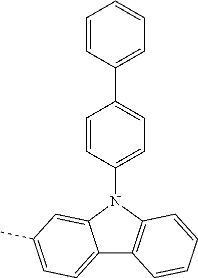 | 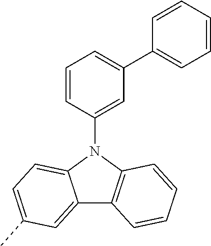 |

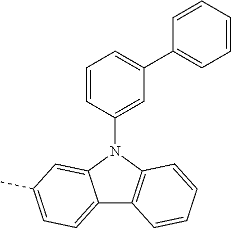

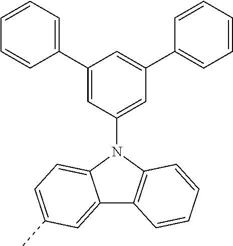

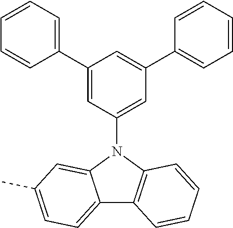

18. The compound of claim 1, wherein the compound represented by Formula 1 is represented by any one of the following Formulas:

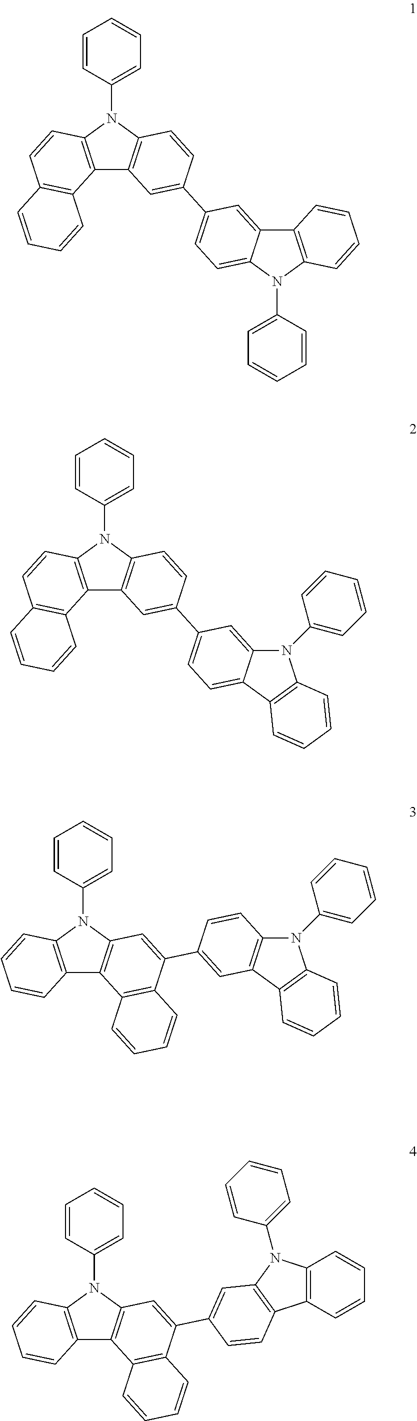 [SMILES: c1ccc(-n2c3ccccc3c3cc(-c4ccc5c(c4)c4c6ccccc6ccc4n5-c4ccccc4)ccc32)cc1 ; c1ccc(-n2c3ccccc3c3ccc(-c4ccc5c(c4)c4c6ccccc6ccc4n5-c4ccccc4)cc32)cc1 ; c1ccc(-n2c3ccccc3c3cc(-c4cc5c(c6ccccc46)c4ccccc4n5-c4ccccc4)ccc32)cc1 ; c1ccc(-n2c3ccccc3c3ccc(-c4cc5c(c6ccccc46)c4ccccc4n5-c4ccccc4)cc32)cc1]

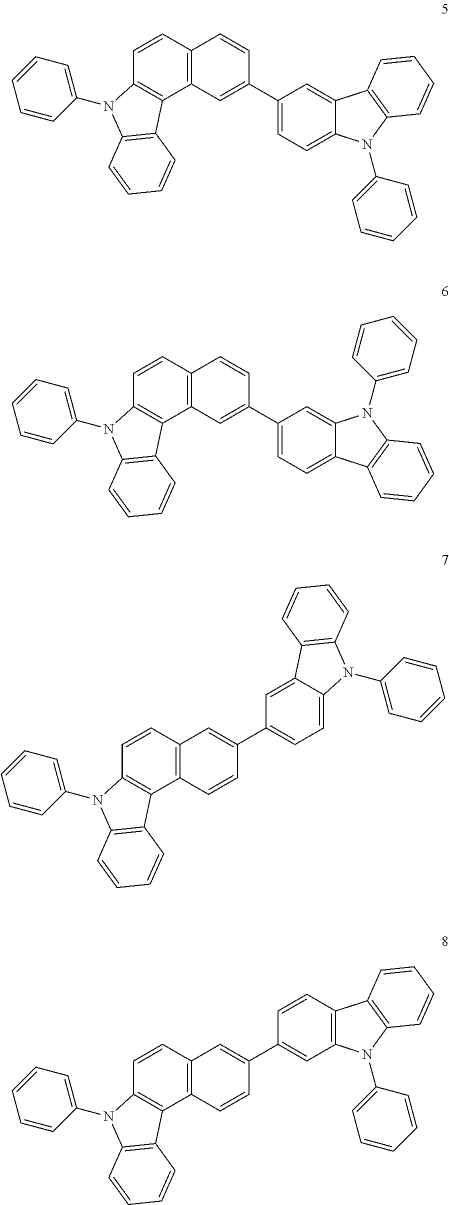 [SMILES: c1ccc(-n2c3ccccc3c3cc(-c4ccc5ccc6c(c5c4)c4ccccc4n6-c4ccccc4)ccc32)cc1 ; c1ccc(-n2c3ccccc3c3ccc(-c4ccc5ccc6c(c5c4)c4ccccc4n6-c4ccccc4)cc32)cc1 ; c1ccc(-n2c3ccccc3c3cc(-c4ccc5c(ccc6c5c5ccccc5n6-c5ccccc5)c4)ccc32)cc1 ; c1ccc(-n2c3ccccc3c3ccc(-c4ccc5c(ccc6c5c5ccccc5n6-c5ccccc5)c4)cc32)cc1]

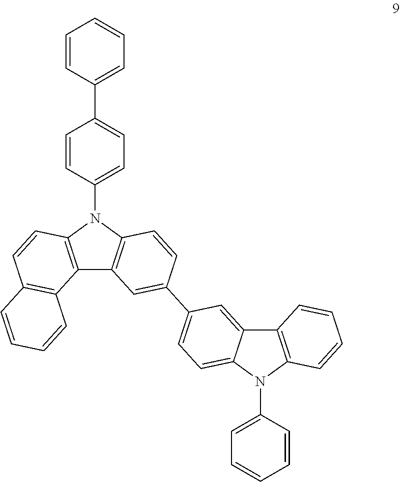 [SMILES: c1ccc(-c2ccc(-n3c4ccc(-c5ccc6c(c5)c5ccccc5n6-c5ccccc5)cc4c4c5ccccc5ccc43)cc2)cc1]

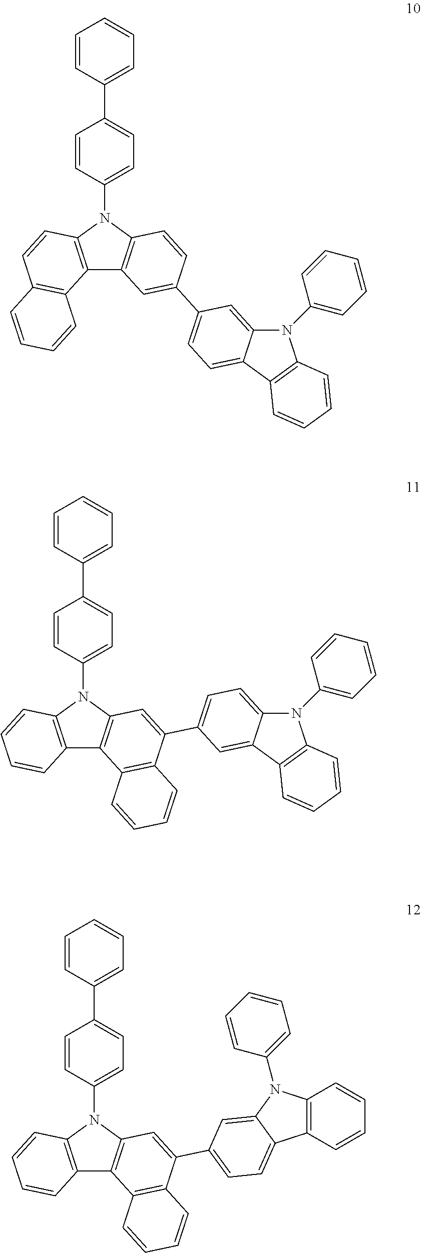 [SMILES: c1ccc(-c2ccc(-n3c4ccc(-c5ccc6c7ccccc7n(-c7ccccc7)c6c5)cc4c4c5ccccc5ccc43)cc2)cc1 ; c1ccc(-c2ccc(-n3c4ccccc4c4c5ccccc5c(-c5ccc6c(c5)c5ccccc5n6-c5ccccc5)cc43)cc2)cc1 ; c1ccc(-c2ccc(-n3c4ccccc4c4c5ccccc5c(-c5ccc6c7ccccc7n(-c7ccccc7)c6c5)cc43)cc2)cc1]

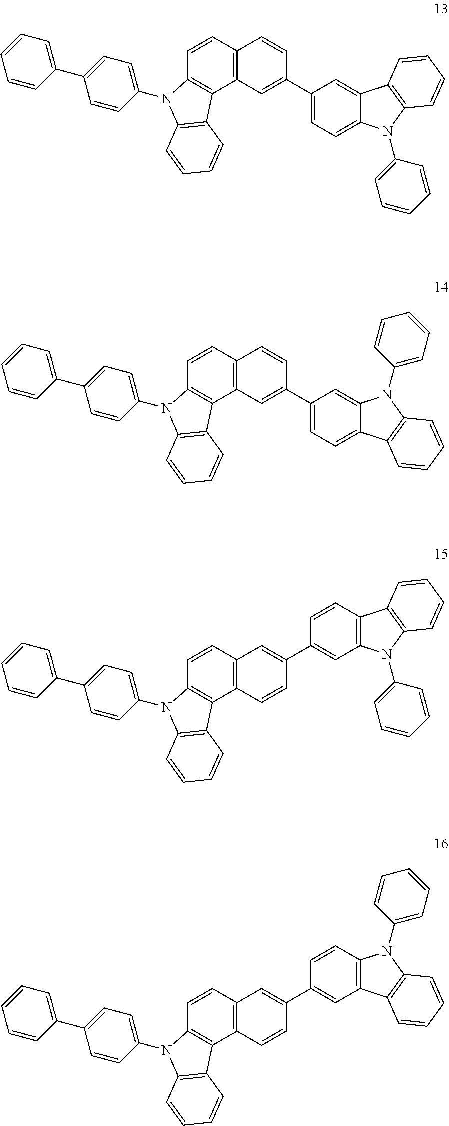 [SMILES: c1ccc(-c2ccc(-n3c4ccccc4c4c5cc(-c6ccc7c(c6)c6ccccc6n7-c6ccccc6)ccc5ccc43)cc2)cc1 ; c1ccc(-c2ccc(-n3c4ccccc4c4c5cc(-c6ccc7c8ccccc8n(-c8ccccc8)c7c6)ccc5ccc43)cc2)cc1 ; c1ccc(-c2ccc(-n3c4ccccc4c4c5ccc(-c6ccc7c8ccccc8n(-c8ccccc8)c7c6)cc5ccc43)cc2)cc1 ; c1ccc(-c2ccc(-n3c4ccccc4c4c5ccc(-c6ccc7c(c6)c6ccccc6n7-c6ccccc6)cc5ccc43)cc2)cc1]

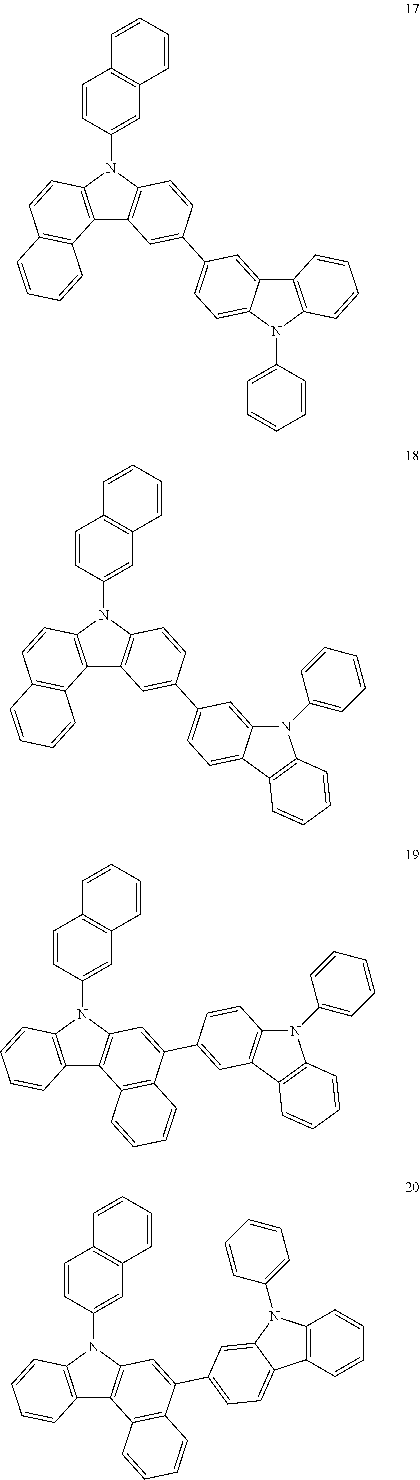 [SMILES: c1ccc(-n2c3ccccc3c3cc(-c4ccc5c(c4)c4c6ccccc6ccc4n5-c4ccc5ccccc5c4)ccc32)cc1 ; c1ccc(-n2c3ccccc3c3ccc(-c4ccc5c(c4)c4c6ccccc6ccc4n5-c4ccc5ccccc5c4)cc32)cc1 ; c1ccc(-n2c3ccccc3c3cc(-c4cc5c(c6ccccc46)c4ccccc4n5-c4ccc5ccccc5c4)ccc32)cc1 ; c1ccc(-n2c3ccccc3c3ccc(-c4cc5c(c6ccccc46)c4ccccc4n5-c4ccc5ccccc5c4)cc32)cc1]

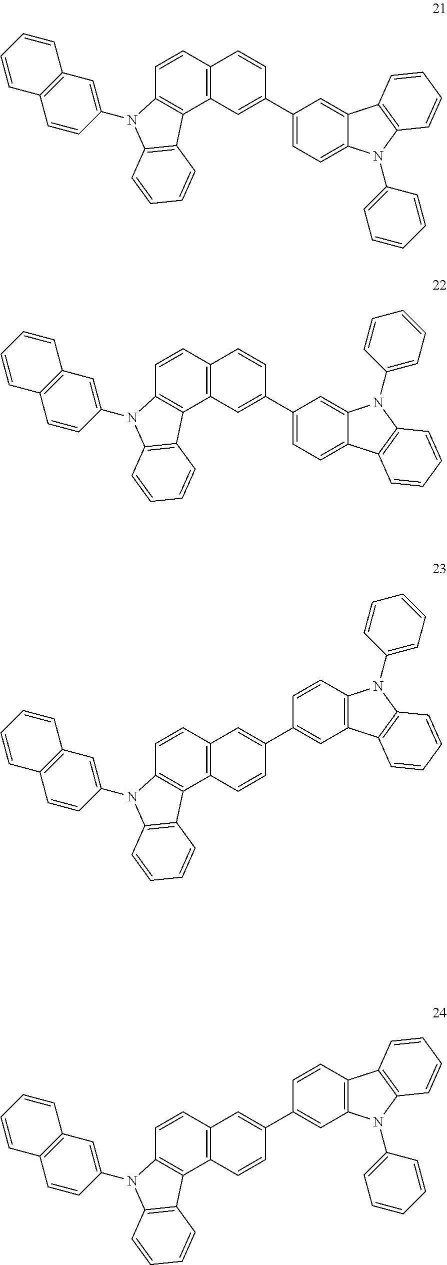 [SMILES: c1ccc(-n2c3ccccc3c3cc(-c4ccc5ccc6c(c5c4)c4ccccc4n6-c4ccc5ccccc5c4)ccc32)cc1 ; c1ccc(-n2c3ccccc3c3ccc(-c4ccc5ccc6c(c5c4)c4ccccc4n6-c4ccc5ccccc5c4)cc32)cc1 ; c1ccc(-n2c3ccccc3c3cc(-c4ccc5c(ccc6c5c5ccccc5n6-c5ccc6ccccc6c5)c4)ccc32)cc1 ; c1ccc(-n2c3ccccc3c3ccc(-c4ccc5c(ccc6c5c5ccccc5n6-c5ccc6ccccc6c5)c4)cc32)cc1]

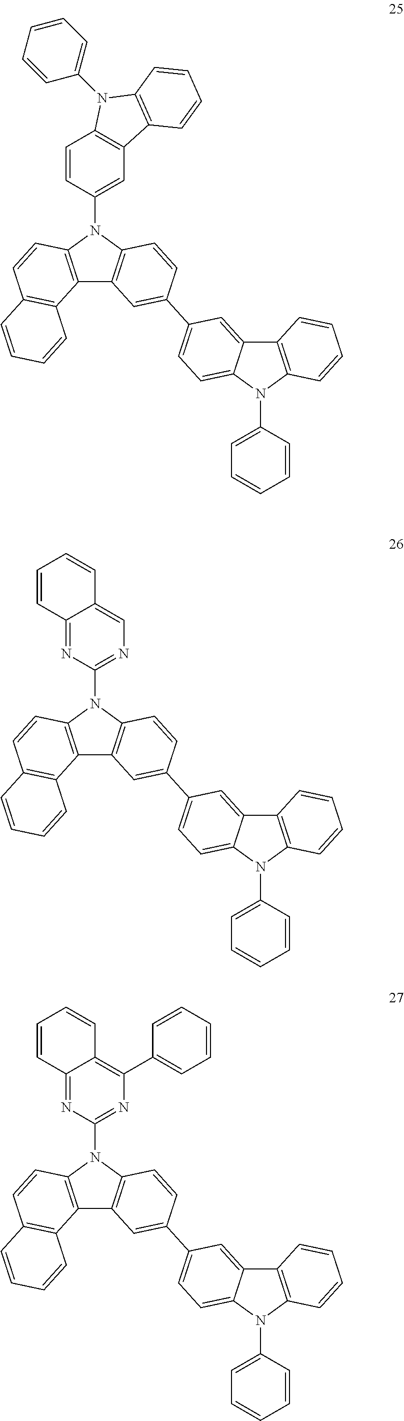 [SMILES: c1ccc(-n2c3ccccc3c3cc(-c4ccc5c(c4)c4c6ccccc6ccc4n5-c4ccc5c(c4)c4ccccc4n5-c4ccccc4)ccc32)cc1 ; c1ccc(-n2c3ccccc3c3cc(-c4ccc5c(c4)c4c6ccccc6ccc4n5-c4ncc5ccccc5n4)ccc32)cc1 ; c1ccc(-c2nc(-n3c4ccc(-c5ccc6c(c5)c5ccccc5n6-c5ccccc5)cc4c4c5ccccc5ccc43)nc3ccccc23)cc1]

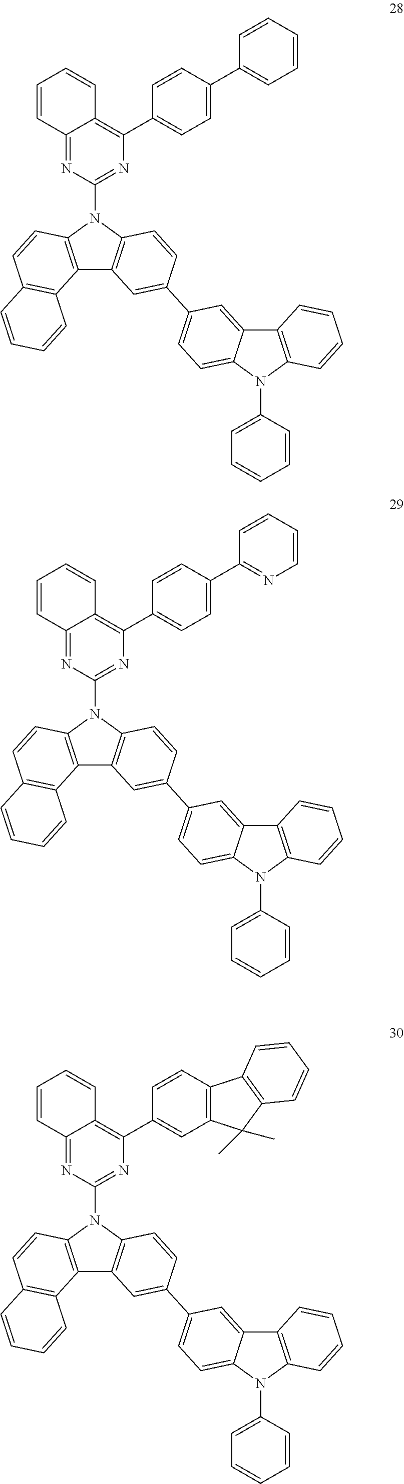

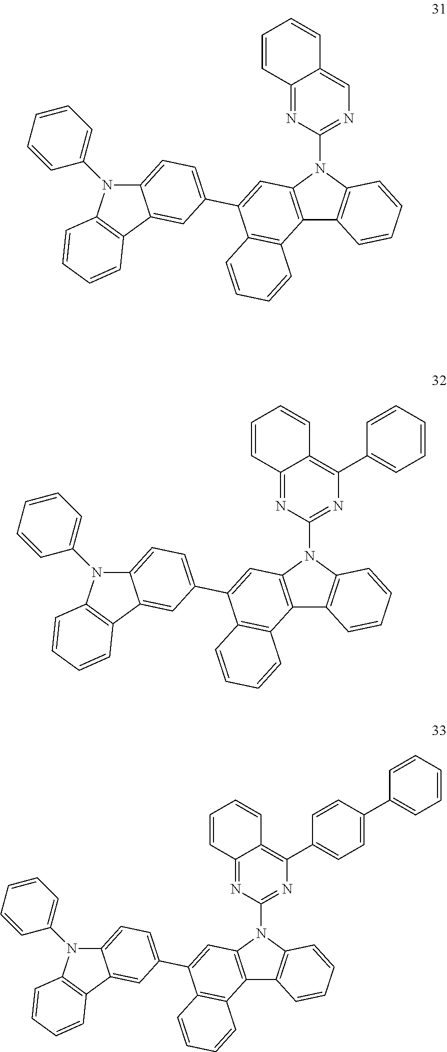 [SMILES: c1ccc(-n2c3ccccc3c3cc(-c4cc5c(c6ccccc46)c4ccccc4n5-c4ncc5ccccc5n4)ccc32)cc1 ; c1ccc(-c2nc(-n3c4ccccc4c4c5ccccc5c(-c5ccc6c(c5)c5ccccc5n6-c5ccccc5)cc43)nc3ccccc23)cc1 ; c1ccc(-c2ccc(-c3nc(-n4c5ccccc5c5c6ccccc6c(-c6ccc7c(c6)c6ccccc6n7-c6ccccc6)cc54)nc4ccccc34)cc2)cc1]

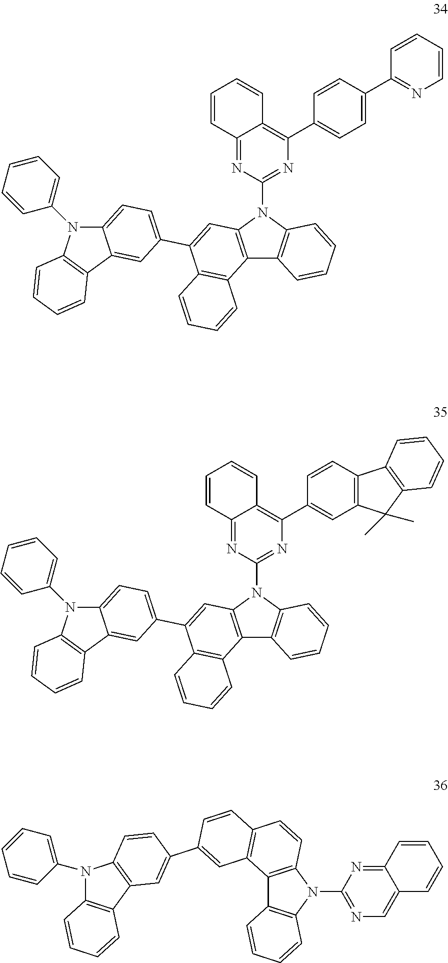 [SMILES: c1ccc(-n2c3ccccc3c3cc(-c4cc5c(c6ccccc46)c4ccccc4n5-c4nc(-c5ccc(-c6ccccn6)cc5)c5ccccc5n4)ccc32)cc1 ; CC1(C)c2ccccc2-c2ccc(-c3nc(-n4c5ccccc5c5c6ccccc6c(-c6ccc7c(c6)c6ccccc6n7-c6ccccc6)cc54)nc4ccccc34)cc21 ; c1ccc(-n2c3ccccc3c3cc(-c4ccc5ccc6c(c5c4)c4ccccc4n6-c4ncc5ccccc5n4)ccc32)cc1]

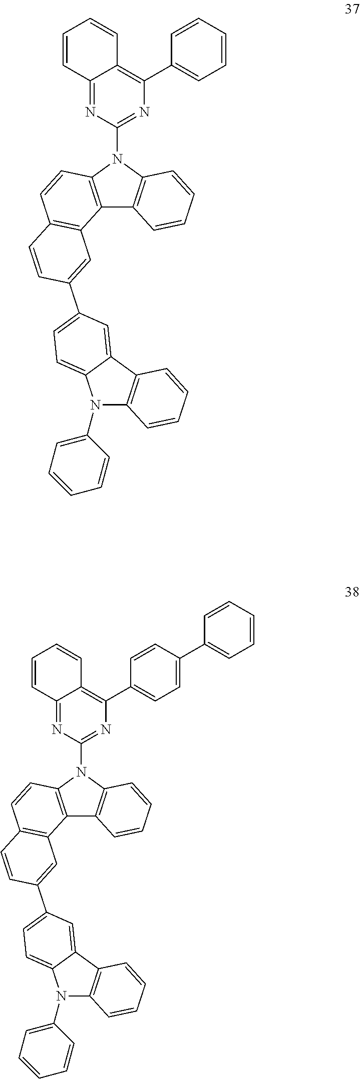 [SMILES: c1ccc(-c2nc(-n3c4ccccc4c4c5cc(-c6ccc7c(c6)c6ccccc6n7-c6ccccc6)ccc5ccc43)nc3ccccc23)cc1 ; c1ccc(-c2ccc(-c3nc(-n4c5ccccc5c5c6cc(-c7ccc8c(c7)c7ccccc7n8-c7ccccc7)ccc6ccc54)nc4ccccc34)cc2)cc1]

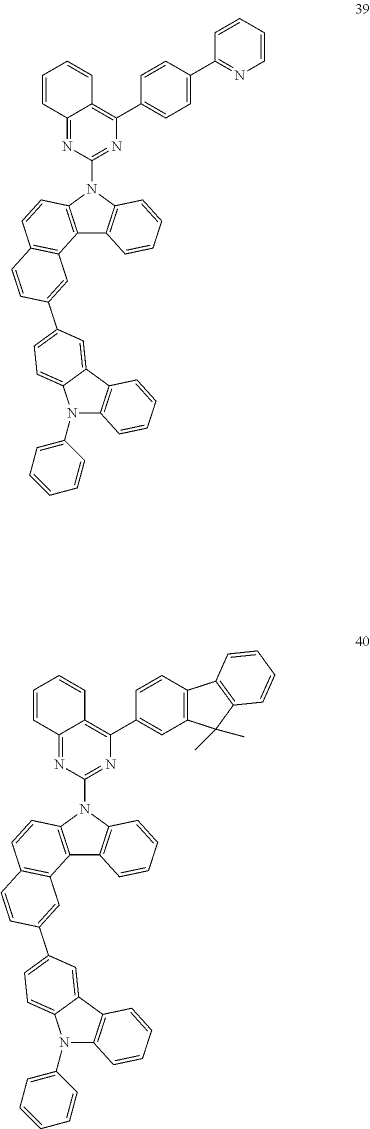 [SMILES: c1ccc(-n2c3ccccc3c3cc(-c4ccc5ccc6c(c5c4)c4ccccc4n6-c4nc(-c5ccc(-c6ccccn6)cc5)c5ccccc5n4)ccc32)cc1 ; CC1(C)c2ccccc2-c2ccc(-c3nc(-n4c5ccccc5c5c6cc(-c7ccc8c(c7)c7ccccc7n8-c7ccccc7)ccc6ccc54)nc4ccccc34)cc21]

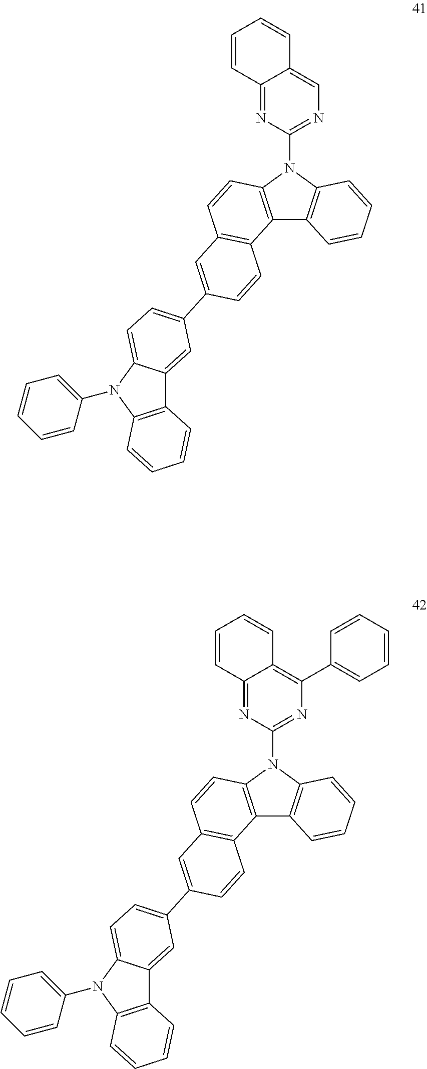 [SMILES: c1ccc(-n2c3ccccc3c3cc(-c4ccc5c(ccc6c5c5ccccc5n6-c5ncc6ccccc6n5)c4)ccc32)cc1 ; c1ccc(-c2nc(-n3c4ccccc4c4c5ccc(-c6ccc7c(c6)c6ccccc6n7-c6ccccc6)cc5ccc43)nc3ccccc23)cc1]

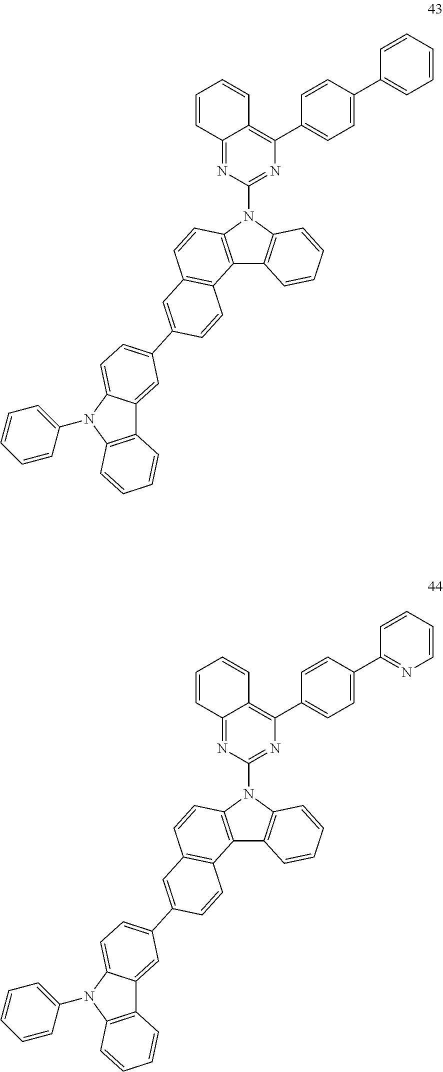 [SMILES: c1ccc(-c2ccc(-c3nc(-n4c5ccccc5c5c6ccc(-c7ccc8c(c7)c7ccccc7n8-c7ccccc7)cc6ccc54)nc4ccccc34)cc2)cc1 ; c1ccc(-n2c3ccccc3c3cc(-c4ccc5c(ccc6c5c5ccccc5n6-c5nc(-c6ccc(-c7ccccn7)cc6)c6ccccc6n5)c4)ccc32)cc1]

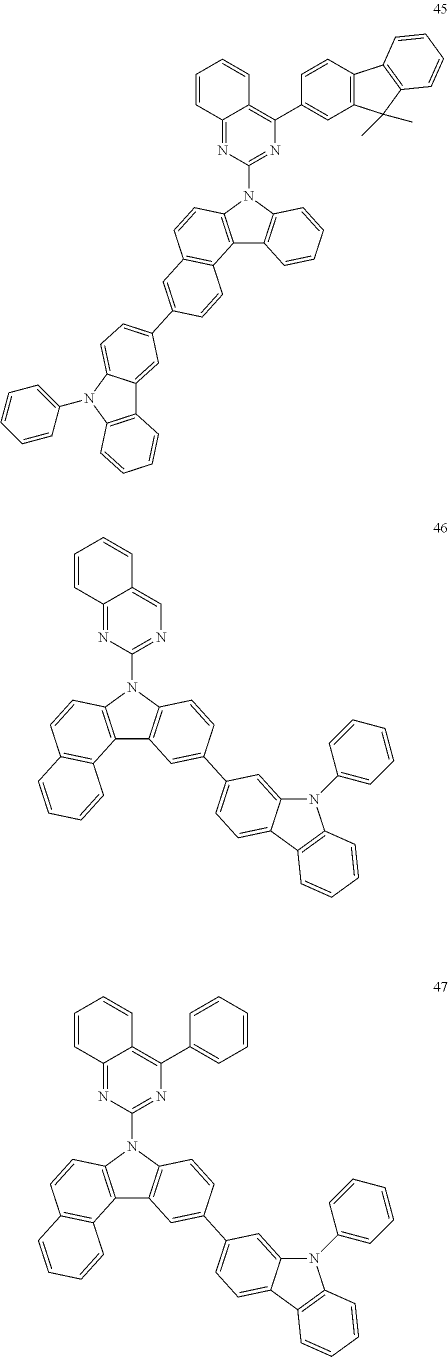 [SMILES: CC1(C)c2ccccc2-c2ccc(-c3nc(-n4c5ccccc5c5c6ccc(-c7ccc8c(c7)c7ccccc7n8-c7ccccc7)cc6ccc54)nc4ccccc34)cc21 ; c1ccc(-n2c3ccccc3c3ccc(-c4ccc5c(c4)c4c6ccccc6ccc4n5-c4ncc5ccccc5n4)cc32)cc1 ; c1ccc(-c2nc(-n3c4ccc(-c5ccc6c7ccccc7n(-c7ccccc7)c6c5)cc4c4c5ccccc5ccc43)nc3ccccc23)cc1]

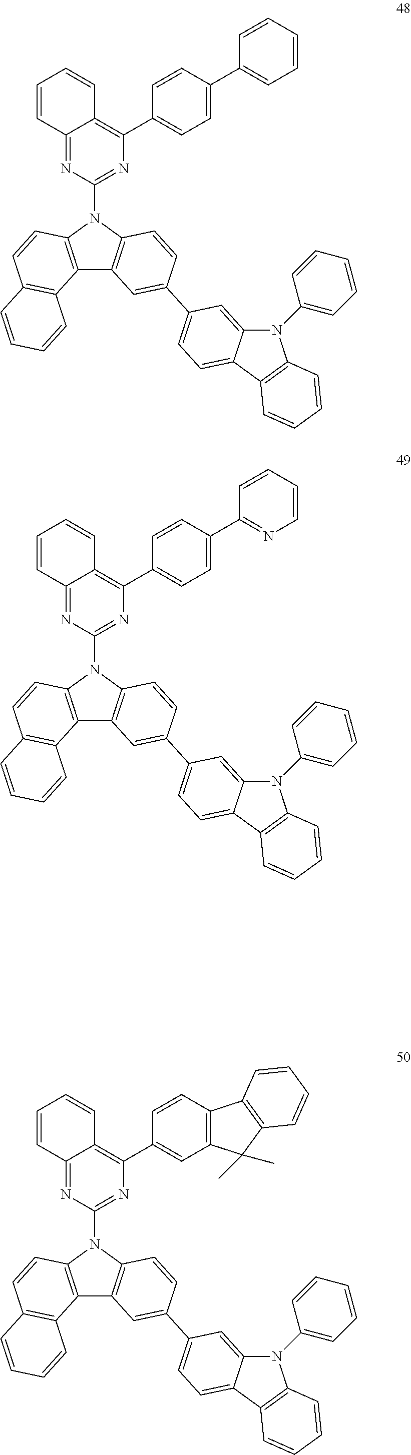 [SMILES: c1ccc(-c2ccc(-c3nc(-n4c5ccc(-c6ccc7c8ccccc8n(-c8ccccc8)c7c6)cc5c5c6ccccc6ccc54)nc4ccccc34)cc2)cc1 ; c1ccc(-n2c3ccccc3c3ccc(-c4ccc5c(c4)c4c6ccccc6ccc4n5-c4nc(-c5ccc(-c6ccccn6)cc5)c5ccccc5n4)cc32)cc1 ; CC1(C)c2ccccc2-c2ccc(-c3nc(-n4c5ccc(-c6ccc7c8ccccc8n(-c8ccccc8)c7c6)cc5c5c6ccccc6ccc54)nc4ccccc34)cc21]

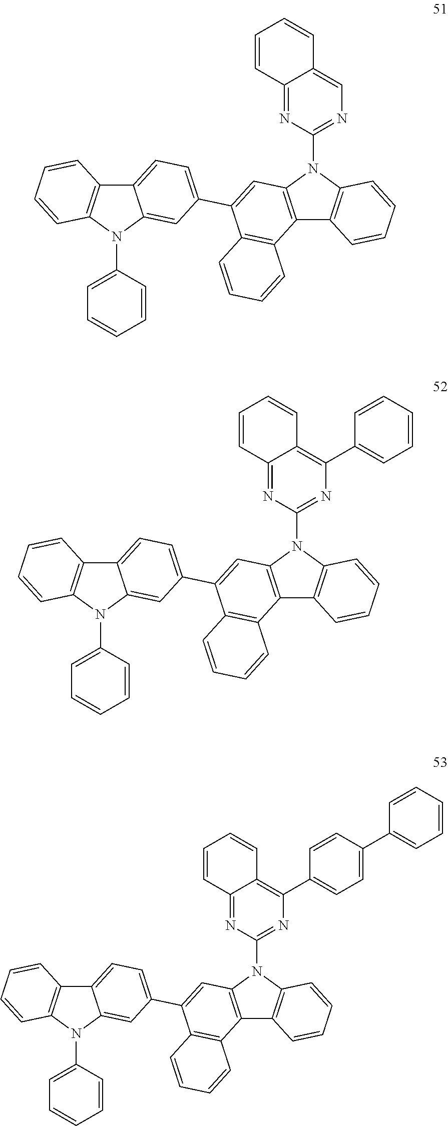

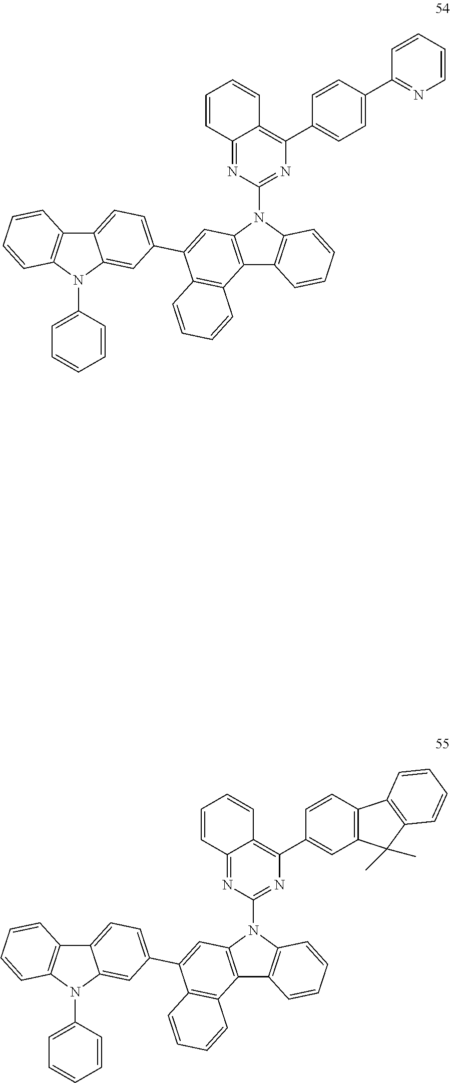

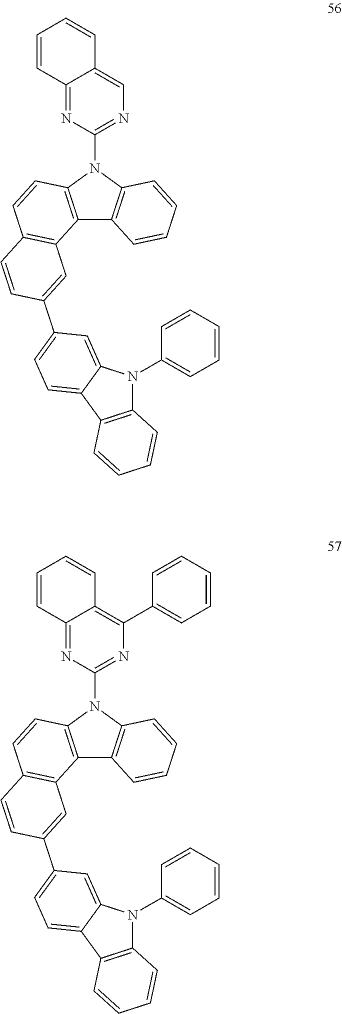 [SMILES: c1ccc(-n2c3ccccc3c3ccc(-c4ccc5ccc6c(c5c4)c4ccccc4n6-c4ncc5ccccc5n4)cc32)cc1 ; c1ccc(-c2nc(-n3c4ccccc4c4c5cc(-c6ccc7c8ccccc8n(-c8ccccc8)c7c6)ccc5ccc43)nc3ccccc23)cc1]

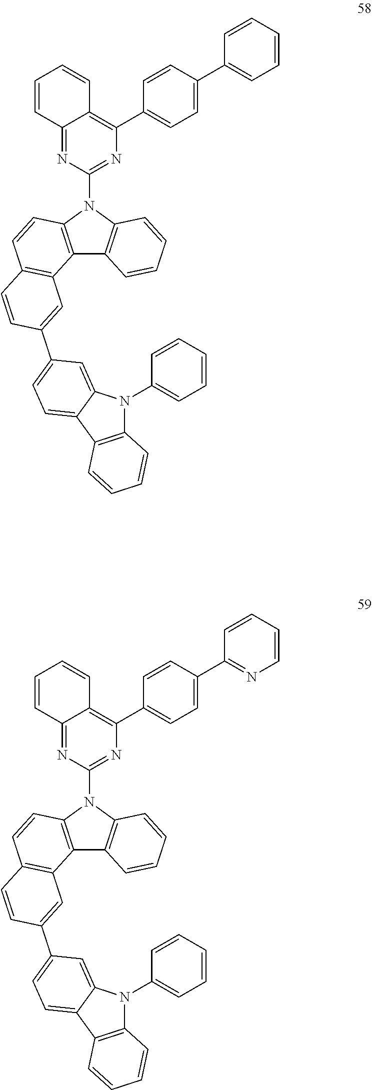 [SMILES: c1ccc(-c2ccc(-c3nc(-n4c5ccccc5c5c6cc(-c7ccc8c9ccccc9n(-c9ccccc9)c8c7)ccc6ccc54)nc4ccccc34)cc2)cc1 ; c1ccc(-n2c3ccccc3c3ccc(-c4ccc5ccc6c(c5c4)c4ccccc4n6-c4nc(-c5ccc(-c6ccccn6)cc5)c5ccccc5n4)cc32)cc1]

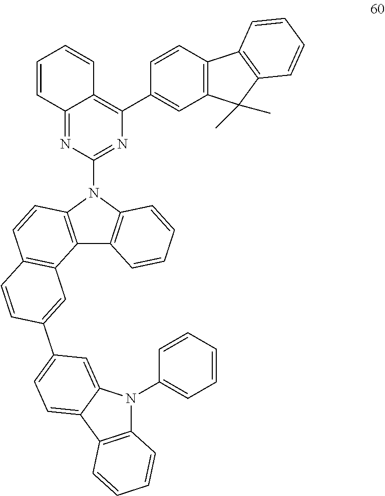 [SMILES: CC1(C)c2ccccc2-c2ccc(-c3nc(-n4c5ccccc5c5c6cc(-c7ccc8c9ccccc9n(-c9ccccc9)c8c7)ccc6ccc54)nc4ccccc34)cc21]

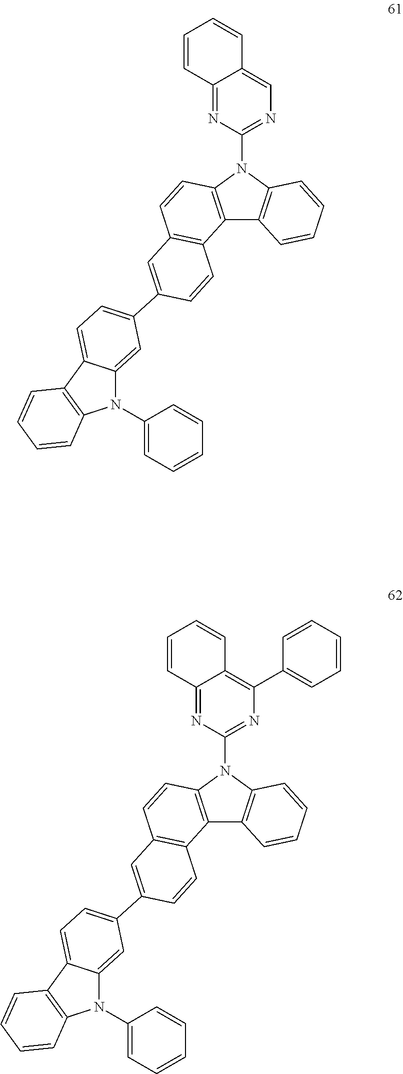 [SMILES: c1ccc(-n2c3ccccc3c3ccc(-c4ccc5c(ccc6c5c5ccccc5n6-c5ncc6ccccc6n5)c4)cc32)cc1 ; c1ccc(-c2nc(-n3c4ccccc4c4c5ccc(-c6ccc7c8ccccc8n(-c8ccccc8)c7c6)cc5ccc43)nc3ccccc23)cc1]

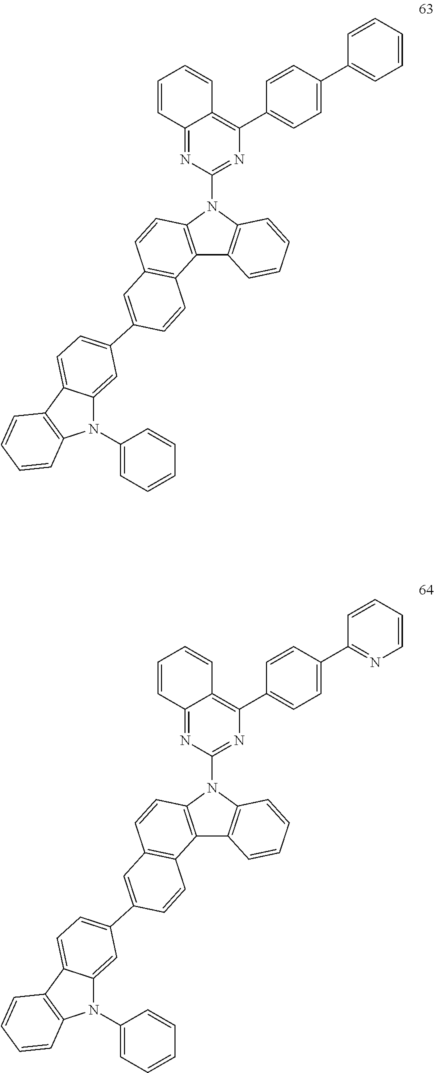 [SMILES: c1ccc(-c2ccc(-c3nc(-n4c5ccccc5c5c6ccc(-c7ccc8c9ccccc9n(-c9ccccc9)c8c7)cc6ccc54)nc4ccccc34)cc2)cc1 ; c1ccc(-n2c3ccccc3c3ccc(-c4ccc5c(ccc6c5c5ccccc5n6-c5nc(-c6ccc(-c7ccccn7)cc6)c6ccccc6n5)c4)cc32)cc1]

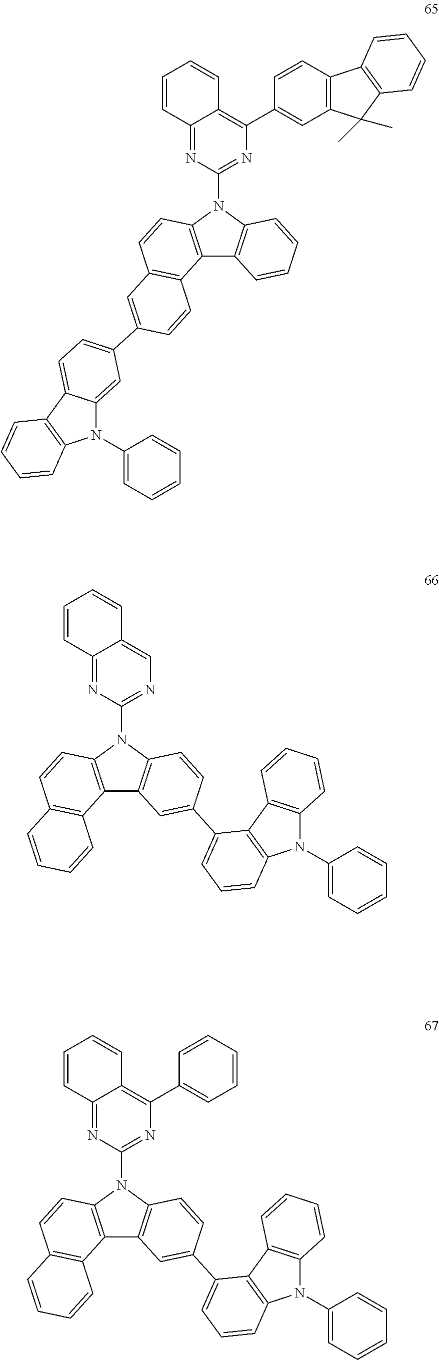 [SMILES: CC1(C)c2ccccc2-c2ccc(-c3nc(-n4c5ccccc5c5c6ccc(-c7ccc8c9ccccc9n(-c9ccccc9)c8c7)cc6ccc54)nc4ccccc34)cc21 ; c1ccc(-n2c3ccccc3c3c(-c4ccc5c(c4)c4c6ccccc6ccc4n5-c4ncc5ccccc5n4)cccc32)cc1 ; c1ccc(-c2nc(-n3c4ccc(-c5cccc6c5c5ccccc5n6-c5ccccc5)cc4c4c5ccccc5ccc43)nc3ccccc23)cc1]

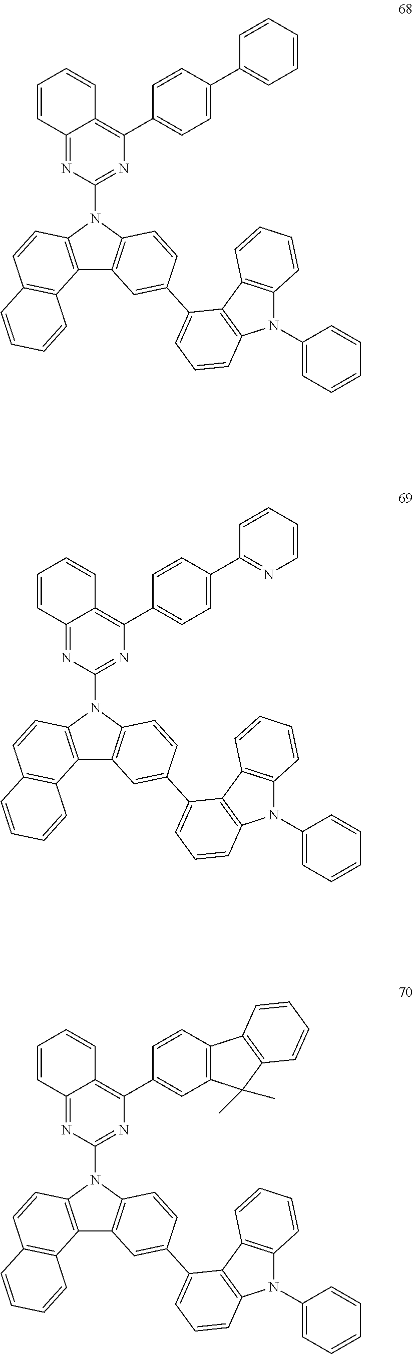 [SMILES: c1ccc(-c2ccc(-c3nc(-n4c5ccc(-c6cccc7c6c6ccccc6n7-c6ccccc6)cc5c5c6ccccc6ccc54)nc4ccccc34)cc2)cc1 ; c1ccc(-n2c3ccccc3c3c(-c4ccc5c(c4)c4c6ccccc6ccc4n5-c4nc(-c5ccc(-c6ccccn6)cc5)c5ccccc5n4)cccc32)cc1 ; CC1(C)c2ccccc2-c2ccc(-c3nc(-n4c5ccc(-c6cccc7c6c6ccccc6n7-c6ccccc6)cc5c5c6ccccc6ccc54)nc4ccccc34)cc21]

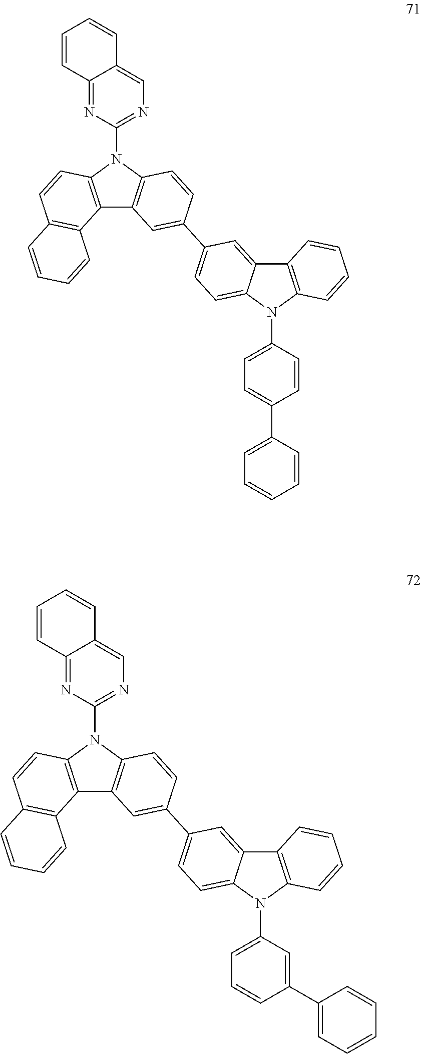 [SMILES: c1ccc(-c2ccc(-n3c4ccccc4c4cc(-c5ccc6c(c5)c5c7ccccc7ccc5n6-c5ncc6ccccc6n5)ccc43)cc2)cc1 ; c1ccc(-c2cccc(-n3c4ccccc4c4cc(-c5ccc6c(c5)c5c7ccccc7ccc5n6-c5ncc6ccccc6n5)ccc43)c2)cc1]

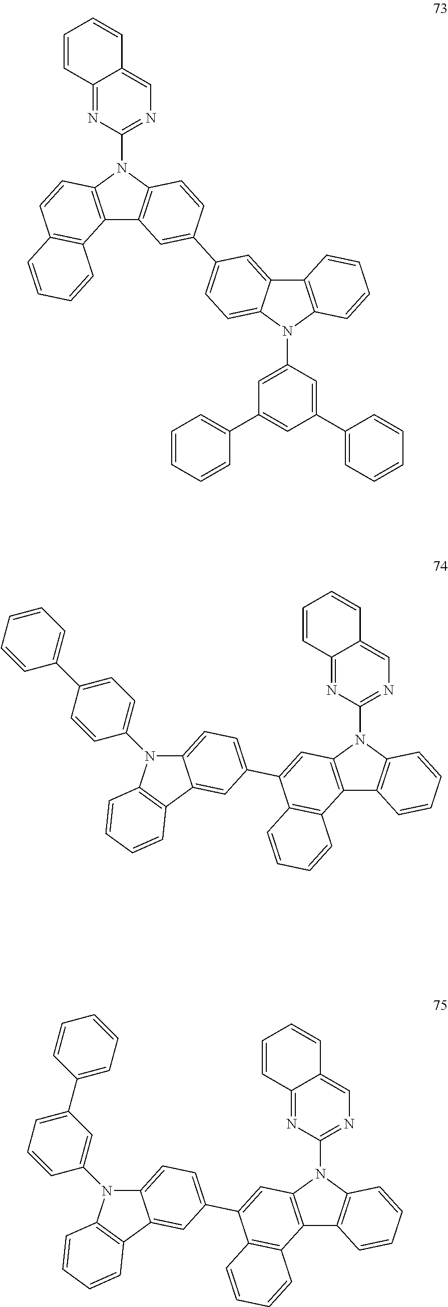

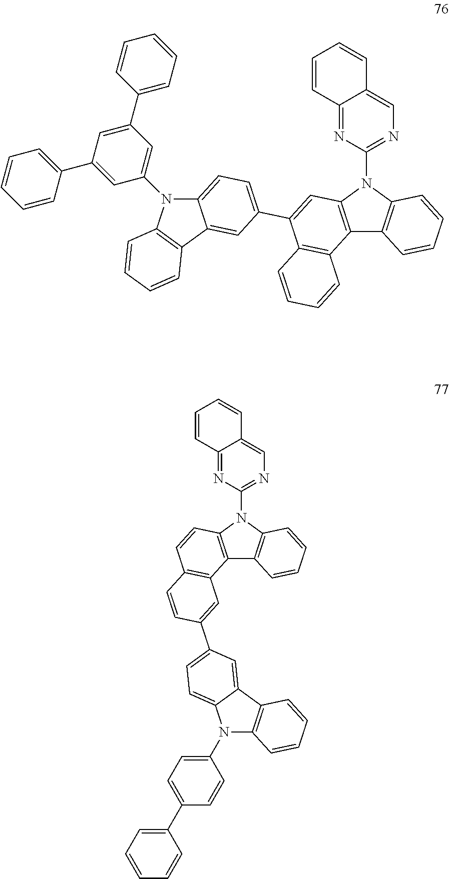

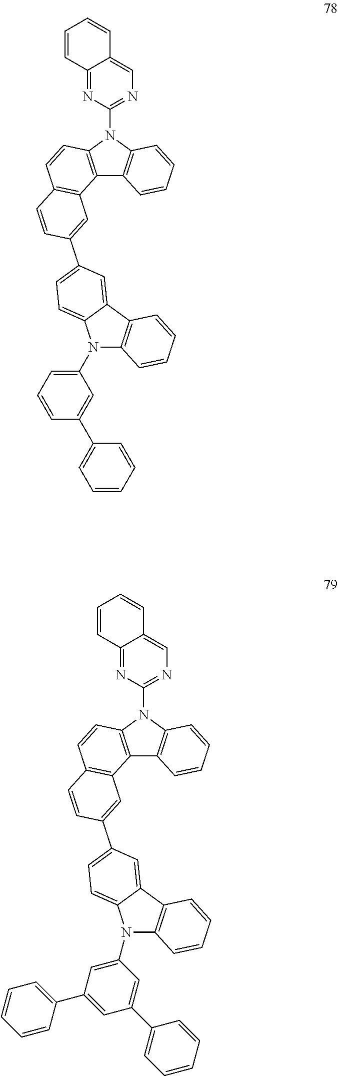

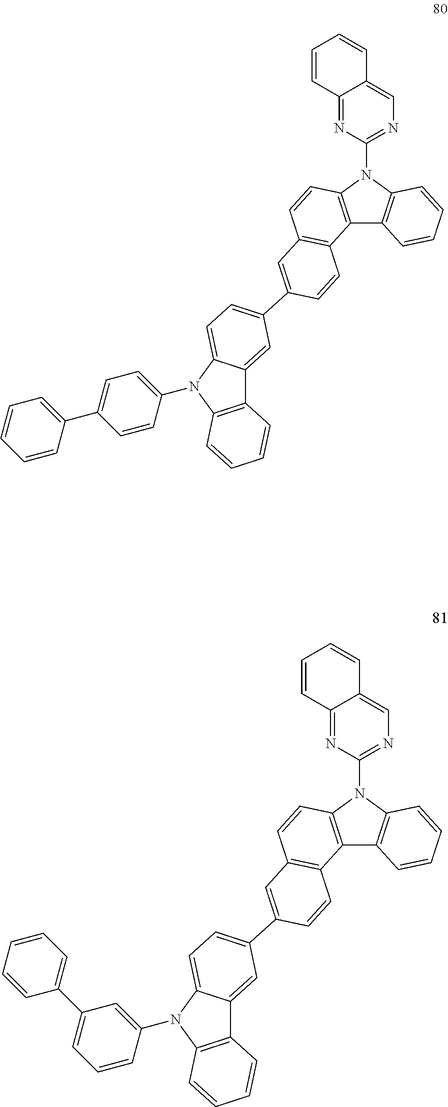 [SMILES: c1ccc(-c2ccc(-n3c4ccccc4c4cc(-c5ccc6c(ccc7c6c6ccccc6n7-c6ncc7ccccc7n6)c5)ccc43)cc2)cc1 ; c1ccc(-c2cccc(-n3c4ccccc4c4cc(-c5ccc6c(ccc7c6c6ccccc6n7-c6ncc7ccccc7n6)c5)ccc43)c2)cc1]

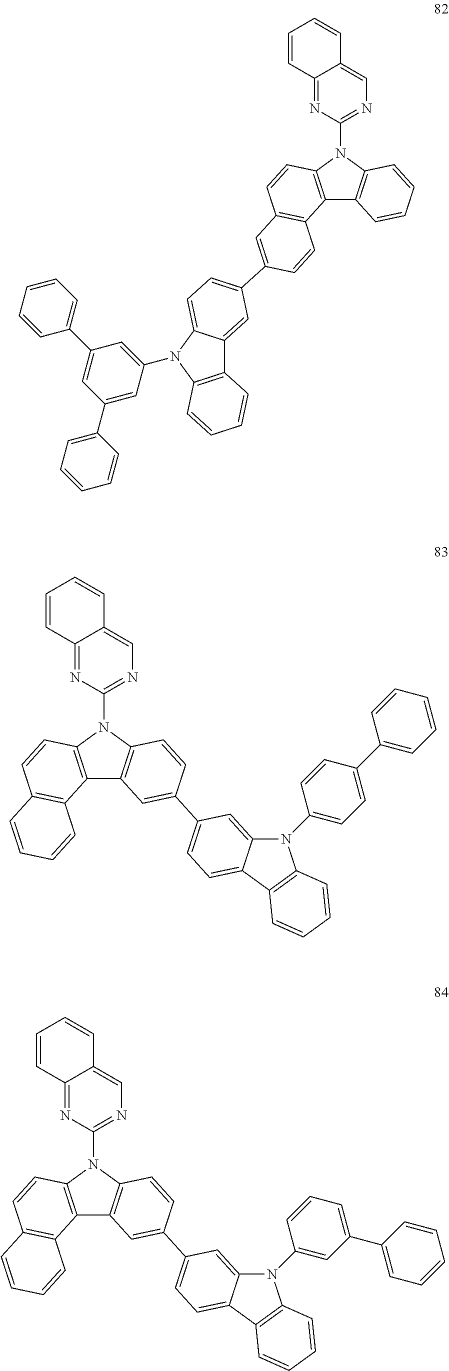 [SMILES: c1ccc(-c2cc(-c3ccccc3)cc(-n3c4ccccc4c4cc(-c5ccc6c(ccc7c6c6ccccc6n7-c6ncc7ccccc7n6)c5)ccc43)c2)cc1 ; c1ccc(-c2ccc(-n3c4ccccc4c4ccc(-c5ccc6c(c5)c5c7ccccc7ccc5n6-c5ncc6ccccc6n5)cc43)cc2)cc1 ; c1ccc(-c2cccc(-n3c4ccccc4c4ccc(-c5ccc6c(c5)c5c7ccccc7ccc5n6-c5ncc6ccccc6n5)cc43)c2)cc1]

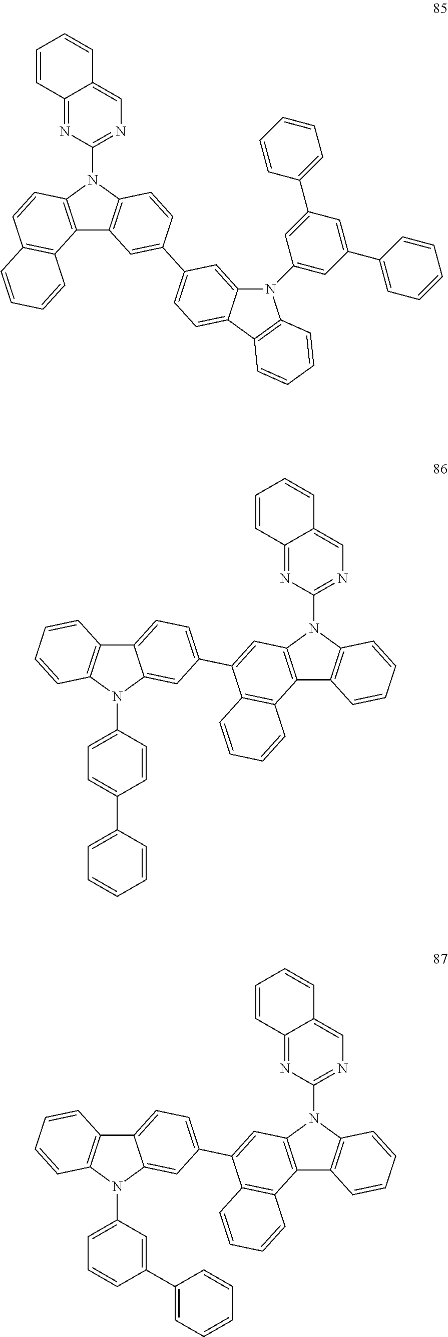 [SMILES: c1ccc(-c2cc(-c3ccccc3)cc(-n3c4ccccc4c4ccc(-c5ccc6c(c5)c5c7ccccc7ccc5n6-c5ncc6ccccc6n5)cc43)c2)cc1 ; c1ccc(-c2ccc(-n3c4ccccc4c4ccc(-c5cc6c(c7ccccc57)c5ccccc5n6-c5ncc6ccccc6n5)cc43)cc2)cc1 ; c1ccc(-c2cccc(-n3c4ccccc4c4ccc(-c5cc6c(c7ccccc57)c5ccccc5n6-c5ncc6ccccc6n5)cc43)c2)cc1]

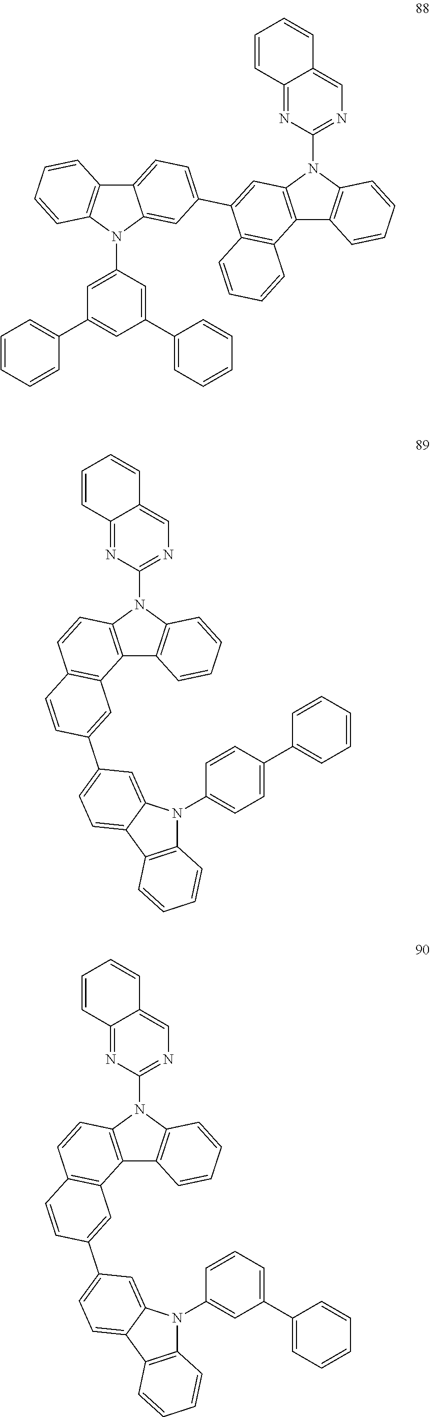 [SMILES: c1ccc(-c2cc(-c3ccccc3)cc(-n3c4ccccc4c4ccc(-c5cc6c(c7ccccc57)c5ccccc5n6-c5ncc6ccccc6n5)cc43)c2)cc1 ; c1ccc(-c2ccc(-n3c4ccccc4c4ccc(-c5ccc6ccc7c(c6c5)c5ccccc5n7-c5ncc6ccccc6n5)cc43)cc2)cc1 ; c1ccc(-c2cccc(-n3c4ccccc4c4ccc(-c5ccc6ccc7c(c6c5)c5ccccc5n7-c5ncc6ccccc6n5)cc43)c2)cc1]

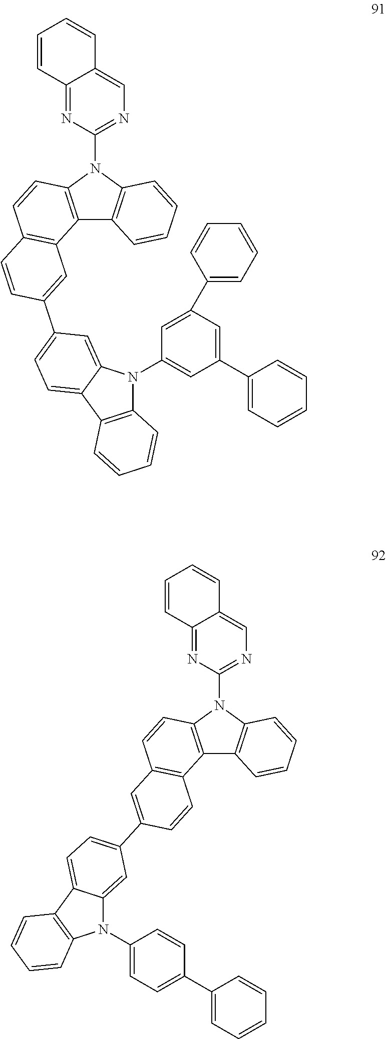 [SMILES: c1ccc(-c2cc(-c3ccccc3)cc(-n3c4ccccc4c4ccc(-c5ccc6ccc7c(c6c5)c5ccccc5n7-c5ncc6ccccc6n5)cc43)c2)cc1 ; c1ccc(-c2ccc(-n3c4ccccc4c4ccc(-c5ccc6c(ccc7c6c6ccccc6n7-c6ncc7ccccc7n6)c5)cc43)cc2)cc1]

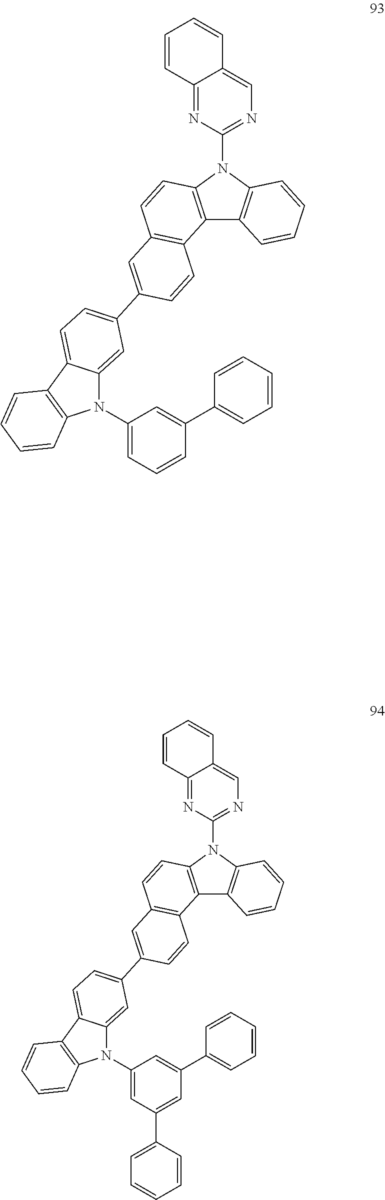 [SMILES: c1ccc(-c2cccc(-n3c4ccccc4c4ccc(-c5ccc6c(ccc7c6c6ccccc6n7-c6ncc7ccccc7n6)c5)cc43)c2)cc1 ; c1ccc(-c2cc(-c3ccccc3)cc(-n3c4ccccc4c4ccc(-c5ccc6c(ccc7c6c6ccccc6n7-c6ncc7ccccc7n6)c5)cc43)c2)cc1]

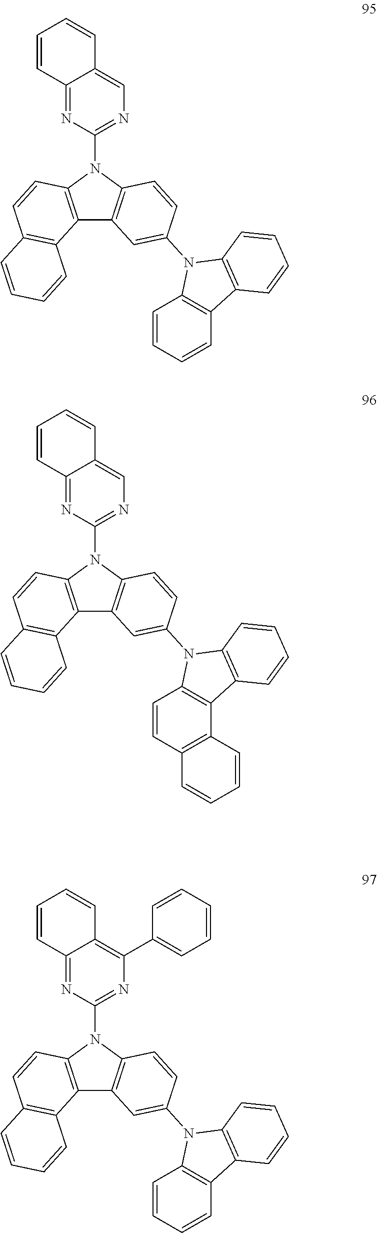 [SMILES: c1ccc2nc(-n3c4ccc(-n5c6ccccc6c6ccccc65)cc4c4c5ccccc5ccc43)ncc2c1 ; c1ccc2nc(-n3c4ccc(-n5c6ccccc6c6c7ccccc7ccc65)cc4c4c5ccccc5ccc43)ncc2c1 ; c1ccc(-c2nc(-n3c4ccc(-n5c6ccccc6c6ccccc65)cc4c4c5ccccc5ccc43)nc3ccccc23)cc1]

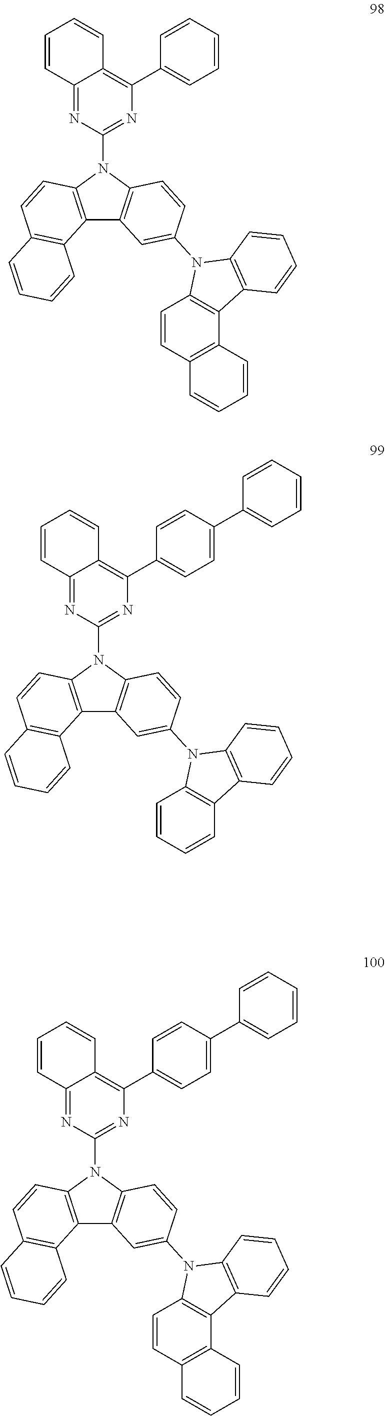 [SMILES: c1ccc(-c2nc(-n3c4ccc(-n5c6ccccc6c6c7ccccc7ccc65)cc4c4c5ccccc5ccc43)nc3ccccc23)cc1 ; c1ccc(-c2ccc(-c3nc(-n4c5ccc(-n6c7ccccc7c7ccccc76)cc5c5c6ccccc6ccc54)nc4ccccc34)cc2)cc1 ; c1ccc(-c2ccc(-c3nc(-n4c5ccc(-n6c7ccccc7c7c8ccccc8ccc76)cc5c5c6ccccc6ccc54)nc4ccccc34)cc2)cc1]

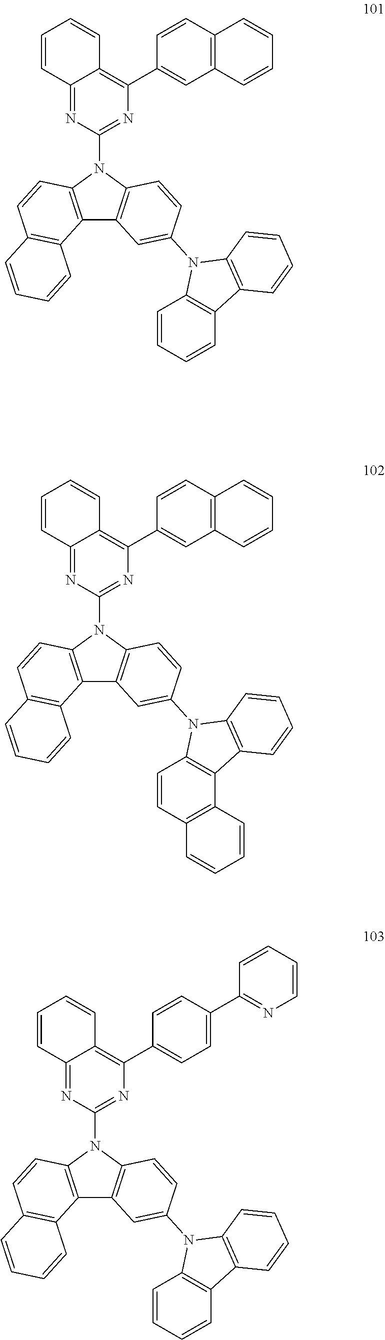 [SMILES: c1ccc2cc(-c3nc(-n4c5ccc(-n6c7ccccc7c7ccccc76)cc5c5c6ccccc6ccc54)nc4ccccc34)ccc2c1 ; c1ccc2cc(-c3nc(-n4c5ccc(-n6c7ccccc7c7c8ccccc8ccc76)cc5c5c6ccccc6ccc54)nc4ccccc34)ccc2c1 ; c1ccc(-c2ccc(-c3nc(-n4c5ccc(-n6c7ccccc7c7ccccc76)cc5c5c6ccccc6ccc54)nc4ccccc34)cc2)nc1]

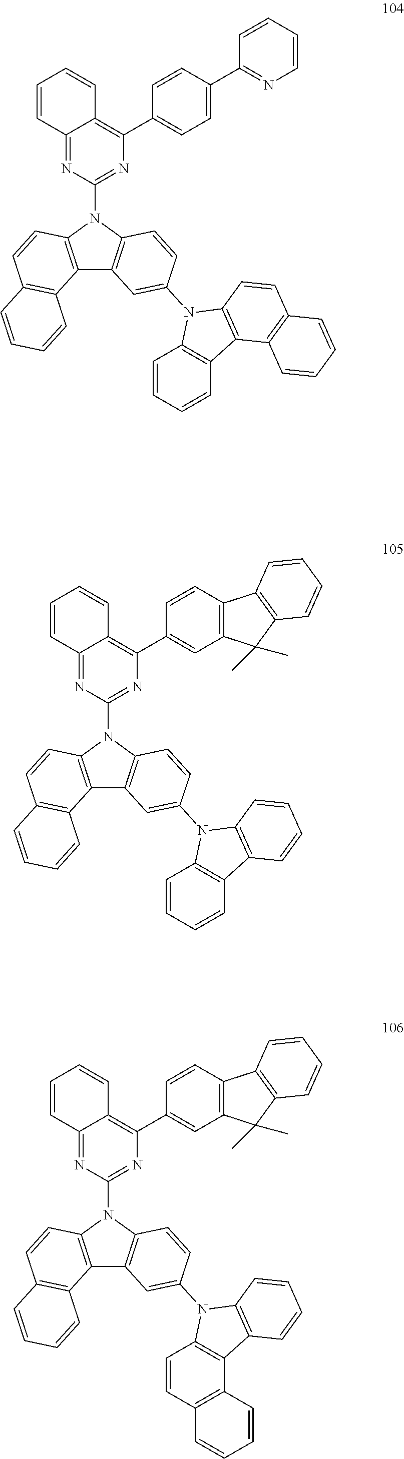 [SMILES: c1ccc(-c2ccc(-c3nc(-n4c5ccc(-n6c7ccccc7c7c8ccccc8ccc76)cc5c5c6ccccc6ccc54)nc4ccccc34)cc2)nc1 ; CC1(C)c2ccccc2-c2ccc(-c3nc(-n4c5ccc(-n6c7ccccc7c7ccccc76)cc5c5c6ccccc6ccc54)nc4ccccc34)cc21 ; CC1(C)c2ccccc2-c2ccc(-c3nc(-n4c5ccc(-n6c7ccccc7c7c8ccccc8ccc76)cc5c5c6ccccc6ccc54)nc4ccccc34)cc21]

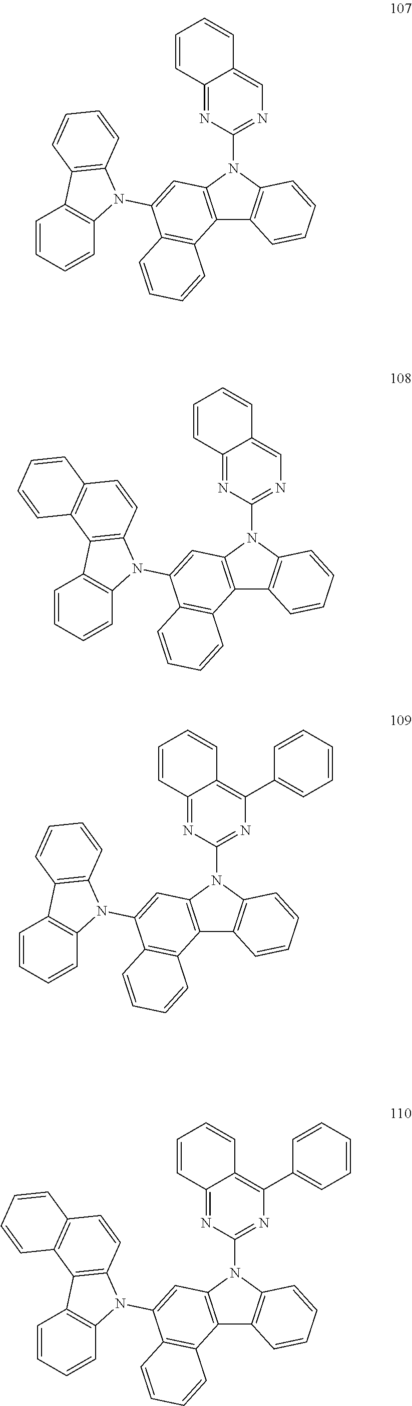 [SMILES: c1ccc2nc(-n3c4ccccc4c4c5ccccc5c(-n5c6ccccc6c6ccccc65)cc43)ncc2c1 ; c1ccc2nc(-n3c4ccccc4c4c5ccccc5c(-n5c6ccccc6c6c7ccccc7ccc65)cc43)ncc2c1 ; c1ccc(-c2nc(-n3c4ccccc4c4c5ccccc5c(-n5c6ccccc6c6ccccc65)cc43)nc3ccccc23)cc1 ; c1ccc(-c2nc(-n3c4ccccc4c4c5ccccc5c(-n5c6ccccc6c6c7ccccc7ccc65)cc43)nc3ccccc23)cc1]

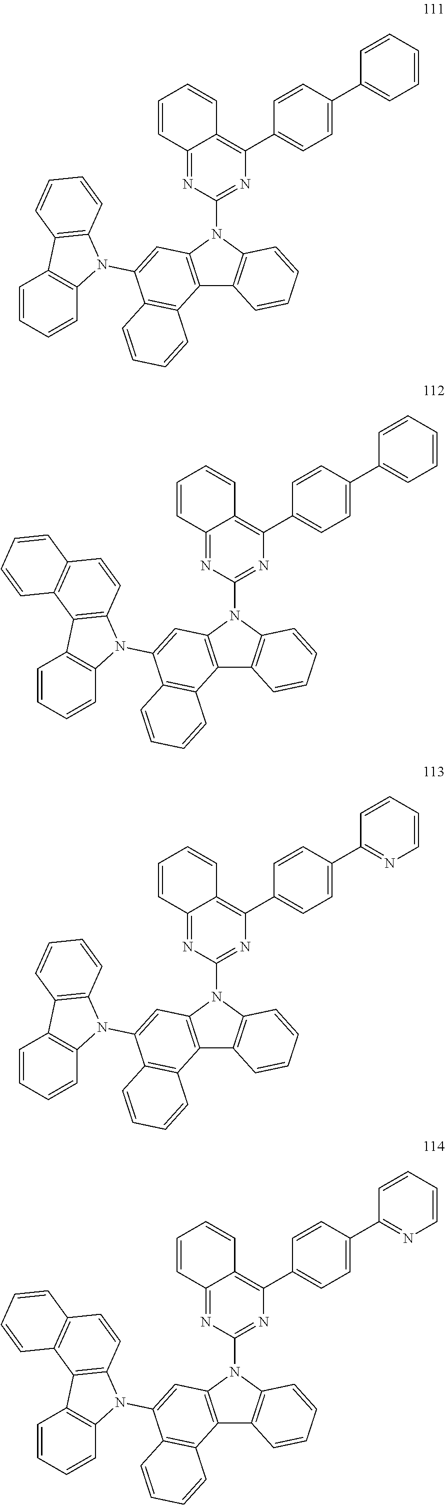 [SMILES: c1ccc(-c2ccc(-c3nc(-n4c5ccccc5c5c6ccccc6c(-n6c7ccccc7c7ccccc76)cc54)nc4ccccc34)cc2)cc1 ; c1ccc(-c2ccc(-c3nc(-n4c5ccccc5c5c6ccccc6c(-n6c7ccccc7c7c8ccccc8ccc76)cc54)nc4ccccc34)cc2)cc1 ; c1ccc(-c2ccc(-c3nc(-n4c5ccccc5c5c6ccccc6c(-n6c7ccccc7c7ccccc76)cc54)nc4ccccc34)cc2)nc1 ; c1ccc(-c2ccc(-c3nc(-n4c5ccccc5c5c6ccccc6c(-n6c7ccccc7c7c8ccccc8ccc76)cc54)nc4ccccc34)cc2)nc1]

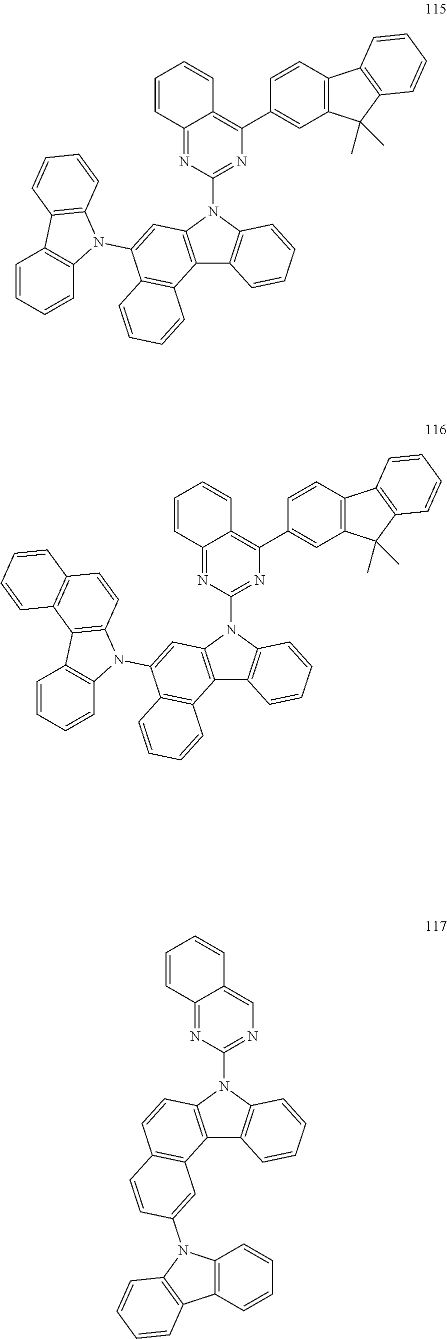 [SMILES: CC1(C)c2ccccc2-c2ccc(-c3nc(-n4c5ccccc5c5c6ccccc6c(-n6c7ccccc7c7ccccc76)cc54)nc4ccccc34)cc21 ; CC1(C)c2ccccc2-c2ccc(-c3nc(-n4c5ccccc5c5c6ccccc6c(-n6c7ccccc7c7c8ccccc8ccc76)cc54)nc4ccccc34)cc21 ; c1ccc2nc(-n3c4ccccc4c4c5cc(-n6c7ccccc7c7ccccc76)ccc5ccc43)ncc2c1]

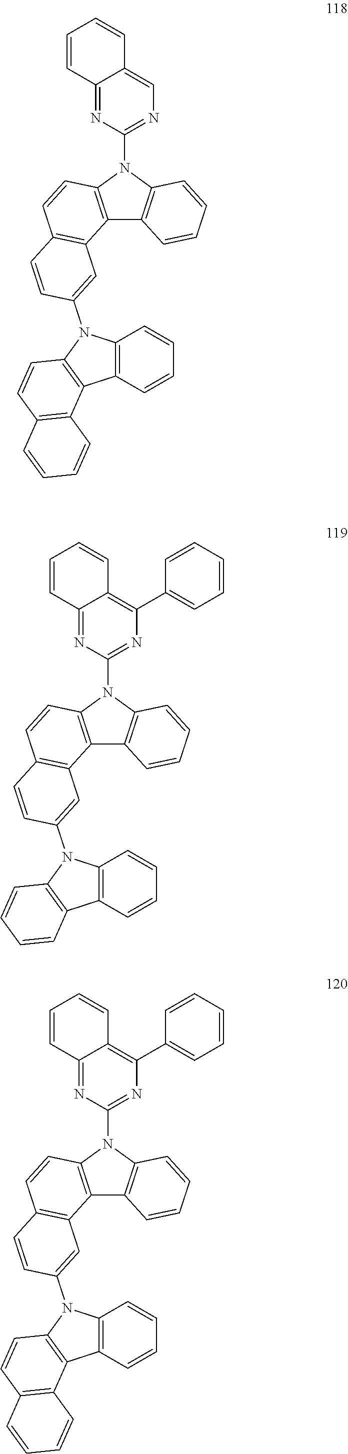 [SMILES: c1ccc2nc(-n3c4ccccc4c4c5cc(-n6c7ccccc7c7c8ccccc8ccc76)ccc5ccc43)ncc2c1 ; c1ccc(-c2nc(-n3c4ccccc4c4c5cc(-n6c7ccccc7c7ccccc76)ccc5ccc43)nc3ccccc23)cc1 ; c1ccc(-c2nc(-n3c4ccccc4c4c5cc(-n6c7ccccc7c7c8ccccc8ccc76)ccc5ccc43)nc3ccccc23)cc1]

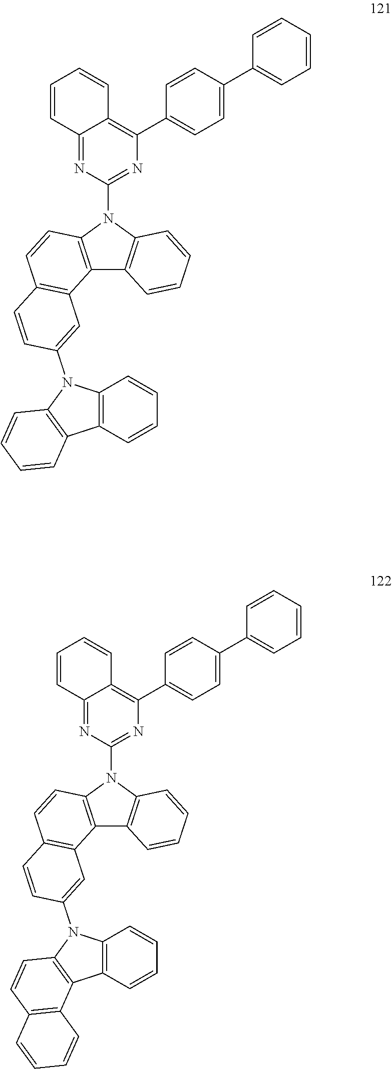 [SMILES: c1ccc(-c2ccc(-c3nc(-n4c5ccccc5c5c6cc(-n7c8ccccc8c8ccccc87)ccc6ccc54)nc4ccccc34)cc2)cc1 ; c1ccc(-c2ccc(-c3nc(-n4c5ccccc5c5c6cc(-n7c8ccccc8c8c9ccccc9ccc87)ccc6ccc54)nc4ccccc34)cc2)cc1]

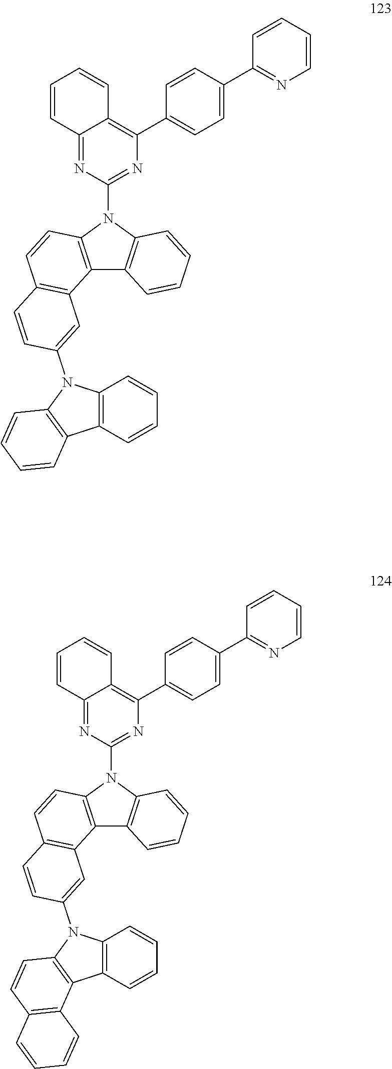 [SMILES: c1ccc(-c2ccc(-c3nc(-n4c5ccccc5c5c6cc(-n7c8ccccc8c8ccccc87)ccc6ccc54)nc4ccccc34)cc2)nc1 ; c1ccc(-c2ccc(-c3nc(-n4c5ccccc5c5c6cc(-n7c8ccccc8c8c9ccccc9ccc87)ccc6ccc54)nc4ccccc34)cc2)nc1]

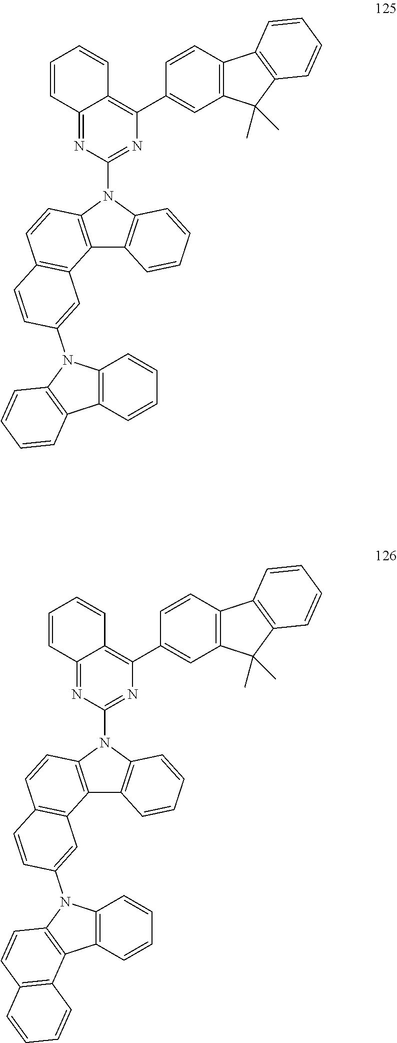 [SMILES: CC1(C)c2ccccc2-c2ccc(-c3nc(-n4c5ccccc5c5c6cc(-n7c8ccccc8c8ccccc87)ccc6ccc54)nc4ccccc34)cc21 ; CC1(C)c2ccccc2-c2ccc(-c3nc(-n4c5ccccc5c5c6cc(-n7c8ccccc8c8c9ccccc9ccc87)ccc6ccc54)nc4ccccc34)cc21]

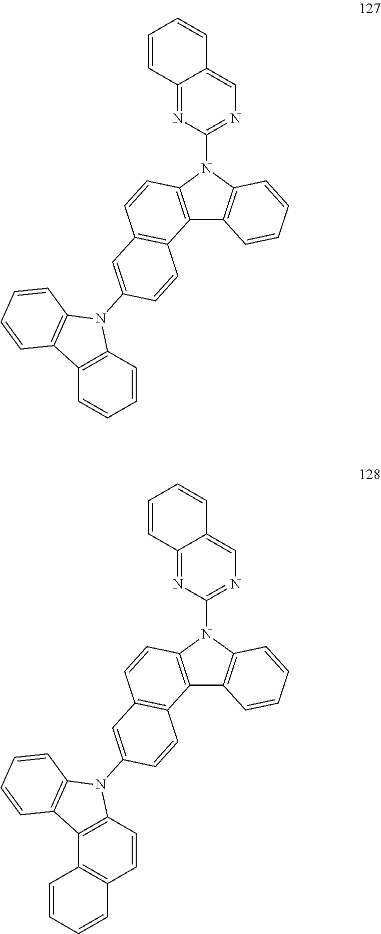 [SMILES: c1ccc2nc(-n3c4ccccc4c4c5ccc(-n6c7ccccc7c7ccccc76)cc5ccc43)ncc2c1 ; c1ccc2nc(-n3c4ccccc4c4c5ccc(-n6c7ccccc7c7c8ccccc8ccc76)cc5ccc43)ncc2c1]

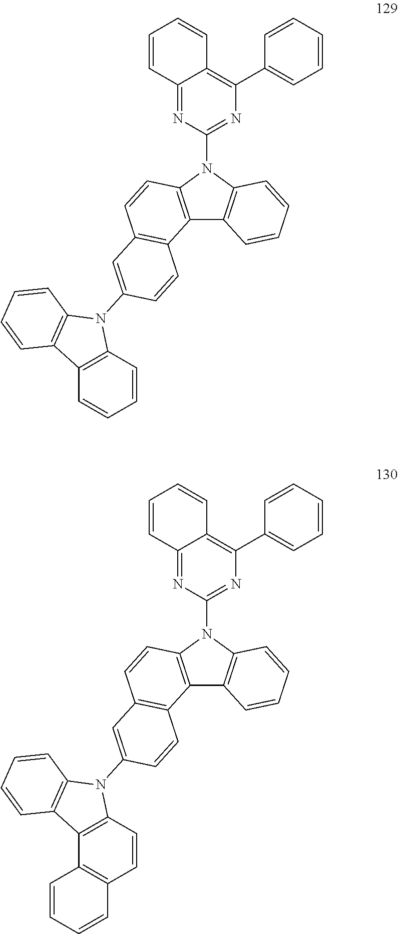 [SMILES: c1ccc(-c2nc(-n3c4ccccc4c4c5ccc(-n6c7ccccc7c7ccccc76)cc5ccc43)nc3ccccc23)cc1 ; c1ccc(-c2nc(-n3c4ccccc4c4c5ccc(-n6c7ccccc7c7c8ccccc8ccc76)cc5ccc43)nc3ccccc23)cc1]

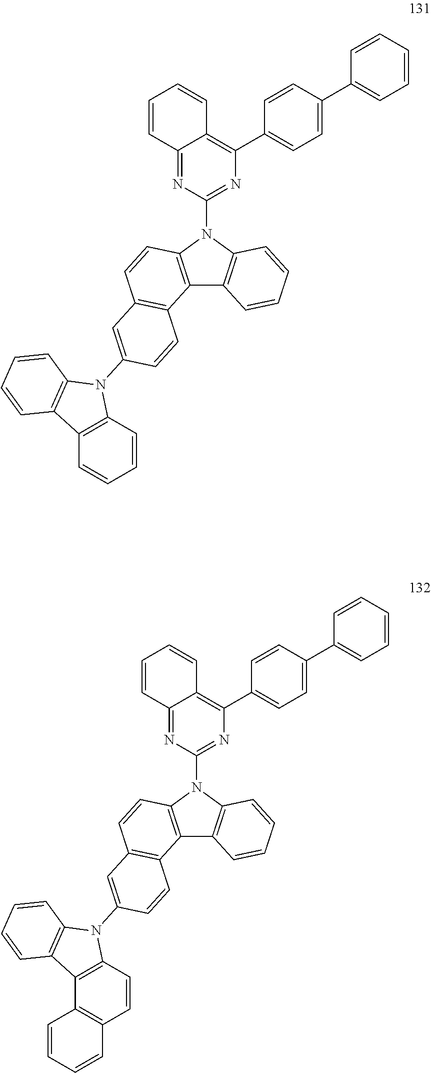 [SMILES: c1ccc(-c2ccc(-c3nc(-n4c5ccccc5c5c6ccc(-n7c8ccccc8c8ccccc87)cc6ccc54)nc4ccccc34)cc2)cc1 ; c1ccc(-c2ccc(-c3nc(-n4c5ccccc5c5c6ccc(-n7c8ccccc8c8c9ccccc9ccc87)cc6ccc54)nc4ccccc34)cc2)cc1]

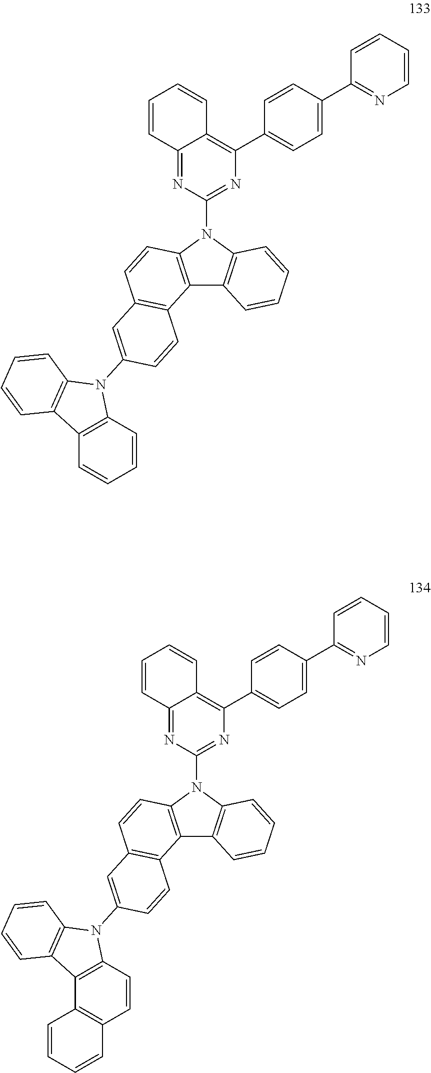 [SMILES: c1ccc(-c2ccc(-c3nc(-n4c5ccccc5c5c6ccc(-n7c8ccccc8c8ccccc87)cc6ccc54)nc4ccccc34)cc2)nc1 ; c1ccc(-c2ccc(-c3nc(-n4c5ccccc5c5c6ccc(-n7c8ccccc8c8c9ccccc9ccc87)cc6ccc54)nc4ccccc34)cc2)nc1]

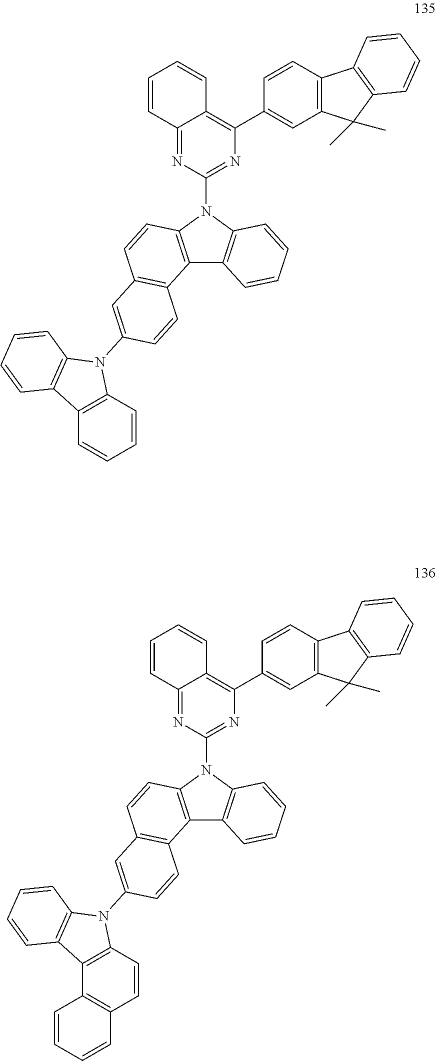 [SMILES: CC1(C)c2ccccc2-c2ccc(-c3nc(-n4c5ccccc5c5c6ccc(-n7c8ccccc8c8ccccc87)cc6ccc54)nc4ccccc34)cc21 ; CC1(C)c2ccccc2-c2ccc(-c3nc(-n4c5ccccc5c5c6ccc(-n7c8ccccc8c8c9ccccc9ccc87)cc6ccc54)nc4ccccc34)cc21]

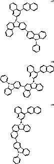

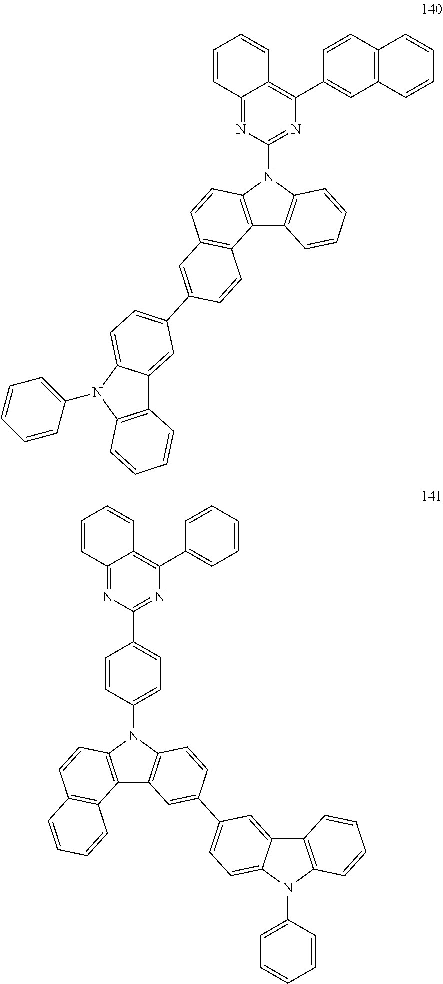

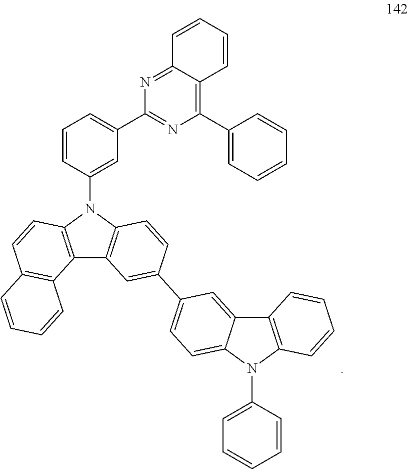

19. An organic electronic device comprising:
a first electrode;
a second electrode; and
one or more organic material layers that are disposed between the first electrode and the second electrode,
wherein one or more layers of the organic material layers includes the compound of claim 1.

20. The organic electronic device of claim 19, wherein the organic material layer includes at least one layer of a hole injection layer, a hole transport layer, a light emitting layer, and an electronic transport layer, and at least one layer of the hole injection layer, the hole transport layer, the light emitting layer, and the electronic transport layer includes the compound of Formula 1.
